(19) United States
(12) Patent Application Publication
(10) Pub. No.: US 2023/0127914 A1
(43) Pub. Date: Apr. 27, 2023

(54) RESIST PATTERN FORMATION METHOD

(71) Applicant: TOKYO OHKA KOGYO CO., LTD., Kawasaki-shi (JP)

(72) Inventor: Eiichi SHIMURA, Kawasaki-shi (JP)

(21) Appl. No.: 17/759,396

(22) PCT Filed: Feb. 9, 2021
(86) PCT No.: PCT/JP2021/004768

§ 371 Date: Jul. 25, 2022

(30) Foreign Application Priority Data
Feb. 21, 2020 (JP) 2020-028199

(51) Int. Cl. G03F 7/039; C08F 220/18; C08F 220/06; C08F 220/28

(52) U.S. Cl. CPC G03F 7/039; C08F 220/1808; C08F 220/06; C08F 220/281; C08F 220/1804

(57) ABSTRACT

A resist pattern formation method including forming a resist film on a support by using a resist composition; exposing the resist film; and subjecting the exposed resist film to alkali development to form a positive-tone resist pattern. The resist composition contains a first resin component and a second resin component. The first resin component contains a polymeric compound having a constitutional unit derived from acrylic acid in which a hydrogen atom bonded to a carbon atom at an α-position may be substituted with a substituent, and the second resin component contains a polymeric compound having both a constitutional unit containing a phenolic hydroxyl group and a constitutional unit containing an acid decomposable group having a polarity that is increased under action of acid.

### TECHNICAL FIELD

The present invention relates to a resist pattern formation method.

Priority is claimed on Japanese Patent Application No. 2020-028199, filed Feb. 21, 2020, the content of which is incorporated herein by reference.

### BACKGROUND ART

In lithography techniques, for example, a resist film formed from a resist material is formed on a substrate, and the resist film is subjected to selective exposure, followed by a developing treatment, whereby a process of forming a resist pattern having a predetermined shape on the resist film is carried out. A resist material in which exposed portions of the resist film become soluble in a developing solution is called positive-tone, and a resist material in which exposed portions of the resist film become insoluble in a developing solution is called negative-tone.

In recent years, in the manufacture of semiconductor elements, liquid crystal display devices, and electronic components, pattern fining has progressed rapidly, and the manufacture thereof is based on photofabrication.

The photofabrication is a general term for processing techniques with which various precision parts are manufactured, by using the patterned coating film as a mask and by forming a coating film on the surface of a processing object using a photosensitive resin composition (a resist composition), patterning the coating film with the photolithography technique, and then carrying out chemical etching, electrolytic etching, or electroforming mainly by electroplating, or the like.

In particular, in association with the downsizing of the electronic equipment, high-density mounting techniques for semiconductor packages have advanced, and multi-pin thin film mounting of packages, formation of fine rewires, and miniaturization of package size have been achieved. In addition, the heterogeneous integration by packaging and the system in a package (SiP) using packaging techniques such as Fan-Out, TSV, and 2.1D/2.5D/3D have been actively studied.

In order to respond to the above, it is required for the resist material to have lithography characteristics such as sensitivity to exposure light sources and resolution that can reproduce a fine-sized pattern, as well as characteristics being capable of being adapted to photolithography, for example, the resistance in the substrate processing such as chemical etching, electrolytic etching, or wet etching in a case of using the resist as a mask, the resistance to plating process such as electrolytic or non-electrolytic plating, and characteristics applicable to photofabrication, such as the resistance to the lift-off process.

As a resist material that satisfies these requirements, a chemical amplification-type resist composition that contains a base material component that exhibits changed solubility in a developing solution under action of acid, and an acid generator component that generates acid upon exposure has been conventionally used as the positive-tone resist (for example, see Patent Documents 1 and 2).

For example, in a case where the developing solution is an alkali developing solution (the alkali developing process), a positive-tone chemical amplification-type resist composition, which contains a resin component in which a site soluble in the alkali developing solution is protected by an acid dissociable and dissolution inhibitory group (a protecting group) to be made insoluble in the alkali developing solution and contains an acid generator component, is generally used. The reason why the resin component is used by being made to be insoluble in the alkali developing solution is that this is greatly related to the amount of residual film in unexposed portions.

In a case where a resist film that is formed using such a resist composition is selectively exposed at the time of the resist pattern formation, in light-exposed portions, an acid is generated from the acid generator component, and the deprotection reaction of the protecting group introduced in advance proceeds under the action of the acid, thereby making the light-exposed portions of the resist film soluble in the alkali developing solution. As a result, a positive-tone pattern in which the light-unexposed portions of the resist film remain as a pattern is formed by carrying out alkali development.

In such photofabrication, it is necessary to form a resist pattern on the surface of the support or the processing object at a required film thickness, depending on the use application and the like.

In such a case where rewires are formed in Fan-Out of a semiconductor package, for example, a resist film having a film thickness of about 3 μm is formed, a resist pattern is formed by exposure through a predetermined mask pattern and subsequent development, and then non-resist portions are subjected plating with a conductor such as copper to form a wire portion.

Alternatively, in a case where a bump or metal post of a semiconductor package is formed, for example, a resist film of about 60 μm is formed, a resist pattern is formed as above, and then non-resist portions are subjected plating with a conductor such as copper to form the bump or metal post.

Alternatively, in the photofabrication in semiconductor element processing, a film of a resist film having, for example, a film thickness of 8 μm or more may be formed on the surface of the processing object to form a resist pattern, and etching or the like may be carried out, depending on the use application.

### CITATION LIST

### Patent Documents

### [Patent Document 1]

Japanese Unexamined Patent Application, First Publication No. H04-211258

### [Patent Document 2]

Japanese Unexamined Patent Application, First Publication No. H11-52562

### SUMMARY OF INVENTION

### Technical Problem

In association with the further evolution of semiconductor element processing, diversification of semiconductor packages, and high integration, deeper etching of semiconductor elements, formation of fine wires, and a higher level of density of protruding electrodes or metal posts, and the like are required. In response to this demand, it is required to form a resist pattern having a high resolution, particularly regarding the resist composition, by which the reduction of the developed film is controlled with higher sensitivity and even a fine pattern can be formed without a residue.

However, in the method of forming a resist pattern using a chemically amplified positive-tone resist composition in the related art, there is a problem in terms of the residue in the vicinity of the substrate interface and the high sensitivity since it is necessary to contain, as a resist composition, a resin that is made to be insoluble in the alkali developing solution by protecting a site soluble in the alkali developing solution with an acid dissociable and dissolution inhibitory group (a protecting group) in order to suppress the dissolution of unexposed portions of the resist film (the reduction of the developed film) due to development.

The present invention has been made in consideration of the above circumstances, and an object of the present invention is to provide a resist pattern formation method, which is a novel method and by which the reduction of the developed film is suppressed, high sensitivity is achieved, and a residue is hardly generated.

### Solution to Problem

In the related art, a resin that is made to be insoluble in an alkali developing solution (an alkaline aqueous solution) by applying an acid dissociable group to a resin that is easily dissolved in the alkali developing solution has been used in the chemically amplified positive-tone resist composition.

In a case where there is a change in film thickness due to development (film reduction or swelling during development) in a state of a resin to which an acid dissociable group is applied, the resist pattern portion is affected in a case where the unexposed portions of the resist film are dissolved or swollen and in a case where the positive-tone resist composition is used.

The reduction of the developed film can be expressed by the dissolution rate (nm/s). The higher the dissolution rate in the alkali developing solution is, the greater the film reduction in the unexposed portions of the resist film during development is. On the other hand, the closer the dissolution rate in the alkali developing solution approaches zero, the smaller the film reduction in the unexposed portions of the resist film during development is. Further, a case where the dissolution rate in the alkali developing solution takes a negative value means that the resist film is swelled by the alkali developing solution during development, where the larger the negative absolute value is, the larger the swelling amount of the resist film is. As a result, in a case of focusing on the residual film of the resist pattern portion, it is favorable for the dissolution rate in the alkali developing solution to be small since it is desirable for the amount of film reduction to be small.

On the other hand, on a substrate having a height difference, or the like, at a place where the exposure amount is reduced, the residue after development tends to be problematic, and thus a margin (a residue margin) on the low exposure side is required. In particular, in a case where focusing on the residue after development, it is desirable that the dissolution rate in the alkali developing solution is high.

For controlling the solubility in an alkali developing solution to a desired value, there is known a method of controlling the introduction rate (the protection rate) of an acid dissociable group (a protecting group) that is introduced in the resin manufacturing stage; and a method of producing a resin in which the high protection rate is high (a resin in which the amount of film reduction is smaller than the predetermined reduction of the developed film) and a resin in which the protection rate is low (a resin in which the amount of film reduction is larger than the predetermined reduction of the developed film), and mixing the two resins so that the predetermined reduction of the developed film is achieved.

Further, a method of mixing resins differing in protecting group or monomer units themselves can be also included. In particular, for residue reduction, a method of mixing a resin in which the amount of film reduction is large and a different resin in which the amount of film reduction is small and using the obtained mixture is used. However, since the amount of film reduction after mixing these resins takes a value between the values of the used individual resins, there is a problem that it is difficult to achieve the balance between the amount of film reduction and the effect of residue reduction.

However, according to the studies of the inventors of the present invention, it has been newly found that in a case where a first resin component (P1) and a second resin component (P2) are mixed, there is a combination in which a value smaller than the dissolution rate of each single resin in an alkali developing solution is exhibited (that is, the mixed resins are made to be insoluble in an alkali developing solution than the first resin component (P1) and the second resin component (P2)).

It has been found that in a case where such a combination of resin components is selected, it is possible to use the first resin component (P1), which has been difficult so far to be used for the resist due to the high dissolution rate in the alkali developing solution, in a case where it is used in combination with the second resin component (P2), it is possible to prepare a chemically amplified positive-tone resist composition of which the dissolution rate in an alkali developing solution is lower than those of both the resins or with which the increase in the reduction of the developed film is suppressed, and in a case where this resin composition is employed, the above-described problems could be solved, and the present invention has completed.

That is, one aspect of the present invention is a resist pattern formation method characterized by including a step of forming a resist film on a support by using a resist composition that generates acid upon exposure and exhibits increased solubility in an alkaki developing solution under action of acid; a step of exposing the resist film; and a step of subjecting the exposed resist film to alkali development to form a positive-tone resist pattern,

in which the resist composition contains a first resin component (P1) and a second resin component (P2), the first resin component (P1) contains a polymeric compound (p10) having a constitutional unit (a0) derived from acrylic acid in which a hydrogen atom bonded to a carbon atom at an α-position may be substituted with a substituent, and the second resin component (P2) contains a polymeric compound (p20) having both a constitutional unit (u0) containing a phenolic hydroxyl group and a constitutional unit (u1) containing an acid decomposable group having a polarity that is increased under action of acid.

### Advantageous Effects of Invention

The present invention provides a novel method in which resins can be mixed with each other to be made insoluble in a developing solution, while resins that are highly soluble singly and are not insoluble in a developing solution are used. That is, according to the present invention, it is possible to provide a resist pattern formation method in which the reduction of the developed film is suppressed, the sensitivity is high, and the residue is hardly generated.

### DESCRIPTION OF EMBODIMENTS

In the present specification and the scope of the present claims, the term “aliphatic” is a relative concept used with respect to the term “aromatic” and defines a group or compound that has no aromaticity.

The “alkyl group” includes linear, branched, and cyclic monovalent saturated hydrocarbon groups, unless otherwise specified. The same applies to an alkyl group in an alkoxy group.

The “alkylene group” includes linear, branched, and cyclic divalent saturated hydrocarbon groups, unless otherwise specified.

The “halogenated alkyl group” is a group obtained by substituting part or all of hydrogen atoms of an alkyl group with a halogen atom. Examples of the halogen atom include a fluorine atom, a chlorine atom, a bromine atom, and an iodine atom.

The “fluorinated alkyl group” or a “fluorinated alkylene group” is a group obtained by substituting part or all of hydrogen atoms of an alkyl group or an alkylene group with a fluorine atom.

The “constitutional unit” indicates a monomer unit that constitutes the formation of a polymeric compound (a resin, a polymer, or a copolymer).

The description of “may have a substituent” means that a case where a hydrogen atom (—H) is substituted with a monovalent group or a case where a methylene (—CH₂—) group is substituted with a divalent group.

The “exposure” is used as a general concept that includes irradiation with any form of radioactive rays.

The “base material component” is an organic compound having a film forming ability, and an organic compound having a molecular weight of 500 or more is preferably used. In a case where the molecular weight of the organic compound is 500 or more, the film forming ability is improved, and in addition, a nano-level resist pattern is easily formed. The organic compounds used as the base material component are roughly classified into a non-polymer and a polymer. As the non-polymer, those having a molecular weight of 500 or more and less than 4,000 are generally used. Hereinafter, a “low molecular weight compound” refers to a non-polymer having a molecular weight of 500 or more and less than 4,000. As the polymer, those having a molecular weight of 1,000 or more are generally used. Hereinafter, a “resin”, a “polymeric compound”, or a “polymer” refers to a polymer having a molecular weight of 1,000 or more. As the molecular weight of the polymer, a polystyrene-equivalent weight average molecular weight determined by gel permeation chromatography (GPC) is used.

The “constitutional unit derived from acrylic acid ester” indicates a constitutional unit that is formed by the cleavage of the ethylenic double bond of acrylic acid ester.

The “acrylic acid ester” indicates a compound in which the terminal hydrogen atom of the carboxy group of acrylic acid (CH₂═CH—COOH) has been substituted with an organic group.

In the “acrylic acid ester”, the hydrogen atom bonded to the carbon atom at the α-position may be substituted with a substituent. The substituent that is substituted for a hydrogen atom bonded to the carbon atom at the α-position is an atom other than a hydrogen atom or a group, and examples thereof include an alkyl group having 1 to 5 carbon atoms and a halogenated alkyl group having 1 to 5 carbon atoms. Further, an itaconic acid diester in which “a hydrogen atom bonded to the carbon atom at the α-position” is substituted with a substituent having an ester bond and an α-hydroxyacryl ester in which “a hydrogen atom bonded to the carbon atom at the α-position” is substituted with a hydroxyalkyl group or a group obtained by modifying a hydroxyl group of the hydroxyalkyl group are also included in the acrylic acid ester. A carbon atom at the α-position of acrylic acid ester indicates the carbon atom bonded to the carbonyl group of acrylic acid unless otherwise specified.

Hereinafter, the acrylic acid ester obtained by substituting a hydrogen atom bonded to the carbon atom at the α-position with a substituent is also referred to as an α-substituted acrylic acid ester. In addition, an acrylic acid ester and an α-substituted acrylic acid ester may be collectively referred to as an “(α-substituted) acrylic acid ester”.

The “constitutional unit derived from acrylamide” indicates a constitutional unit that is formed by the cleavage of the ethylenic double bond of acrylamide.

In acrylamide, the hydrogen atom bonded to the carbon atom at the α-position may be substituted with a substituent, and one or both hydrogen atoms on the amino group of the acrylamide may be substituted with a substituent. The carbon atom at the α-position of acrylamide indicates the carbon atom bonded to the carbonyl group of acrylamide unless otherwise specified.

Examples of the substituent that is substituted for the hydrogen atom bonded to the carbon atom at the α-position of acrylamide include an alkyl group having 1 to 5 carbon atoms and a halogenated alkyl group having 1 to 5 carbon atoms.

The “constitutional unit derived from hydroxystyrene” indicates a constitutional unit that is formed by the cleavage of an ethylenic double bond of hydroxystyrene. The “constitutional unit derived from a hydroxystyrene derivative” indicates a constitutional unit formed by the cleavage of an ethylenic double bond of a hydroxystyrene derivative.

The “hydroxystyrene derivative” includes compounds in which the hydrogen atom at the α-position of hydroxystyrene has been substituted with another substituent such as an alkyl group or a halogenated alkyl group; and derivatives thereof. Examples of the derivatives thereof include hydroxystyrene in which the hydrogen atom of the hydroxyl group has been substituted with an organic group and may have the hydrogen atom at the α-position substituted with a substituent; and hydroxystyrene which has a substituent other than a hydroxyl group bonded to the benzene ring and may have the hydrogen atom at the α-position substituted with a substituent.

Here, the α-position (carbon atom at the α-position) indicates the carbon atom having the benzene ring bonded thereto unless otherwise specified.

Examples of the substituent that is substituted for the hydrogen atom at the α-position of hydroxystyrene include the same ones as those described above as the substituent for the α-position in the α-substituted acrylic acid ester.

The “constitutional unit derived from vinylbenzoic acid or a vinylbenzoic acid derivative” indicates a constitutional unit that is formed by the cleavage of the ethylenic double bond of vinylbenzoic acid or a vinylbenzoic acid derivative.

The “vinylbenzoic acid derivative” includes compounds in which the hydrogen atom at the α-position of vinylbenzoic acid has been substituted with another substituent such as an alkyl group or a halogenated alkyl group; and derivatives thereof. Examples of the derivatives thereof include vinylbenzoic acid in which the hydrogen atom of the carboxy group has been substituted with an organic group and may have the hydrogen atom at the α-position substituted with a substituent; and vinylbenzoic acid which has a substituent other than a hydroxyl group and a carboxy group bonded to the benzene ring and may have the hydrogen atom at the α-position substituted with a substituent. Here, the α-position (carbon atom at the α-position) indicates the carbon atom having the benzene ring bonded thereto unless otherwise specified.

The “styrene derivative” includes a compound obtained by substituting a hydrogen atom at the α-position of styrene with another substituent such as an alkyl group or a halogenated alkyl group; and a derivative thereof. Examples of the derivatives thereof include those obtained by bonding a substituent to a benzene ring of hydroxystyrene in which a hydrogen atom at the α-position may be substituted with a substituent. Here, the α-position (carbon atom at the α-position) indicates the carbon atom having the benzene ring bonded thereto unless otherwise specified.

The “constitutional unit derived from styrene” or the “constitutional unit derived from a styrene derivative” indicates a constitutional unit formed by cleavage of an ethylenic double bond of styrene or a styrene derivative.

The alkyl group as a substituent at the α-position is preferably a linear or branched alkyl group, and specific examples thereof include an alkyl group having 1 to 5 carbon atoms, such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group as the substituent at the α-position include a group obtained by substituting part or all hydrogen atoms of the above-described “alkyl group as the substituent at the α-position” with a halogen atom. Examples of the halogen atom include a fluorine atom, a chlorine atom, a bromine atom, and an iodine atom, where a fluorine atom is particularly preferable.

Specific examples of the hydroxyalkyl group as the substituent at the α-position include groups in which some or all hydrogen atoms of the above-described “alkyl group as the substituent at the α-position” are substituted with a hydroxyl group. The number of hydroxyl groups in the hydroxyalkyl group is preferably in a range of 1 to 5, and most preferably 1.

In the present specification and the scope of the present claims, asymmetric carbon atoms may be present, and thus enantiomers or diastereomers may be present depending on the structures represented by the chemical formula. In that case, these isomers are represented by one chemical formula. These isomers may be used alone or in the form of a mixture.

### (Resist Pattern Formation Method)

One aspect of the present invention is a resist pattern formation method characterized by including a step of forming a resist film on a support by using a resist composition that generates acid upon exposure and exhibits increased solubility in an alkali developing solution under action of acid; a step of exposing the resist film; and a step of subjecting the exposed resist film to alkali development to form a positive-tone resist pattern.

In the present aspect, a resist composition containing a first resin component (P1) and a second resin component (P2), each of which have a specific constitutional unit, is employed as the resist composition. Details in regard to this resist composition will be described later.

Examples of one embodiment of such a method of forming a resist pattern include a method of forming a resist pattern carried out as described below.

### [Step of Forming Resist Film on Support]

First, a resist composition containing a first resin component (P1) and a second resin component (P2), each of which have a specific constitutional unit, is prepared.

Next, this resist composition is applied onto a support, and heating (post-apply baking (PAB)) treatment is carried out to form a resist film.

As a method of applying a resist composition on a support, a spin coating method, a slit coating method, a roll coating method, a screen printing method, an applicator method, a spray coating method, an inkjet method, or the like can be employed. The conditions of the heating treatment may be appropriately determined depending on the kind and the blending proportion of each component in the resist composition, the thickness of the coating film, and the like, and examples thereof are conditions at 70° C. to 150° C. and preferably 80° C. to 140° C., and about for 1° C. to 60 minutes.

It is noted that, instead of directly applying a resist composition onto a support, the resist composition may be applied in advance in a film shape or the like by the above-described coating method or the like, and an appropriate heating step may be carried out to produce a film-shaped coating film (a dry film), and then this dry film may be attached to a support and used.

The film thickness of the resist film is, for example, in a range of 1 to 250 μm, preferably 1 to 100 μm, more preferably 1 to 80 μm, and still more preferably 2 to 65 μm.

The support is not particularly limited, and any one known in the related art can be used. Examples thereof include substrates for electronic components and substrates having predetermined wiring patterns formed thereon. Examples of the substrate include a substrate made of a metal such as silicon, silicon nitride, titanium, tantalum, palladium, titanium tungsten, copper, chromium, iron, aluminum, or gold, and a glass substrate or organic material substrates on which a metal thin film is laminated. In particular, in the present embodiment, a resist pattern can be favorably formed even on a copper substrate. As the material for the wiring pattern, for example, copper, solder, chromium, aluminum, nickel, gold, or the like is used.

### [Step of Exposing Resist Film]

Next, through a mask having a predetermined pattern or by using an apparatus capable of drawing directly without using a mask, the resist film formed on the support is selectively irradiated (exposed) with radioactive rays including electromagnetic waves or particle beams, for example, ultraviolet rays or visible light having a wavelength in a range of 240 to 500 nm.

As the radiation source of the radioactive rays, a low-pressure mercury lamp, a high-pressure mercury lamp, an ultra-high-pressure mercury lamp, a metal halide lamp, an argon gas laser, an excimer laser, a light emitting diode (LED), or the like can be used. Further, the radioactive rays include microwaves, infrared rays, visible rays, ultraviolet rays, X-rays, γ-rays, electron beams, proton beams, neutron beams, and ion beams. The irradiation dose of radioactive rays may be appropriately determined depending on the kind and the blending amount of each component in the resist composition, the film thickness of the coating film, and the like. Further, radioactive rays also include beams of light that activate an acid generator to generate acid.

Next, after the resist film is exposed, the acid diffusion and the deprotection of the acid dissociable group (the protecting group) are promoted preferably by carrying out heating (post-exposure baking (PEB)) treatment using a known method, whereby the alkali solubility of the exposed portions of the resist film is changed. Here, the conditions of the heating treatment may be appropriately determined depending on the kind of each component in the resist composition, the blending proportion, the thickness of the coating film, and the like, and preferred examples thereof are conditions at 80° C. to 150° C. and about for 1° C. to 60 minutes.

### [Step of Subjecting Exposed Resist Film to Alkali Development]

Next, unnecessary portions are dissolved and removed, for example, by using an alkaline aqueous solution as a developing solution, whereby a predetermined positive-tone resist pattern is obtained.

As the developing solution, it is possible to use an aqueous solution of alkalis such as sodium hydroxide, potassium hydroxide, sodium carbonate, sodium silicate, sodium metasilicate, aqueous ammonia, ethylamine, n-propylamine, diethylamine, di-n-propylamine, triethylamine, methyl diethylamine, dimethyl ethanolamine, triethanolamine, tetramethylammonium hydroxide (TMAH), tetraethylammonium hydroxide, pyrrole, piperidine, 1,8-diazabicyclo[5,4,0]-7-undecene, and 1,5-diazabicyclo[4,3,0]-5-nonane.

The concentration of alkalis in the developing solution may be appropriately set depending on the kind of resin. For example, in a case of a TMAH aqueous solution, it is preferably 0.75% to 5% by mass and more preferably 2% to 3% by mass.

Further, as the developing solution, it is also possible to use an aqueous solution obtained by adding a proper amount of a water-soluble organic solvent such as methanol or ethanol or a surfactant to the above-described aqueous solution of alkalis.

The concentration of the surfactant in the developing solution is, for example, preferably 0.02% to 2.5% by mass.

The alkali development time may be appropriately determined depending on the kind and the blending proportion of each component in the resist composition, and the thickness of the dry film of the composition, and it is preferably 0.5 to 30 minutes.

Further, the alkali development method may be any one of a liquid filling method, a dipping method, a puddle method, a spray development method, and the like. After the alkali development, as necessary, washing with running water may be carried out, for example, for 30 to 90 seconds, and drying may be carried out using a spin drying method, an air gun, an oven, or the like.

In a case of embedding, by plating or the like, a conductor such as a metal in the non-resist portions (the portions removed by the alkali developing solution) of the resist pattern obtained as described above, it is possible to form conductive structure bodies such as a wire, a metal post, and a bump.

The plating treatment method is not particularly limited, and various methods known in the related art can be employed. As a plating solution, a solder plating solution, a copper plating solution, a gold plating solution, or a nickel plating solution is particularly preferably used. Finally, the remaining resist pattern is removed using a stripping solution or the like according to a conventional method. Alternatively, it is possible to carry out substrate processing such as chemical etching, electrolytic etching, or wet etching in a case of using, as a mask, the resist pattern obtained as described above.

### <Resist Composition>

The resist composition that is used in the resist pattern formation method according to the present embodiment is a resist composition that generates acid upon exposure and exhibits increased solubility in an alkali developing solution under action of acid.

The resist composition contains a resin component (P) (hereinafter, also referred to as a “component (P)”) exhibiting increased solubility in a developing solution under action of acid.

Examples of the resist composition in the present embodiment include a resist composition containing the component (P) and an acid generator component (hereinafter, also referred to as “component (B)”) that generates acid upon exposure.

In a case where a resist film is formed using the resist composition and the formed resist film is subjected to selective exposure, an acid is generated at exposed portions of the resist film, and the acid acts on the resin component to change the solubility of the resin component in a developing solution, whereas the solubility of the resin component in a developing solution is not changed at unexposed portions of the resist film, which generates the difference in solubility in the developing solution between exposed portions and unexposed portions of the resist film. As a result, in the present embodiment, in a case where the resist film is subjected to alkali development, exposed portions of the resist film are dissolved and removed to form a positive-tone resist pattern.

### <<Component (P): Resin Component>>

In the present embodiment, the resin component (P) (the component (P)) includes a least a first resin component (P1) (hereinafter, also referred to as a “component (P1)”) and a second resin component (P2) (hereinafter, also referred to as a “component “P2)”).

In regard to first resin component (P1):

In the present embodiment, the first resin component (P1) (the component (P1)) contains a polymeric compound (p10) (hereinafter, also referred to as “a component (p10)”) that has a constitutional unit (a0) derived from acrylic acid in which a hydrogen atom bonded to a carbon atom at an α-position may be substituted with a substituent.

The component (p10) may be a component having another constitutional unit as necessary in addition to the constitutional unit (a0).

### Constitutional Unit (a0)

The constitutional unit (a0) preferably a constitutional unit derived from acrylic acid in which the hydrogen atom bonded to the carbon atom at the α-position may be substituted with a substituent.

The “constitutional unit derived from acrylic acid” indicates a constitutional unit that is formed by the cleavage of the ethylenic double bond of acrylic acid.

In the “acrylic acid” referred to here, the hydrogen atom bonded to the carbon atom at the α-position may be substituted with a substituent. The substituent that is substituted for a hydrogen atom bonded to the carbon atom at the α-position is an atom other than a hydrogen atom or a group, and examples thereof include an alkyl group having 1 to 5 carbon atoms and a halogenated alkyl group having 1 to 5 carbon atoms. It is noted that the carbon atom at the α-position of acrylic acid indicates the carbon atom bonded to the carbonyl group of acrylic acid unless otherwise specified.

Preferred specific examples of such a constitutional unit (a0) include a constitutional unit represented by General Formula (a0-0) shown below.

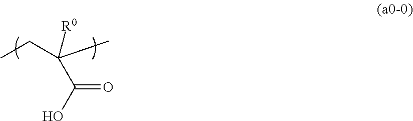

[In the formula, R⁰ represents a hydrogen atom, an alkyl group having 1 to 5 carbon atoms, or a halogenated alkyl group having 1 to 5 carbon atoms.]

In General Formula (a0-0), R⁰ represents a hydrogen atom, an alkyl group having 1 to 5 carbon atoms, or a halogenated alkyl group having 1 to 5 carbon atoms.

The alkyl group having 1 to 5 carbon atoms as R⁰ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group obtained by substituting part or all hydrogen atoms in the alkyl group having 1 to 5 carbon atoms with a halogen atom. Examples of the halogen atom include a fluorine atom, a chlorine atom, a bromine atom, and an iodine atom, where a fluorine atom is particularly preferable.

R⁰ is preferably a hydrogen atom, an alkyl group having 1 to 5 carbon atoms, or a fluorinated alkyl group having 1 to 5 carbon atoms, and particularly preferably a hydrogen atom or a methyl group in terms of industrial availability. That is, it is preferably acrylic acid or methacrylic acid.

The constitutional unit (a0) contained in the component (p10) may be one kind or may be two or more kinds.

The proportion of the constitutional unit (a0) in the component (p10) is preferably in a range of 5% to 40% by mole, more preferably in a range of 5% to 30% by mole, and still more preferably in a range of 10% to 25% by mole, with respect to the total (100% by mole) of all constitutional units constituting the component (p10).

In a case where the proportion of the constitutional unit (a0) is equal to or larger than the lower limit value, the characteristics such as sensitivity and residue reduction are improved. In addition, in a case where it is equal to or smaller than the upper limit value of the preferred range, the balance with other constitutional units can be achieved.

In regard to other constitutional units:

Such a component (p10) may be a component having another constitutional unit as necessary in addition to the constitutional unit (a0).

Examples of the other constitutional units include a constitutional unit (a1) derived from an acrylic acid ester in which a hydrogen atom bonded to a carbon atom at an α-position may be substituted with a substituent and is a constitutional unit containing an acid decomposable group having a polarity that is increased under action of acid; and a constitutional unit (a2) derived from a polymerizable compound having an ether bond.

### Constitutional Unit (a1)

The constitutional unit (a1) is a constitutional unit derived from an acrylic acid ester in which a hydrogen atom bonded to a carbon atom at an α-position may be substituted with a substituent and is a constitutional unit containing an acid decomposable group having a polarity that is increased under action of acid whereby the solubility in an alkali developing solution is improved.

The “acid decomposable group” is a group having an acid decomposable group in which at least part of bonds in the structure of the acid decomposable group can be cleaved under action of acid.

Examples of the acid decomposable group having a polarity that is increased under action of acid include groups which are decomposed under action of acid to generate a polar group.

Examples of the polar group include a carboxy group and a sulfo group (—SO₃H). Among these, a carboxy group is preferable.

More specific examples of the acid decomposable group include a group (for example, a group obtained by protecting a hydrogen atom of the carboxy group with an acid dissociable group) obtained by protecting the above-described polar group with an acid dissociable group.

Here, the “acid dissociable group” indicates any one of (i) a group in which a bond between the acid dissociable group and an atom adjacent to the acid dissociable group can be cleaved under action of acid; and (ii) a group in which part of bonds are cleaved under action of acid, and then a decarboxylation reaction occurs, thereby cleaving the bond between the acid dissociable group and the atom adjacent to the acid dissociable group.

The acid dissociable group is not particularly limited, and it is possible to use those which have been proposed so far as acid dissociable groups of the base resin for a chemical amplification-type resist.

Among the above polar groups, examples of the acid dissociable group that protects the carboxy group include an acid dissociable group represented by General Formula (a1-r-1) (hereinafter referred to as an “acetal-type acid dissociable group”) and an acid dissociable group represented by General Formula (a1-r-2) (among the acid dissociable groups represented by General Formula (a1-r-2), hereinafter, an acid dissociable group composed of an alkyl group may be referred to as, for convenience, a “tertiary alkyl ester-type acid dissociable group”).

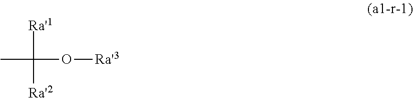

[In the formula, Ra′¹ and Ra′² represent a hydrogen atom or an alkyl group, Ra′³ represents a hydrocarbon group, and Ra′³ may be bonded to any of Ra′¹ or Ra′² to form a ring.]

In regard to acid dissociable group represented by General Formula (a1-r-1)

In General Formula (a1-r-1), it is preferable that at least one of Ra′¹ and Ra′² represents a hydrogen atom and more preferable that both of them represent a hydrogen atom.

In a case where Ra′¹ or Ra′² represents an alkyl group, examples of the alkyl group include the same one as the alkyl group mentioned as the substituent which may be bonded to the carbon atom at the α-position, in the explanation of the α-substituted acrylic acid ester, and the alkyl group preferably has 1 to 5 carbon atoms. Specific examples thereof include linear or branched alkyl groups such as a methyl group, an ethyl group, a propyl group, an isopropyl group, an n-butyl group, an isobutyl group, a tert-butyl group, a pentyl group, an isopentyl group, and a neopentyl group, and a methyl group or an ethyl group is preferable, and a methyl group is particularly preferable.

In General Formula (a1-r-1), examples of the hydrocarbon group as Ra′³ include a linear alkyl group, a branched alkyl group, and a cyclic alkyl group. The linear alkyl group has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group has preferably 3 to 10 carbon atoms and more preferably 3 to 5 carbon atoms. Specific examples thereof include an isopropyl group, an isobutyl group, a tert-butyl group, an isopentyl group, and a neopentyl group, and an isopropyl group is most preferable.

The cyclic alkyl group has preferably 3 to 20 carbon atoms and more preferably 4 to 12 carbon atoms. Specific examples thereof include a monocycloalkane such as cyclopentane or cyclohexane; and a group obtained by removing one or more hydrogen atoms from a polycycloalkane such as adamantane, norbornane, isobornane, tricyclodecane, or tetracyclododecane. A part of carbon atoms constituting the ring of the cyclic alkyl group may be substituted with an ethereal oxygen atom (—O—).

In a case where Ra′³ is bonded to any one of Ra′¹ or Ra′² to form a ring, the cyclic group is preferably a 4-membered to 7-membered ring, and more preferably a 4-membered to 6-membered ring. Specific examples of the cyclic group include a tetrahydropyranyl group and a tetrahydrofuranyl group.

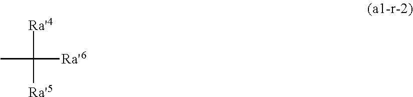

[In the formula, Ra′⁴ to Ra′⁶ each represent a hydrocarbon group, and Ra′⁵ and Ra′⁶ may be bonded to each other to form a ring.]

In regard to acid dissociable group represented by General Formula (a1-r-2)

In General Formula (a1-r-2), examples of the hydrocarbon group as Ra′⁴ to Ra′⁶ include the same one as Ra′³.

Ra′⁴ is preferably an alkyl group having 1 to 5 carbon atoms. In a case where Ra′⁵ and Ra′⁶ are bonded to each other to form a ring, examples thereof include a group represented by General Formula (a1-r2-1). On the other hand, in a case where Ra′⁴ to Ra′⁶ are not bonded to each other and represent an independent hydrocarbon group, examples thereof include a group represented by General Formula (a1-r2-2).

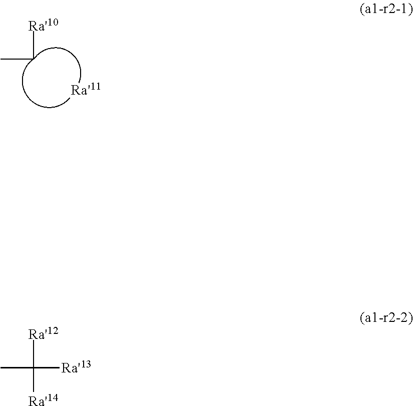

[In the formula, Ra′¹⁰ represents an alkyl group having 1 to 10 carbon atoms, Ra′¹¹ represents a group forming an aliphatic cyclic group together with the carbon atom to which Ra′¹⁰ is bonded, and Ra′¹² to Ra′¹⁴ each independently represent a hydrocarbon group.]

In General Formula (a1-r2-1), the alkyl group in the alkyl group having 1 to 10 carbon atoms as Ra′¹⁰ is preferably the groups mentioned as the linear or branched alkyl group as Ra′³ in General Formula (a1-r-1). In General Formula (a1-r2-1), the aliphatic cyclic group composed of Ra′¹¹ is preferably the group mentioned as the cyclic alkyl group as Ra′³ in General Formula (a1-r-1).

In General Formula (a1-r2-2), Ra′¹² and Ra′¹⁴ are each independently preferably an alkyl group having 1 to 10 carbon atoms, and the alkyl group is more preferably the group exemplified as a linear or branched alkyl group as Ra′³ in General Formula (a1-r-1), still more preferably a linear alkyl group having 1 to 5 carbon atoms, and particularly preferably a methyl group or an ethyl group.

In General Formula (a1-r2-2), Ra′¹³ is preferably a linear, branched, or cyclic alkyl group exemplified as the hydrocarbon group as Ra′³ in General Formula (a1-r-1). Among the above, it is preferably the group mentioned as the cyclic alkyl group as Ra′³.

Specific examples of General Formula (a1-r2-1) are shown below.

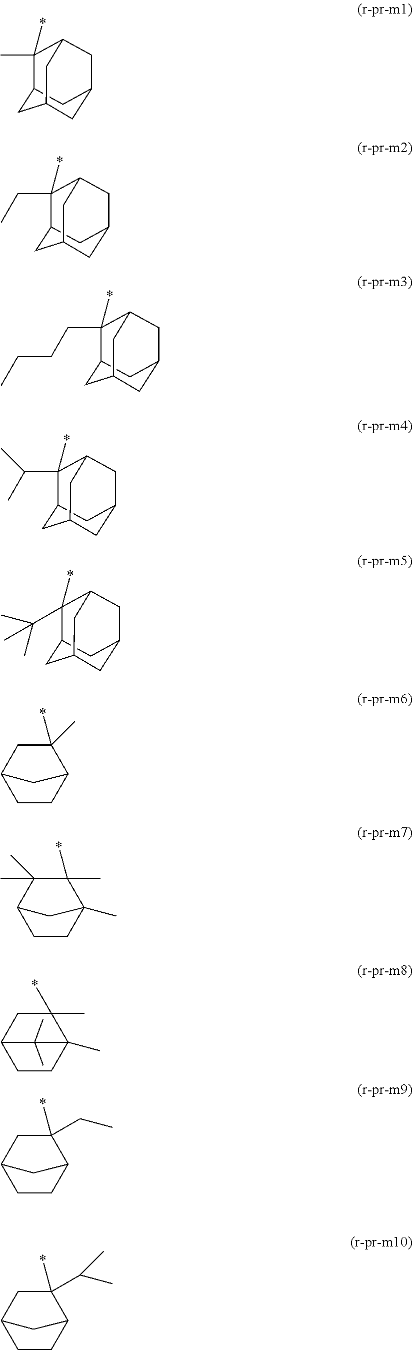

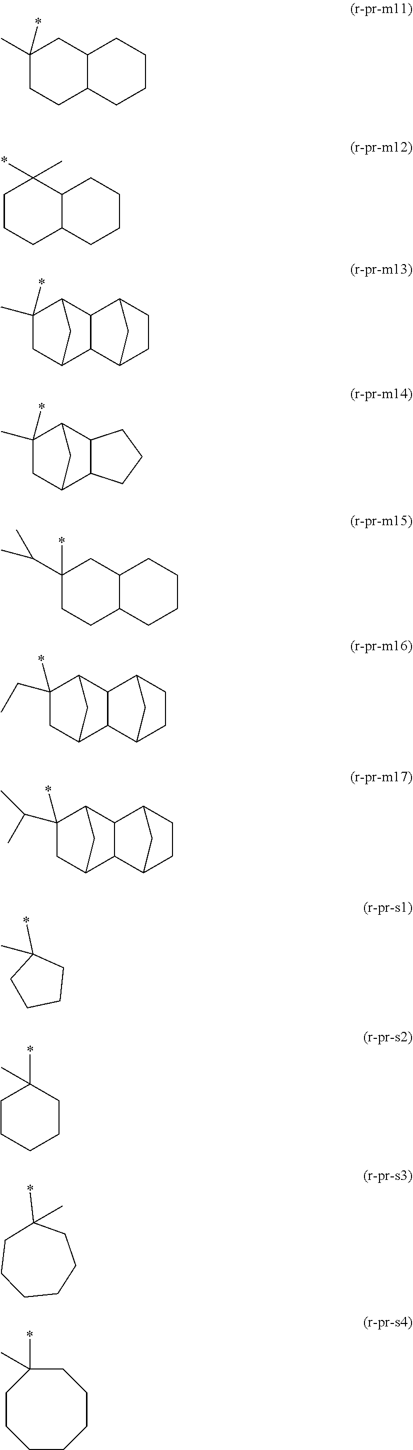

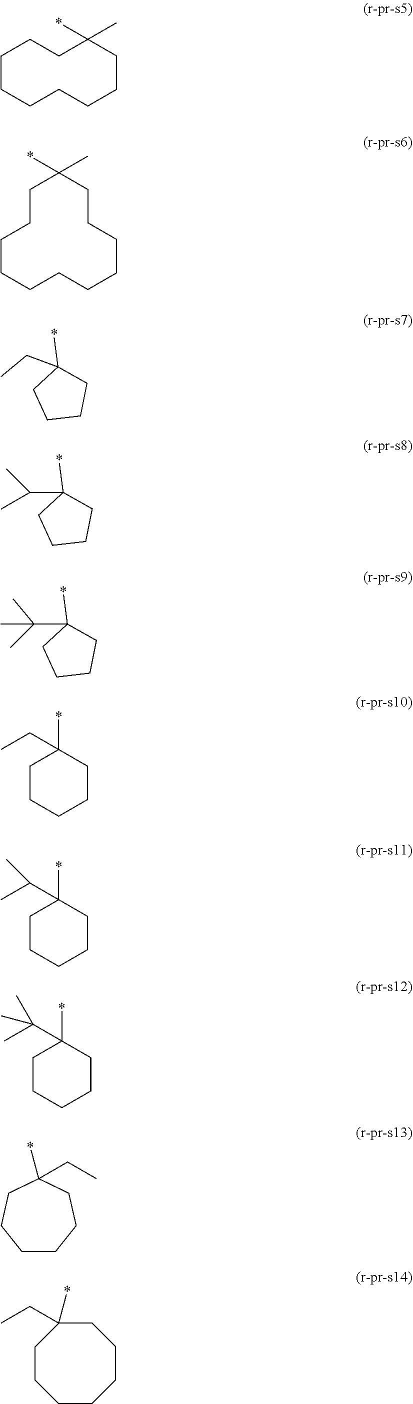

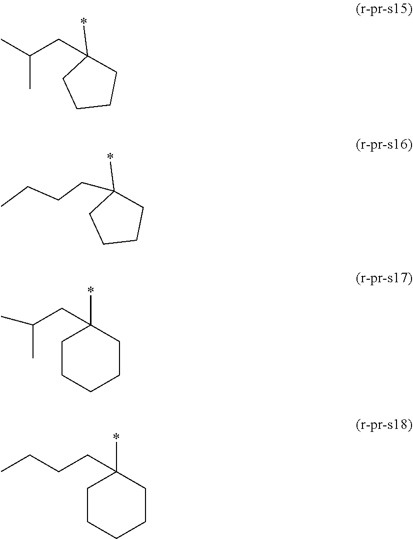

Specific examples of General Formula (a1-r2-2) are shown below.

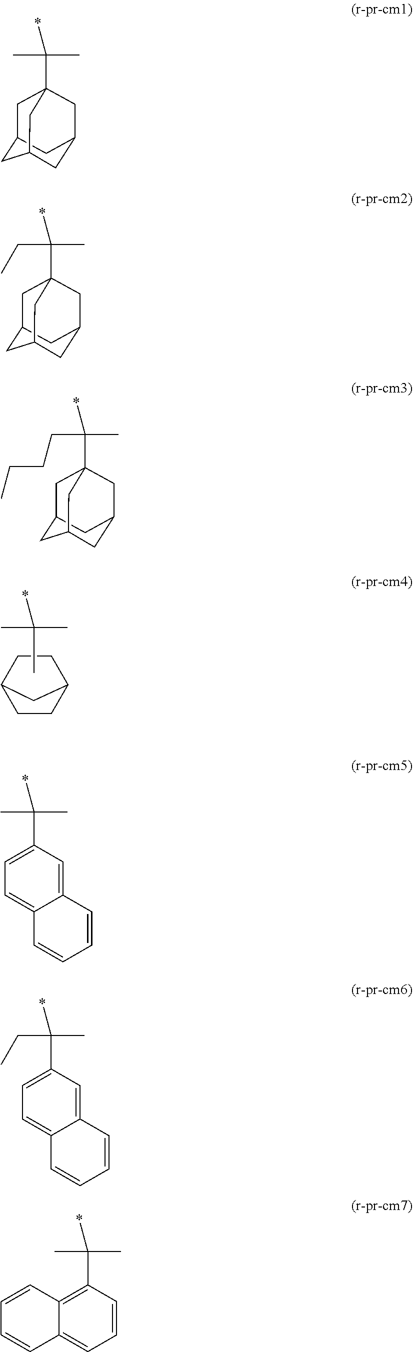

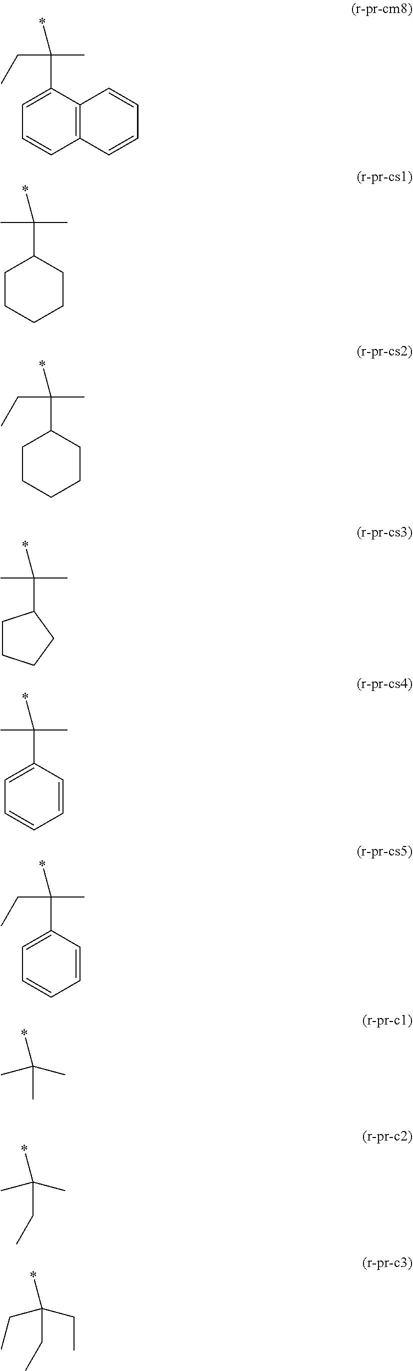

Preferred specific examples of such a constitutional unit (a1) include constitutional units represented by General Formula (a1-1) shown below.

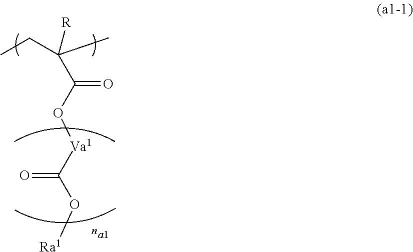

[In the formula, R represents a hydrogen atom, an alkyl group having 1 to 5 carbon atoms, or a halogenated alkyl group having 1 to 5 carbon atoms. Va¹ is a divalent hydrocarbon group which may have an ether bond, a urethane bond, or an amide bond. Each nₐ₁ is independently in a range of 0 to 2. Ra¹ is an acid dissociable group represented by General Formula (a1-r-1) or (a1-r-2).]

In General Formula (a1-1), the alkyl group having 1 to 5 carbon atoms is preferably linear or branched, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms is a group obtained by substituting part or all hydrogen atoms in the alkyl group having 1 to 5 carbon atoms with a halogen atom. Examples of the halogen atom include a fluorine atom, a chlorine atom, a bromine atom, and an iodine atom, where a fluorine atom is particularly preferable.

R is preferably a hydrogen atom, an alkyl group having 1 to 5 carbon atoms, or a fluorinated alkyl group having 1 to 5 carbon atoms, and most preferably a hydrogen atom or a methyl group in terms of industrial availability.

The divalent hydrocarbon group as Va¹ may be an aliphatic hydrocarbon group or an aromatic hydrocarbon group. The aliphatic hydrocarbon group indicates a hydrocarbon group that has no aromaticity. The aliphatic hydrocarbon group as the divalent hydrocarbon group represented by Va¹ may be saturated or unsaturated. In general, it is preferable that the aliphatic hydrocarbon group is saturated.

More specific examples of the aliphatic hydrocarbon group include a linear or branched aliphatic hydrocarbon group and an aliphatic hydrocarbon group containing a ring in the structure thereof.

In addition, examples of Va¹ include those in which the divalent hydrocarbon group is bonded through an ether bond, a urethane bond, or an amide bond.

The linear or branched aliphatic hydrocarbon group has preferably 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

Examples of the aliphatic hydrocarbon group containing a ring in the structure thereof include an alicyclic hydrocarbon group (a group obtained by removing two hydrogen atoms from an aliphatic hydrocarbon ring), a group obtained by bonding an alicyclic hydrocarbon group to the terminal of a linear or branched aliphatic hydrocarbon group, and a group obtained by interposing an alicyclic hydrocarbon group in the middle of a linear or branched aliphatic hydrocarbon group. Examples of the linear or branched aliphatic hydrocarbon group include the same ones as the linear or branched aliphatic hydrocarbon groups exemplified in the description of the aliphatic hydrocarbon group as the divalent hydrocarbon group as Va¹.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples thereof include adamantane, norbornane, isobornane, tricyclodecane, and tetracyclododecane.

The aromatic hydrocarbon group represents a hydrocarbon group having an aromatic ring.

The aromatic hydrocarbon group as divalent hydrocarbon group as Va¹ preferably has 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. However, the number of carbon atoms in the substituent is not included in the number of carbon atoms.

Specific examples of the aromatic ring contained in the aromatic hydrocarbon group include aromatic hydrocarbon rings such as benzene, biphenyl, fluorene, naphthalene, anthracene, and phenanthrene; and an aromatic heterocyclic ring obtained by substituting part of carbon atoms constituting the above-described aromatic hydrocarbon rings with a hetero atom. Examples of the hetero atom in the aromatic heterocyclic rings include an oxygen atom, a sulfur atom, and a nitrogen atom.

Specific examples of the aromatic hydrocarbon group include a group (an arylene group) obtained by removing two hydrogen atoms from the above-described aromatic hydrocarbon ring; a group obtained by substituting one hydrogen atom of a group (an aryl group) obtained by removing one hydrogen atom from the aromatic hydrocarbon ring with an alkylene group (for example, a group obtained by removing one hydrogen atom from an aryl group in an arylalkyl group such as a benzyl group, a phenethyl group, a 1-naphthylmethyl group, a 2-naphthylmethyl group, a 1-naphthylethyl group, or a 2-naphthylethyl group); and a group obtained by removing two hydrogen atoms from an aromatic compound (for example, biphenyl or fluorene) containing two or more aromatic rings. The alkylene group (an alkyl chain the arylalkyl group) preferably has 1 to 4 carbon atoms, more preferably 1 or 2 carbon atoms, and particularly preferably 1 carbon atom.

In General Formula (a1-1), Ra¹ is preferably an acid dissociable group represented by General Formula (a1-r-2).

Specific examples of General Formula (a1-1) are shown below. In each of the formulae shown below, R^{α}represents a hydrogen atom, a methyl group, or a trifluoromethyl group.

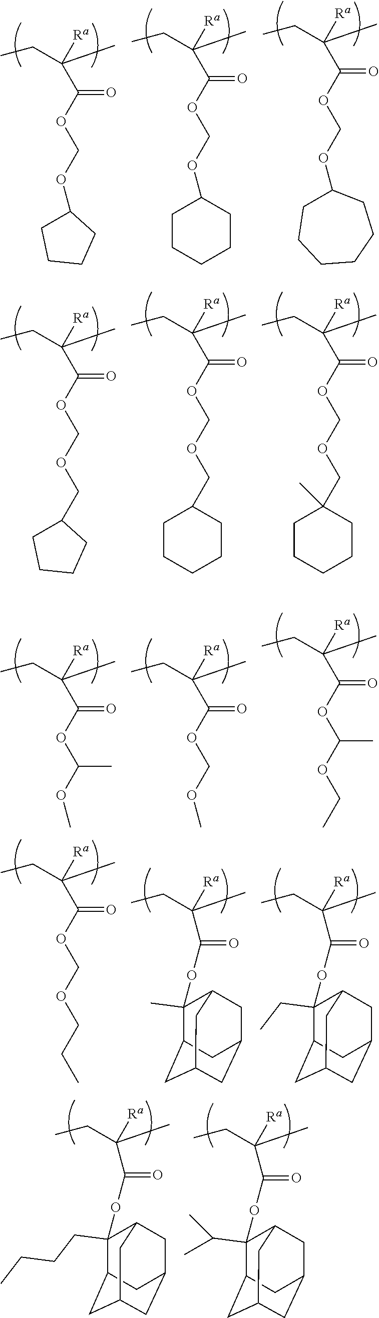

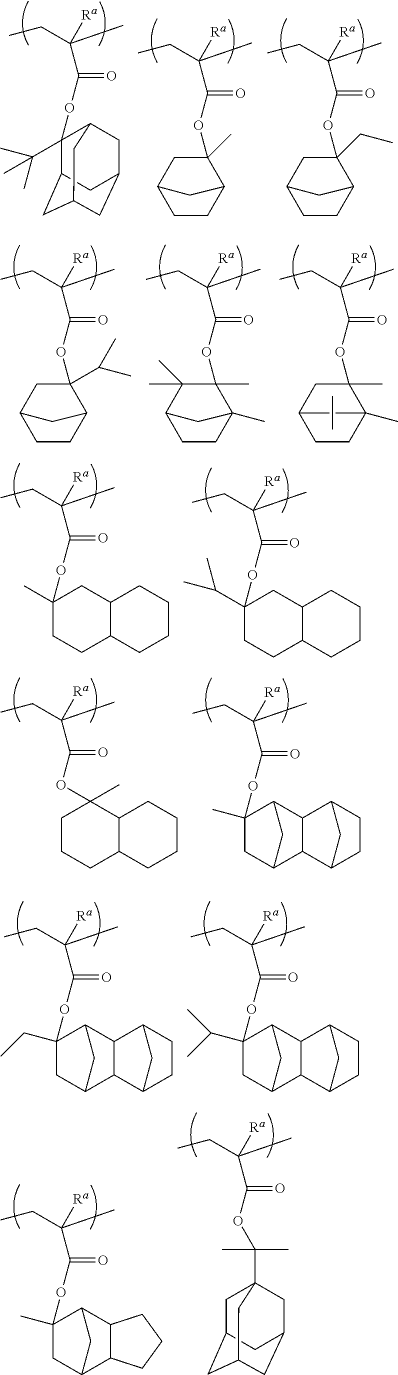

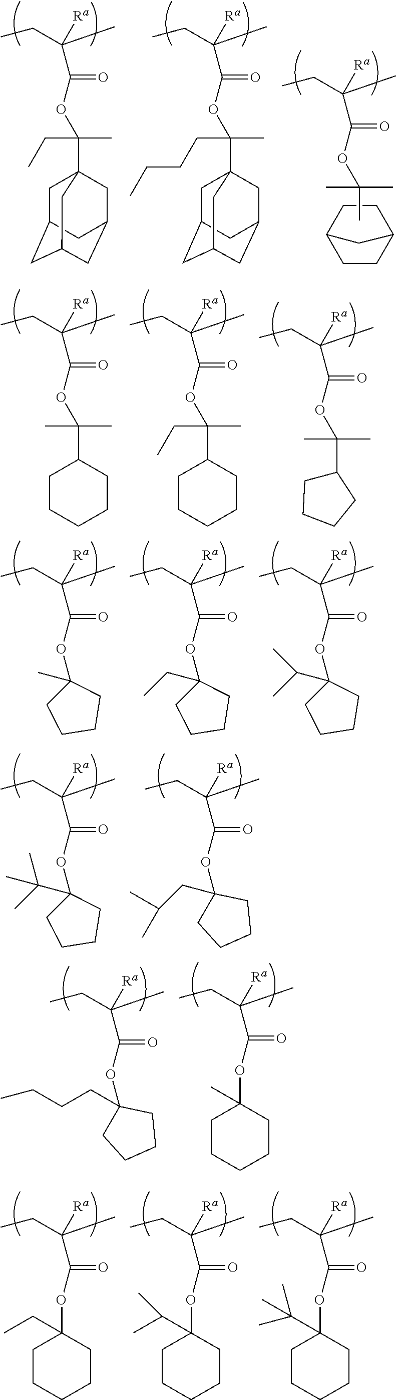

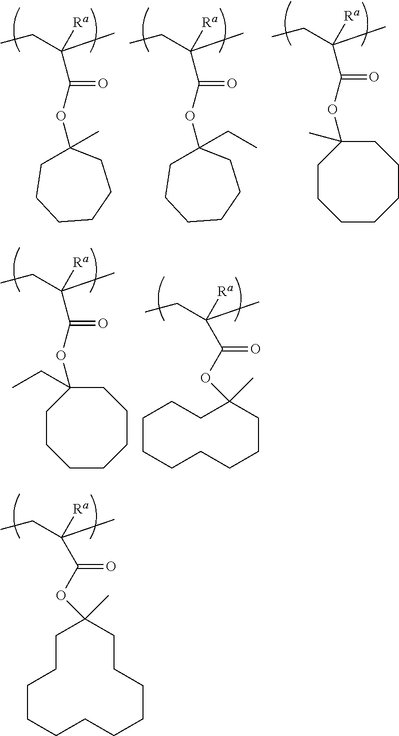

The constitutional unit (a1) contained in the component (p10) may be one kind or may be two or more kinds.

In a case where the component (p10) has the constitutional unit (a1), the proportion of the constitutional unit (a1) in the component (p10) is preferably in a range of 5% to 95% by mole, more preferably in a range of 10% to 80% by mole, and still more preferably in a range of 15% to 60% by mole, with respect to the total (100% by mole) of all constitutional units constituting the component (p10).

In a case where the proportion of the constitutional unit (a1) is equal to or larger than the lower limit value of the preferred range, a resist pattern can be easily obtained, and the characteristics such as resolution are improved. In addition, in a case where it is equal to or smaller than the upper limit value of the preferred range, the balance with other constitutional units can be achieved.

### Constitutional Unit (a2)

The constitutional unit (a2) is a constitutional unit derived from a polymerizable compound having an ether bond.

Examples of the above-described polymerizable compound having an ether bond include a radically polymerizable compound such as a (meth)acrylic acid derivative having an ether bond and an ester bond, and specific examples thereof include 2-methoxyethyl (meth)acrylate, 2-ethoxyethyl (meth)acrylate, methoxytriethylene glycol (meth)acrylate, 3-methoxybutyl (meth)acrylate, ethylcarbitol (meth)acrylate, phenoxypolyethylene glycol (meth)acrylate, methoxypolypropylene glycol (meth)acrylate, tetrahydrofurfuryl (meth)acrylate.

Here, the above-described polymerizable compound having an ether bond is preferably 2-methoxyethyl (meth)acrylate, 2-ethoxyethyl (meth)acrylate, or methoxytriethylene glycol (meth)acrylate. This polymerizable compound may be used alone, or two or more kinds thereof may be used in combination.

Such a component (p10) ca further contain a constitutional unit derived from another polymerizable compound for the intended purpose of properly controlling physical or chemical characteristics.

Examples of such a polymerizable compound include a known radically polymerizable compound and an anionic polymerizable compound. Examples of such polymerizable compounds include monocarboxylic acids such as crotonic acid; dicarboxylic acids such as maleic acid, fumaric acid, and itaconic acid; methacrylic acid derivatives having a carboxyl group and an ester bond, such as 2-methacryloyloxyethyl succinic acid, 2-methacryloyloxyethyl maleic acid, 2-methacryloyloxyethyl phthalic acid, and 2-methacryloxyethyl hexahydrophthalic acid; (meth)acrylic acid alkyl esters such as methyl (meth)acrylate, ethyl (meth)acrylate, and butyl (meth)acrylate; (meth)acrylic acid hydroxyalkyl esters such as 2-hydroxyethyl (meth)acrylate and 2-hydroxypropyl (meth)acrylate; (meth)acrylic acid aryl esters such as phenyl (meth)acrylate and benzyl (meth)acrylate; dicarboxylic acid diesters such as diethyl maleate and dibutyl fumarate; vinyl group-containing aromatic compounds such as styrene, α-methyl styrene, chlorostyrene, chloromethyl styrene, vinyl toluene, hydroxystyrene, α-methyl hydroxystyrene, α-ethyl hydroxystyrene; vinyl group-containing aliphatic compounds such as vinyl acetate; conjugate diolefins such as butadiene and isoprene; nitrile group-containing polymerizable compound such as acrylonitrile and methacrylonitrile; chlorine-containing polymerizable compounds such as vinyl chloride and vinylidene chloride; and amide bond-containing polymerizable compounds such as acrylamide and methacrylamide.

Such a component (p10) may further have a constitutional unit (a4) containing an acid non-dissociable cyclic group, as necessary. It is conceived that in a case where the component (p10) has the constitutional unit (a4), the dry etching resistance, heat resistance, or plating resistance of the resist pattern to be formed is improved.

The “acid non-dissociable cyclic group” in the constitutional unit (a4) is a cyclic group that remains in the constitutional unit as it is without being dissociated even in a case where an acid generated upon exposure acts on it.

Examples of the constitutional unit (a4) preferably include a constitutional unit derived from an acrylic acid ester including an acid non-dissociable aliphatic cyclic group. As the cyclic group, a large number of cyclic groups known in the related art can be used as those that are used for the resin component of the resist composition.

It is preferable to be at least one selected from a tricyclodecyl group, an adamantyl group, a tetracyclododecyl group, an isobornyl group, and a norbornyl group, from the viewpoint of industrial availability. These polycyclic groups may have, as a substituent, a linear or branched alkyl group having 1 to 5 carbon atoms.

Specific examples of the constitutional unit (a4) include a constitutional unit having any structure of General Formulae (a4-1) to (a4-7).

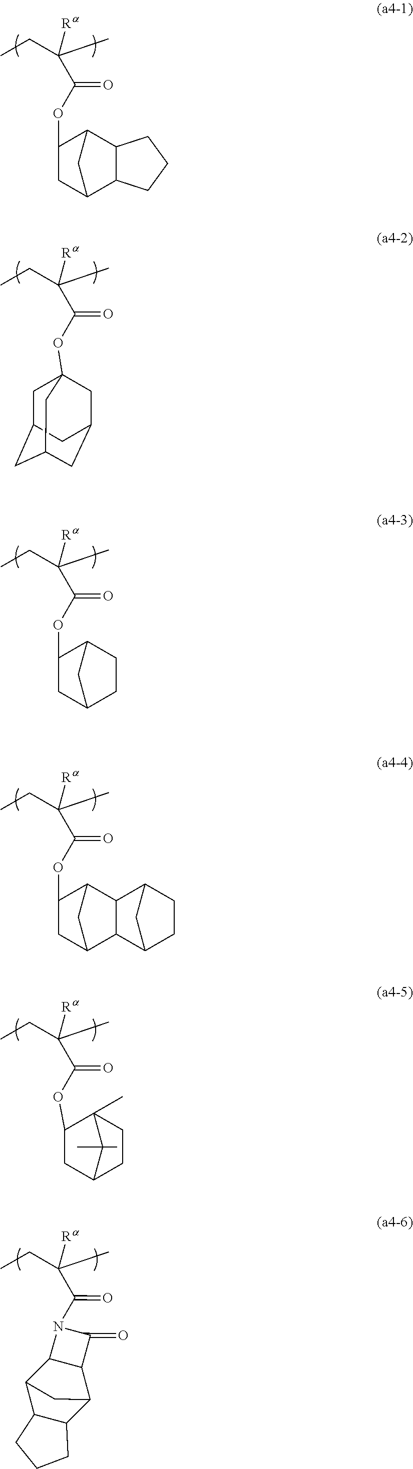

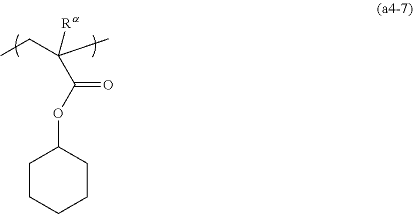

[In the formula, R^{α}is the same as above.]

The constitutional unit (a4) contained in the component (p10) may be one kind or may be two or more kinds.

The component (P1) that is used in the resist composition in the present embodiment is a component containing a polymeric compound (p10) having a constitutional unit (a0).

The component (p10) is preferably a polymeric compound having a constitutional unit (a0) and a constitutional unit (a1); a polymeric compound having a constitutional unit (a0) and a constitutional unit (a2); or a polymeric compound having a constitutional unit (a0) and a constitutional unit derived from a (meth)acrylic acid alkyl ester.

Examples of the component (p10) more preferably include a polymeric compound having a constitutional unit (a0), a constitutional unit (a1), a constitutional unit (a2), and a constitutional unit derived from a (meth)acrylic acid alkyl ester; and a polymeric compound having a constitutional unit (a0), a constitutional unit (a2), and a constitutional unit derived from a (meth)acrylic acid alkyl ester.

The weight average molecular weight (Mw) (based on the polystyrene equivalent value determined by gel permeation chromatography (GPC)) of the component (p10), which is not particularly limited, is preferably in a range of 5,000 to 500,000, more preferably in a range of 10,000 to 400,000, and still more preferably in a range of 20,000 to 300,000.

In a case where Mw of the component (p10) is equal to or smaller than the upper limit value of this preferred range, a resist solvent solubility sufficient to be used as a resist is exhibited. On the other hand, in a case where it is equal to or larger than the lower limit value of this preferred range, dry etching resistance and plating resistance are good.

The dispersity (Mw/Mn) of the component (p10) is not particularly limited; however, it is preferably in a range of 1.0 to 20.0, more preferably in a range of 1.0 to 15.0, and particularly preferably in a range of 1.1 to 13.5. Here, Mn represents the number average molecular weight.

In regard to second resin component (P2):

In the present embodiment, the second resin component (P2) (the component (P2)) includes a polymeric compound (p20) (hereinafter, also referred to as a “component (p20)”) having both a constitutional unit (u0) containing a phenolic hydroxyl group and a constitutional unit (u1) containing an acid decomposable group having a polarity that is increased under action of acid.

The component (p20) may be a component having another constitutional unit as necessary in addition to the constitutional unit (u0) and the constitutional unit (u1).

### Constitutional Unit (u0)

The constitutional unit (u0) is a constitutional unit containing a phenolic hydroxyl group.

Preferred specific examples of the constitutional unit (u0) include constitutional units represented by General Formula (u0-0) shown below.

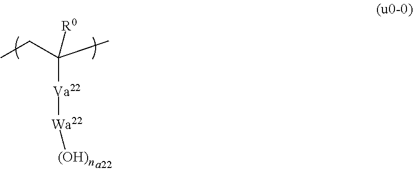

[In the formula, R²² represents a hydrogen atom, an alkyl group having 1 to 5 carbon atoms, or a halogenated alkyl group having 1 to 5 carbon atoms. Va²² represents a divalent linking group or a single bond. Wa²² represents an (nₐ₂₂+1)-valent aromatic hydrocarbon group. nₐ₂₂ represents an integer in a range of 1 to 3.]

In General Formula (u0-0), the alkyl group having 1 to 5 carbon atoms as R²² is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. The halogenated alkyl group having 1 to 5 carbon atoms as R²² is a group obtained by substituting part or all of hydrogen atoms in the alkyl group having 1 to 5 carbon atoms with a halogen atom. Examples of the halogen atom include a fluorine atom, a chlorine atom, a bromine atom, and an iodine atom, where a fluorine atom is particularly preferable.

R²² is preferably a hydrogen atom, an alkyl group having 1 to 5 carbon atoms, or a fluorinated alkyl group having 1 to 5 carbon atoms, and in terms of industrial availability, a hydrogen atom or a methyl group is most preferable.

In General Formula (u0-0), suitable examples of the divalent linking group as Va²² include a divalent hydrocarbon group which may have a substituent, and a divalent linking group has a hetero atom.

### Divalent Hydrocarbon Group Which May Have Substituent:

In a case where Va²² represents a divalent hydrocarbon group which may have a substituent, the hydrocarbon group may be an aliphatic hydrocarbon group or an aromatic hydrocarbon group.

### Aliphatic Hydrocarbon Group as Va²²

The aliphatic hydrocarbon group indicates a hydrocarbon group that has no aromaticity. The aliphatic hydrocarbon group may be saturated or unsaturated.

In general, it is preferable that the aliphatic hydrocarbon group is saturated.

Examples of the aliphatic hydrocarbon group include a linear or branched aliphatic hydrocarbon group, and an aliphatic hydrocarbon group containing a ring in the structure thereof.

### Linear or Branched Aliphatic Hydrocarbon Group

The linear aliphatic hydrocarbon group preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group has preferably 2 to 10 carbon atoms, more preferably 3 to 6 carbon atoms, still more preferably 3 or 4 carbon atoms, and most preferably 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The above-described linear or branched aliphatic hydrocarbon group may have or may not have a substituent. Examples of the substituent include a fluorine atom, a fluorinated alkyl group having 1 to 5 carbon atoms, which has been substituted with a fluorine atom, and a carbonyl group.

### Aliphatic Hydrocarbon Group Containing Ring in Structure Thereof

Examples of the aliphatic hydrocarbon group containing a ring in the structure thereof include a cyclic aliphatic hydrocarbon group which may have a substituent containing a hetero atom in the ring structure thereof (a group obtained by removing two hydrogen atoms from an aliphatic hydrocarbon ring), a group obtained by bonding the cyclic aliphatic hydrocarbon group to the terminal of a linear or branched aliphatic hydrocarbon group, and a group obtained by interposing the cyclic aliphatic hydrocarbon group in a linear or branched aliphatic hydrocarbon group. Examples of the linear or branched aliphatic hydrocarbon group described above include the same ones as the linear or branched aliphatic hydrocarbon groups exemplified in the description of the aliphatic hydrocarbon group as Va²².

The cyclic aliphatic hydrocarbon group preferably has 3 to 20 carbon atoms and more preferably 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing two hydrogen atoms from a polycycloalkane, and the polycycloalkane is preferably a group having 7 to 12 carbon atoms. Specific examples of the polycyclic alicyclic hydrocarbon group include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom, a halogenated alkyl group, a hydroxyl group, and a carbonyl group.

The alkyl group as the substituent is preferably an alkyl group having 1 to 5 carbon atoms, and most preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Examples of the halogenated alkyl group as the substituent include a group obtained by substituting part or all of hydrogen atoms in the above-described alkyl groups with the above-described halogen atoms.

In the cyclic aliphatic hydrocarbon group, part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.

### Aromatic Hydrocarbon Group as Va²²

The aromatic hydrocarbon group is a hydrocarbon group having at least one aromatic ring.

The aromatic ring is not particularly limited as long as it is a cyclic conjugated system having (4n +2)π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. However, the number of carbon atoms in the substituent is not included in the number of carbon atoms. Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group (an arylene group or a heteroarylene group) obtained by removing two hydrogen atoms from the above-described aromatic hydrocarbon ring or the above-described aromatic heterocyclic ring; a group obtained by removing two hydrogen atoms from an aromatic compound (for example, biphenyl or fluorene) having two or more aromatic rings; and a group (for example, a group obtained by further removing one hydrogen atom from an aryl group in the arylalkyl group such as a benzyl group, a phenethyl group, a 1-naphthylmethyl group, a 2-naphthylmethyl group, a 1-naphthylethyl group, or a 2-naphthylethyl group) obtained by substituting one hydrogen atom of a group (an aryl group or a heteroaryl group) obtained by removing one hydrogen atom from the above aromatic hydrocarbon ring or the above aromatic heterocyclic ring, with an alkylene group. The above-described alkylene group bonded to the aryl group or the heteroaryl group preferably has 1 to 4 carbon atoms, more preferably 1 or 2 carbon atoms, and particularly preferably 1 carbon atom.

With respect to the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of substituents include an alkyl group, an alkoxy group, a halogen atom, a halogenated alkyl group, and a hydroxyl group.

The alkyl group as the substituent is preferably an alkyl group having 1 to 5 carbon atoms, and most preferably a methyl group, an ethyl group, a propyl group, an n-butyl group, or a tert-butyl group.

Examples of the alkoxy group, the halogen atom, and the halogenated alkyl group, as the substituent, include the same groups as those exemplified as the substituent that is substituted for a hydrogen atom contained in the cyclic aliphatic hydrocarbon group.

### Divalent Linking Group Containing Hetero Atom:

In a case where Va²² represents a divalent linking group containing a hetero atom, preferred examples of the linking group include —O—, —C(═O)—O—, —C(═O)—, —O—C(═O)—O—, —C(═O)—NH—, —NH—, —NH—C(═NH)—(H may be substituted with a substituent such as an alkyl group, an acyl group, or the like), —S—, —S(═O)₂—, —S(═O)₂—O—, and a group represented by General Formula —Y²¹—O—Y²²—, —Y²¹—O—, —Y²¹—C(═O)—O—, —C(═O)—O—Y²¹—, —[Y²¹—C(═O)—O]_{m″}Y²²—, —Y²¹—O—C(═)—Y²²—or —Y²¹—S(═O)₂—O—Y²²—[in the formulae, Y²¹ and Y²² each independently represent a divalent hydrocarbon group which may have a substituent, O represents an oxygen atom, and m″ represents an integer in a range of 0 to 3].

In a case where the above-described divalent linking group containing a hetero atom is —C(═O)—NH—, —C(═O)—NH—C(═O)—, —NH—, or —NH—C(═NH)—, H may be substituted with a substituent such as an alkyl group, an acyl group, or the like. The substituent (an alkyl group, an acyl group, or the like) preferably has 1 to 10 carbon atoms, more preferably 1 to 8 carbon atoms, and particularly preferably 1 to 5 carbon atoms.

In General Formulae —Y²¹—O—Y²²—,—Y²¹—O—, —Y²¹—C(═O)—O—, —C(═O)—O—Y²¹—, —[Y²¹—C(═O)—O]m″—Y²²—, —Y²¹—O—C(═O)—Y²²—, and Y²¹—S(═O)₂—O—Y²²—, Y²¹, and Y²² each independently represent a divalent hydrocarbon group which may have a substituent. Examples of the divalent hydrocarbon group include the same one as “the divalent hydrocarbon groups which may have a substituent”, mentioned in the explanation of the above-described divalent linking group.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

In the group represented by Formula —[Y²¹—C(═O)—O]_{m″}—Y²²—, m″ represents an integer in a range of 0 to 3, preferably an integer in a range of 0 to 2, more preferably 0 or 1, and particularly preferably 1. In other words, it is particularly preferable that the group represented by Formula —[Y²¹—C(═O)—O]_{m″}—Y²²— represents a group represented by Formula —Y²¹—C(═O)—O—Y²²—. Among them, a group represented by Formula —(CH₂)ₐ′—C(═O)—O—(CH₂)_{b}′— is preferable. In the formula, a′ represents an integer in a range of 1 to 10, preferably an integer in a range of 1 to 8, more preferably an integer in a range of 1 to 5, still more preferably 1 or 2, and most preferably 1. b′ represents an integer in a range of 1 to 10, preferably an integer in a range of 1 to 8, more preferably an integer in a range of 1 to 5, still more preferably 1 or 2, and most preferably 1.

Va²² is preferably a single bond, an ester bond [—C(═O)—O—], an ether bond (—O—), —C(═O)—NH—, a linear or branched alkylene group, or a combination of these, and particularly, it is more preferably a single bond among the above.

In General Formula (u0-0), examples of the aromatic hydrocarbon group as Wa²² include a group obtained by removing (nₐ₂₂+1) hydrogen atoms from an aromatic ring. Here, the aromatic ring is not particularly limited as long as it is a cyclic conjugated system having (4n+2)π electrons, and may be monocyclic or polycyclic. The aromatic ring preferably has 5 to 30 carbon atoms, more preferably 5 to 20 carbon atoms, still more preferably 6 to 15 carbon atoms, and particularly preferably 6 to 12 carbon atoms. Specific examples of the aromatic ring include aromatic hydrocarbon rings such as benzene, naphthalene, anthracene, and phenanthrene; and an aromatic heterocyclic ring obtained by substituting part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

In General Formula (u0-0), nₐ₂₂ represents an integer in a range of 1 to 3, and it is preferably 1 or 2 and more preferably 1.

Specific examples of the constitutional unit (u0) are shown below.

In the formulae shown below, R^{α}represents a hydrogen atom, a methyl group, or a trifluoromethyl group.

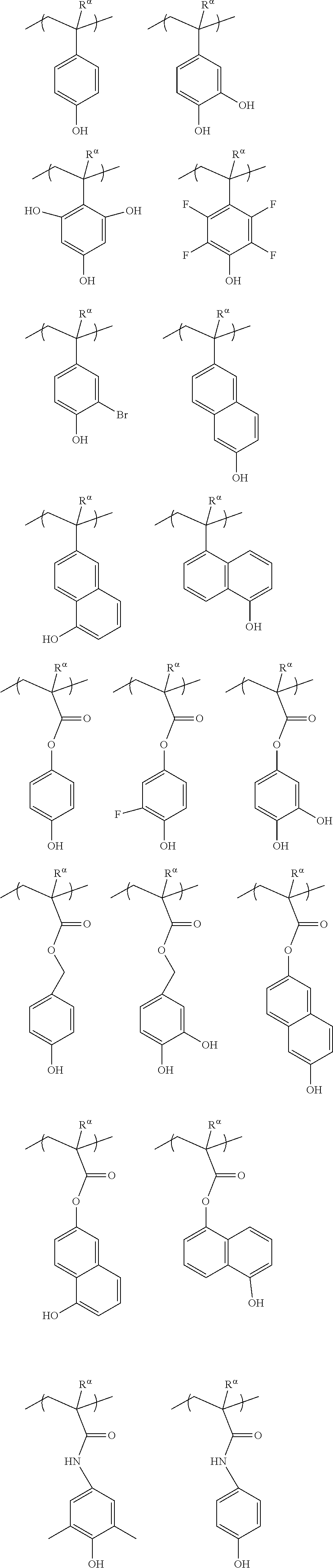

The constitutional unit (u0) contained in the component (p20) may be one kind or may be two or more kinds.

The proportion of the constitutional unit (u0) in the component (p20) is, for example, preferably in a range of 40% to 90% by mole, more preferably in a range of 50% to 85% by mole, and particularly preferably in a range of 60% to 80% by mole, with respect to the total (100% by mole) of all constitutional units constituting the component (p20).

In a case where the proportion of the constitutional unit (u0) is within the above-described preferred range, the characteristics such as sensitivity and residue reduction are improved.

### Constitutional Unit (u1)

The constitutional unit (u1) is a constitutional unit that contains an acid decomposable group having a polarity that is increased under action of acid. Similar to the acid decomposable group in the constitutional unit (a1), the “acid decomposable group” referred to here is a group having an acid decomposable group in which at least part of bonds in the structure of the acid decomposable group can be cleaved under action of acid.

Examples of the acid decomposable group having a polarity that is increased under action of acid include groups which are decomposed under action of acid to generate a polar group.

Examples of the polar group include a carboxy group and a sulfo group (—SO₃H). Among these, a carboxy group is preferable.

More specific examples of the acid decomposable group include a group (for example, a group obtained by protecting a hydrogen atom of the carboxy group with an acid dissociable group) obtained by protecting the above-described polar group with an acid dissociable group.

The acid dissociable group is not particularly limited, and it is possible to use those which have been proposed so far as acid dissociable groups of the base resin for a chemical amplification-type resist.

Among the above polar groups, examples of the acid dissociable group that protects the carboxy group include an acid dissociable group represented by General Formula (a1-r-1) (an “acetal-type acid dissociable group”) and an acid dissociable group represented by General Formula (a1-r-2) (among the acid dissociable groups represented by General Formula (a1-r-2), an acid dissociable group composed of an alkyl group: a “tertiary alkyl ester-type acid dissociable group”).

Preferred specific examples of the constitutional unit (u1) include a constitutional unit derived from an acrylic acid ester in which a hydrogen atom bonded to a carbon atom at an α-position may be substituted with a substituent and is a constitutional unit containing an acid decomposable group having a polarity that is increased under action of acid.

Examples of the constitutional unit (u1) include the same one as the above-described constitutional unit (a1). Among them, suitable examples thereof include a constitutional unit represented by General Formula (a1-1). Ra¹ in General Formula (a1-1) is more preferably an acid dissociable group represented by General Formula (a1-r-2) and still more preferably an acid dissociable group represented by General Formula (a1-r2-2).

In General Formula (a1-r2-2), Ra′¹², Ra′¹³, and Ra′¹⁴ are each independently preferably an alkyl group having 1 to 10 carbon atoms, and the alkyl group is still more preferably a linear alkyl group having 1 to 5 carbon atoms and particularly preferably a methyl group or an ethyl group.

Alternatively, preferred specific examples of the constitutional unit (u1) include a constitutional unit in which at least part of hydrogen atoms in the hydroxyl group of the constitutional unit derived from hydroxystyrene or the hydroxystyrene derivative is protected by a substituent containing the acid decomposable group.

For example, examples thereof include a constitutional unit in which at least part of hydrogen atoms in the hydroxyl group of the constitutional unit derived from hydroxystyrene is protected by an ethoxyethyl group. Further, examples thereof include a constitutional unit in which at least part of hydrogen atoms in the hydroxyl group of the constitutional unit derived from hydroxystyrene is protected by a tertiary alkyloxycarbonyl (t-Boc) group.

The constitutional unit (u1) contained in the component (p20) may be one kind or may be two or more kinds.

The proportion of the constitutional unit (u1) in the component (p20) is, for example, preferably in a range of 5% to 50% by mole, more preferably in a range of 10% to 45% by mole, and particularly preferably in a range of 15% to 40% by mole, with respect to the total (100% by mole) of all constitutional units constituting the component (p20).

In a case where the proportion of the constitutional unit (u1) is within the above-described preferred range, the characteristics such as sensitivity and residue reduction are improved.

The component (p20) may have other constitutional units derived from a polymerizable compound such as styrene, in addition to the constitutional unit (u0) and the constitutional unit (u1).

Examples of such a polymerizable compound include styrene, chlorostyrene, chloromethyl styrene, vinyl toluene, α-methyl styrene, and (meth)acrylic acid alkyl esters s such as methyl (meth)acrylate, ethyl (meth)acrylate, and butyl (meth)acrylate.

The weight average molecular weight of the component (p20) is preferably 1,000 to 50,000.

In addition, in the resist composition of the present embodiment, the component (P1) and the component (P2) are preferably used in combination, where in a case where a dissolution rate of the component (P1) in an alkali developing solution is denoted by DRpi, a dissolution rate of the component (P2) in an alkali developing solution is denoted by DR_{P2}, and a dissolution rate of a mixed resin of the component (P1) and the component (P2), in an alkali developing solution, is denoted by DR_{MIX}, a mixing ratio satisfying the following expressions are present,

DR_{MIX}<DR_{P1} and DR_{MIX}<DR_{P2}.

That is, it is preferable to select a combination of resins, in which the dissolution rate of a mixed resin in an alkali developing solution is small as compared with the dissolution rate of each single resin in an alkali developing solution. As a result, in the resist pattern formation, even in a case of a resin that is difficult to be used due to having a high dissolution rate in an alkali developing solution, the reduction of the developed film is suppressed and the residue is hardly generated.

In the related art, a resin that is made to be insoluble in an alkali developing solution (an alkaline aqueous solution) by introducing an acid dissociable group into a resin that is easily dissolved in the alkali developing solution has been used in the resin component (P).

For controlling the dissolution rate in an alkali developing solution to a desired value and achieving insolubility in an alkali developing solution, there is known a method of controlling the introduction rate (the protection rate) of an acid dissociable group (a protecting group) that is introduced into an alkali-soluble resin in the resin manufacturing stage; and a method of producing, for example, resins having different protection rates in consideration of variations during production and mixing them to obtain an insolubilized resin (a mixed resin) having a desired dissolution rate. In this case, in an alkali developing solution, there has been a general relationship of DR′_{PH}<DR′_{MIX}<DR′_{PL} between dissolution rates of an insolubilized resin P′_{MIX} (dissolution rate: DR′_{MIX}) after mixing, a resin P′_{H} (dissolution rate: DR′_{PH}) having a high protection rate and a low dissolution rate before mixing, and a resin P′_{L} (dissolution rate: DR′_{PL}) having a low protection rate and a high dissolution rate before mixing.

Further, there is also a case of mixing resins differing in protecting group or monomer units themselves. Even in this case, although there has been known a method of using a resin P″_{MIX} (dissolution rate: DR″_{MIX}) obtained by mixing a resin P_{X} (dissolution rate: DR_{Px}) having a large amount of film reduction and a different resin P_{Y} (dissolution rate: DR_{PY}) having a small amount of film reduction, the relationship between the dissolution rates in the mixed alkali developing solution has been generally DR_{PY}<DR″_{MIX}<DR_{Px}.

However, in the present embodiment, it is preferable to employ a resist composition having both the component (P1) and the component (P2), which satisfy the relationship of specific dissolution rates (that is, DR_{MIX}<DR_{P1} and DR_{MIX}<DR_{P2}) as described above (it is preferable to suppress relatively low the dissolution rate of the mixed resin even in a case of using a resin having a relatively high dissolution rate in an alkali developing solution). As a result, in the resist pattern formation, the reduction of the developed film is controlled with higher sensitivity, and it is possible to form a resist pattern having a high resolution by which a fine pattern can be formed without a residue even on a substrate having height difference.

### [Dissolution Rate of Resin in Alkali Developing Solution]

Regarding the dissolution rate (DR) of the resin in an alkali developing solution, the value itself of the dissolution rate derived from the kind and the concentration of the alkali developing solution to be used and the temperature greatly changes. Therefore, in the present invention, the dissolution rate that is measured and calculated by using a developing solution and developing conditions which are used or planned to be used in the resist patterning with the final resist composition is defined.

Although the dissolution rate (DR) of the resin in an alkali developing solution is not as high as that of the developing solution, it varies depending on the film thickness of the coating film, heating conditions, and the like. Properly speaking, it is favorable to define the dissolution rate that is calculated in a case where a resin film is prepared under the conditions actually used, that is, the film thickness of the coating film that is used or planned to be used in the resist patterning with the resist composition and the heating conditions (PAB) at the time of film coating and developed using the above-described developing solution and developing conditions. However, the film thickness of the coating film and the heating conditions at the time of film coating are changed in a timely manner depending on the intended purpose. Therefore, in the present invention, the dissolution rate acquired and calculated according to a method shown in the following measurement procedures is defined as “a dissolution rate of a resin in an alkali developing solution”.

The measurement of “the dissolution rate of the resin in an alkali developing solution” defined in the present invention shall be in accordance with the following procedures (1) to (6) or procedures (1′) to (6′).

A procedure (1): A resin solution is prepared by mixing a resin with an organic solvent component (a solvent) that is generally used in a resist composition. The preparation of the resin solution may be carried out by mixing a mixture of a plurality of resins prepared in advance with an organic solvent component or may be carried out by preparing individual resin solutions of single resins and then mixing them at a required proportion. As necessary, the resin solution may be diluted with a solvent, or an appropriate amount of a leveling agent (a surfactant) may be added thereto.

A procedure (2): The resin solution is applied onto a silicon wafer and then subjected to baking treatment (PAB) at 120° C. for 90 seconds to form a resin film having a thickness of about 4 μm.

A procedure (3): The film thickness (the initial film thickness X) of the resin film is measured.

A procedure (4): The silicon wafer on which the resin film has been formed is exposed and then developed with a predetermined alkali developing solution at a predetermined temperature for 60 seconds using a developing machine without exposure and a heat treatment step (PEB) after the exposure, and then washing with water and drying (non-heating drying such as spin drying or N₂ air blow) are carried out.

A procedure (5): After development, the film thickness of the resin film (the film thickness Y after development) is measured.

A procedure (6): The dissolution rate (DR) of the resin in the alkali developing solution is calculated.

DR (nm/s)=(X−Y)/60 seconds (development time)

It is noted that in a case where the resin film is completely dissolved due to development in the above procedure, the development time in the procedure (4) may be shortened to 30 seconds and measurement may be carried out. In addition, in a case where it is difficult to use a silicon wafer or a developing machine, or in a case where the measurement is difficult in the above-described procedure, the measurement is carried out by the following procedures (1′) to (6′).

A procedure (1′): A resin solution is prepared by mixing a resin with an organic solvent component (a solvent) that is generally used in a resist composition. The preparation of the resin solution may be carried out by mixing a mixture of a plurality of resins prepared in advance with an organic solvent component or may be carried out by preparing individual resin solutions of single resins and then mixing them at a required proportion. As necessary, the resin solution may be diluted with a solvent, or an appropriate amount of a leveling agent (a surfactant) may be added thereto.

A procedure (2′): The resin solution is applied onto a support on which the film thickness can be measured, such as a silicon wafer, and then subjected to baking treatment (PAB) at 120° C. for 120 seconds to form a resin film having a thickness of about 4 μm.

A procedure (3′): The film thickness (the initial film thickness X) of the resin film is measured.

A procedure (4′): A predetermined alkali developing solution is put in a container such as a beaker or a vat. The temperature of the developing solution is adjusted as necessary, whereby the temperature of the developing solution is set to a predetermined temperature. A container having a size in which the support on which the resin film has been formed in the procedure (2′) can be placed is selected or a size in which the cut support on which the resin film has been formed can be placed.

A procedure (5′) The support is immersed in an alkali developing solution in the container, and the time taken until the formed resin film is completely dissolved (the dissolution time Z) is measured. It is noted that the dissolution time is limited to 2 minutes, and in a case where it is not completely dissolved after 2 minutes, the support is taken out, washed with water, and dried properly, and then the film thickness of the resin (the film thickness Y after development) is measured.

A procedure (6′): The dissolution rate (DR) of the resin in the alkali developing solution is calculated.

In a case of being completely dissolved: DR (nm/s)=(X)/(Z)

In a case of not being completely dissolved: DR (nm/s)=(X−Y)/120 seconds (development time)

It is noted that in a case of the intended purpose of comparing the magnitude between DR_{P1}, DR_{P2}, and DR_{MIX} shown in the present embodiment, instead of using the measurement by using a developing solution and developing conditions and a resin film thickness and production conditions which are used or planned to be used in the resist patterning with the final resist composition, the values regarding the dissolution rate values acquired by comparison using the same developing solution and developing conditions and the same resin film thickness and resin film production conditions may be examined. Specifically, as an example, in a case where a developing solution of 2.38% by mass of TMAH and developing conditions at 23° C. are used in the final resist patterning, a developing solution of 5% by mass of TMAH may be used in the measurement and the comparison of the dissolution rates to calculate DR, and the magnitude between DR_{P1}, DR_{P2}, and DR_{MIX} may be compared. This method of using a developing solution of 5% by mass of TMAH is an effective method particularly in the examination and comparison in a case where DR_{P2} has a small value in a developing solution and developing conditions which are used or planned to be used in the resist patterning with the final resist composition. Similarly, in a case where DR can be measured under the same conditions even in a case where the thickness of the resin film and the film forming conditions are changed, the observed values can be compared.

Further, a measurement method other than the above procedure may be adopted as long as dissolution rates with which the magnitude between DR_{P1}, DR_{P2}, and DR_{MIX} shown in the present embodiment can be compared can be measured. For example, the quartz crystal microbalance (QCM) method may be used as an example to determine dissolution rates and then they may be compared.

This is because although the DR values observed change depending on the measurement conditions and the measurement method, the relative positional relationship of the values observed under the same conditions does not change.

In the resist composition that is used in the resist pattern formation method according to the present embodiment, the component (P) may contain a resin component (hereinafter, this resin component is also referred to as a “component (P3)”) other than the component (P1) and the component (P2).

The component (P3) is not particularly limited, and examples thereof include a novolak type phenol resin (p31) and a polyhydroxystyrene-based resin (p32) (however, a resin corresponding to the component (P2) is excluded).

Novolak type phenol resin (p31):

As the novolak type phenol resin (p31) (the component ((p31)), it is possible to use, for example, one obtained by subjecting an aromatic compound (phenols) having a phenolic hydroxyl group and aldehydes to addition condensation under an acid catalyst.

Examples of the phenols include phenol, o-cresol, m-cresol, p-cresol, o-ethyl phenol, m-ethyl phenol, p-ethyl phenol, o-butyl phenol, m-butyl phenol, p-butyl phenol, 2,3-xylenol, 2,4-xylenol, 2,5-xylenol, 2,6-xylenol, 3,4-xylenol, 3,5-xylenol, 2,3,5-trimethyl phenol, 3,4,5-trimethyl phenol, p-phenyl phenol, resorcinol, hydroquinone, hydroquinone monomethyl ether, pyrogallol, phloroglucinol, hydroxydiphenyl, bisphenol A, gallic acid, gallic acid ester, α-naphthol, and β-naphthol.

Examples of the aldehydes include formaldehyde, furfural, benzaldehyde, nitrobenzaldehyde, and acetaldehyde.

The acid catalyst at the time of the addition condensation reaction is not particularly limited, and for example, hydrochloric acid, nitric acid, sulfuric acid, formic acid, oxalic acid, acetic acid, or the like is used.

Among the above, the component (p31) is preferably a resin having a constitutional unit represented by General Formula (u31-0).

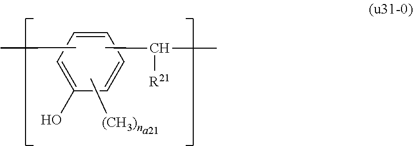

[In the formula, R²¹ is a hydrogen atom or an organic group. nₐ₂₁ represents an integer in a range of 1 to 3.]

In General Formula (u31-0), R²¹ is a hydrogen atom or an organic group. The organic group as R²¹ is derived from the aldehydes that are used in the addition condensation. Among them, R²¹ is preferably a hydrogen atom (derived from formaldehyde).

nₐ₂₁ is an integer in a range of 1 to 3, and it is preferably 1 or 3 and more preferably 1.

The weight average molecular weight of the component (p31) is preferably 1,000 to 50,000.

Polyhydroxystyrene resin (p32):

As the polyhydroxystyrene resin (p32) (the component ((p32)), it is possible to use, for example, a resin having a constitutional unit (u0) represented by General Formula (u0-0).

The component (p32) may have other constitutional units derived from a polymerizable compound such as styrene, in addition to the constitutional unit (u0). Examples of such a polymerizable compound include styrene, chlorostyrene, chloromethyl styrene, vinyl toluene, α-methyl styrene, and (meth)acrylic acid alkyl esters s such as methyl (meth)acrylate, ethyl (meth)acrylate, and butyl (meth)acrylate.

The weight average molecular weight of the component (p32) is preferably 1,000 to 50,000.

As described above, the resin component (the component (P)) that is used in the resist composition of the embodiment contains the first resin component (P1) and the second resin component (P2).

The first resin component (P1) contains a polymeric compound (p10) having a constitutional unit (a0) derived from acrylic acid in which a hydrogen atom bonded to a carbon atom at an α-position may be substituted with a substituent, and the second resin component (P2) contains a polymeric compound (p20) having both a constitutional unit (u0) containing a phenolic hydroxyl group and a constitutional unit (u1) containing an acid decomposable group having a polarity that is increased under action of acid.

In addition, it is preferable to employ the first resin component (P1) and the second resin component (P2), where in a case where a dissolution rate of the first resin component (P1) in an alkali developing solution is denoted by DRpi, a dissolution rate of the second resin component (P2) in an alkali developing solution is denoted by DR_{P2}, and a dissolution rate of a mixed resin of the first resin component (P1) and the second resin component (P2), in an alkali developing solution, is denoted by DR_{MIX}, a mixing ratio satisfying the following expressions are present,

DR_{MIX}<DR_{P1} and DR_{MIX}<DR_{P2}.

The content proportion of the component (P1) contained in the resist composition in the present embodiment may be appropriately determined depending on the kind of resin, and it is, for example, preferably 10 parts by mass or more and 50 parts by mass or less with respect to 100 parts by mass of the total of the component (P1) and the component (P2).

In a case where the content proportion of the component (P1) is within the above-described preferred range, the high sensitivity is achieved, the resolution is increased, and the residue is hardly generated in the resist pattern formation.

Further, the polymeric compound (p10) can take a dissolution rate in an alkali developing solution, at which it has been difficult to be made insoluble in unexposed portions in the related art in a case of being used alone as a resist composition. Specifically, the dissolution rate in an alkali developing solution is preferably 5 nm/sec or more, more preferably 10 nm/sec or more, and particularly preferably in a range of 10 to 10,000 nm/sec. In a case where the dissolution rate of the component (p10) in an alkali developing solution is equal to or higher than the lower limit value of the above-described preferred range, the dissolution rate can be further improved in exposed portions after exposure, and thus residue is hardly generated and the sensitivity can be easily increased.

In addition, the dissolution rate of the polymeric compound (p20) in an alkali developing solution is preferably 100 nm/sec or less, more preferably more than 0 nm/sec and 20 nm/sec or less, and particularly preferably more than 0 nm/sec and 10 nm/sec or less. In a case where the dissolution rate of the component (p20) in the alkali developing solution is within the above-described preferred range, the reduction of the developed film can be suppressed, and the sensitivity can be easily increased.

Further, the dissolution rate DR_{MIX} of the mixed resin of the component (P1) and the component (P2) in an alkali developing solution is preferably more than 0 nm/sec and 35 nm/sec or less, more preferably more than 0 nm/sec and 20 nm/sec or less, and particularly preferably more than 0 nm/sec and 10 nm/sec or less.

In a case where the dissolution rate DR_{MIX} of the mixed resin in an alkali developing solution is within the above-described preferred range, the reduction of the developed film is suppressed, and a good residual film pattern can be easily obtained.

### <<Component (B) : Acid Generator Component>>

The component (B) is not particularly limited, and those which have been proposed so far as an acid generator for a chemical amplification-type resist composition in the related art can be used.

Examples of such an acid generator are various and include onium salt-based acid generators such as an iodonium salt and a sulfonium salt; an oxime sulfonate-based acid generator; diazomethane-based acid generators such as bisalkyl or bisaryl sulfonyl diazomethanes and poly(bis-sulfonyl)diazomethanes; nitrobenzyl sulfonate-based acid generators; iminosulfonate-based acid generators; and disulfone-based acid generators.

Examples of the onium salt-based acid generator include an onium salt having an organic cation represented by each of General Formulae (ca-1) to (ca-5) in the cation moiety.

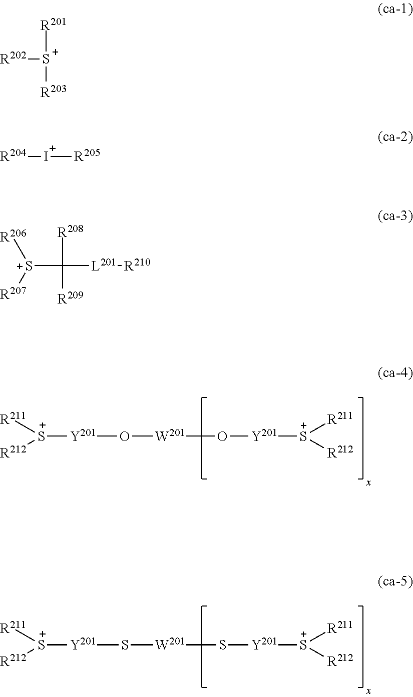

[In the formula, R²⁰¹ to R²⁰⁷, R²¹¹, and R²¹² each independently represent an aryl group, a heteroaryl group, an alkyl group, or an alkenyl group, each of which may have a substituent. R²⁰¹ to R²⁰³, R²⁰⁶ and R²⁰⁷, or R²¹¹ and R²¹² may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂-containing cyclic group which may have a substituent. L²⁰¹ represents —C(═O)—or —C(═O)—O—. Y²⁰¹s each independently represent an arylene group, an alkylene group, or an alkenylene group. x represents 1 or 2. W²⁰¹ represents an (x+1)-valent linking group.]

Examples of the aryl group as R²⁰¹ to R²⁰⁷, R²¹¹, and R²¹² include an unsubstituted aryl group having 6 to 20 carbon atoms, and a phenyl group or a naphthyl group is preferable.

Examples of the heteroaryl group as R²⁰¹ to R²⁰⁷ and R²¹¹ to R²¹² include those obtained by substituting part of carbon atoms constituting the aryl group with a hetero atom. Examples of the hetero atom include an oxygen atom, a sulfur atom, and a nitrogen atom. Examples of the heteroaryl group include a group obtained by removing one hydrogen atom from 9H-thioxanthene; and as a substituted heteroaryl group, a group obtained by removing one hydrogen atom from 9H-thioxanthene-9-one.

The alkyl group as R²⁰¹ to R²⁰⁷, R²¹¹, and R²¹² is preferably a chain-like or cyclic alkyl group having 1 to 30 carbon atoms.

The alkenyl group as R²⁰¹ to R²⁰⁷, R²¹¹, and R²¹² preferably has 2 to 10 carbon atoms.

Examples of the substituent which may be contained in R²⁰¹ to R²⁰⁷ and R²¹⁰ to R²¹² include an alkyl group, a halogen atom, a halogenated alkyl group, a carbonyl group, a cyano group, an amino group, an oxo group (═O), an aryl group, and a group represented by each of General Formulae (ca-r-1) to (ca-r-10) shown below.

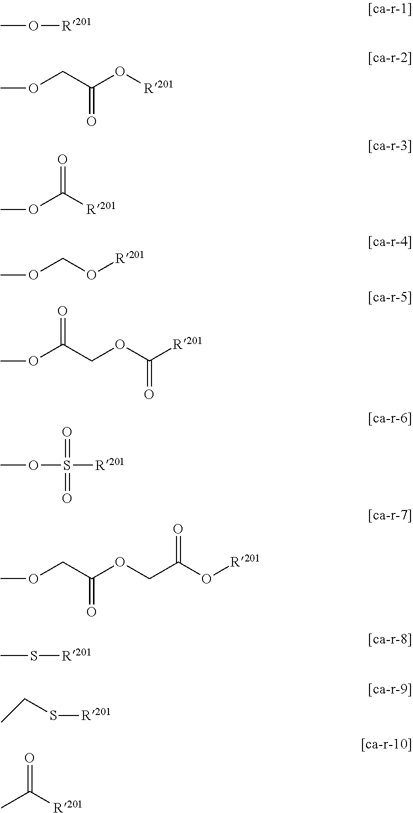

[In the formulae, each R′²⁰¹ independently represents a hydrogen atom, a cyclic group which may have a substituent, a chain-like alkyl group which may have a substituent, or a chain-like alkenyl group which may have a substituent.]

In General Formulae (ca-r-1) to (ca-r-10) described above, each R′²⁰¹ independently represents a hydrogen atom, a cyclic group which may have a substituent, a chain-like alkyl group which may have a substituent, or a chain-like alkenyl group which may have a substituent.

Cyclic group which may have substituent:

The cyclic group is preferably a cyclic hydrocarbon group, and the cyclic hydrocarbon group may be an aromatic hydrocarbon group or a cyclic aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R′²⁰¹ is a hydrocarbon group having an aromatic ring. The aromatic hydrocarbon group preferably has 3 to 30 carbon atoms, more preferably 5 to 30, still more preferably 5 to 20, particularly preferably 6 to 15, and most preferably 6 to 10. However, the number of carbon atoms in the substituent is not included in the number of carbon atoms.

Specific examples of the aromatic ring contained in the aromatic hydrocarbon group as R′²⁰¹ include benzene, fluorene, naphthalene, anthracene, phenanthrene, biphenyl, and an aromatic heterocyclic ring obtained by substituting part of carbon atoms constituting one of these aromatic rings with a hetero atom, as well as a ring obtained by substituting part of hydrogen atoms constituting these aromatic rings or aromatic heterocyclic rings with an oxo group or the like. Examples of the hetero atom in the aromatic heterocyclic rings include an oxygen atom, a sulfur atom, and a nitrogen atom.

Specific examples of the aromatic hydrocarbon group as R′²⁰¹ include a group (an aryl group: for example, a phenyl group, a naphthyl group, or an anthracenyl group) obtained by removing one hydrogen atom from the aromatic ring, a group (for example, an arylalkyl group such aa benzyl group, a phenethyl group, a 1-naphthylmethyl group, a 2-naphthylmethyl group, 1-naphthylethyl group, or a 2-naphthylethyl group) obtained by substituting one hydrogen atom of the above aromatic ring with an alkylene group, a group (for example, anthraquinone) obtained by removing one hydrogen atom from a ring in which part of hydrogen atoms constituting the aromatic ring are substituted with an oxo group or the like, and a group (for example, 9H-thioxanthene or 9H-thioxanthene-9-one) obtained by removing one hydrogen atom from an aromatic heterocyclic ring. The alkylene group (an alkyl chain the arylalkyl group) preferably has 1 to 4 carbon atoms, more preferably 1 or 2 carbon atoms, and particularly preferably 1 carbon atom.

Examples of the cyclic aliphatic hydrocarbon group as R′²⁰¹ include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group obtained by bonding the alicyclic hydrocarbon group to the terminal of a linear or branched aliphatic hydrocarbon group, and a group obtained by interposing the alicyclic hydrocarbon group is in a linear or branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, a polycycloalkane having a bridged ring-based polycyclic skeleton, such as adamantane, norbomane, isobomane, tricyclodecane, or tetracyclododecane, and a polycycloalkane having a condensed ring-based polycyclic skeleton, such as a cyclic group having a steroid skeleton is more preferable.

Among them, the cyclic aliphatic hydrocarbon group as R′²⁰¹ is preferably a group obtained by removing one or more hydrogen atoms from a monocycloalkane or a polycycloalkane, more preferably a group obtained by removing one hydrogen atom from a polycycloalkane, particularly preferably an adamantyl group or a norbornyl group, and most preferably an adamantyl group.

The linear or branched aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

Chain-like alkyl group which may have substituent:

The chain-like alkyl group as R′²⁰¹may be linear or branched.

The linear alkyl group preferably has 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecil group, an icosyl group, a henicosyl group, and a docosyl group.

The branched alkyl group preferably has 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

A chain-like alkenyl group as R′²⁰¹ may be linear or branched, and the chain-like alkenyl group preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent in the cyclic group, chain-like alkyl group, or alkenyl group as R′²⁰¹ include an alkoxy group, a halogen atom, a halogenated alkyl group, a hydroxyl group, a carbonyl group, a nitro group, an amino group, an oxo group, a cyclic group as R′²⁰¹, an alkylcarbonyl group, and a thienylcarbonyl group.

Among them, R′²⁰¹ is preferably a cyclic group which may have a substituent or a chain-like alkyl group which may have a substituent.

R²⁰¹ to R²⁰³, R²⁰⁶ and R²⁰⁷, and R²¹¹ and R²¹² are bonded to each other to form a ring with a sulfur atom in the formula, these groups may be bonded to each other via a hetero atom such as a sulfur atom, an oxygen atom or a nitrogen atom, or a functional group such as a carbonyl group, —SO—, —SO₂—, —SO₃—, —COO—, —CONH—or —N(R_{N})— (here, R_{N} represents an alkyl group having 1 to 5 carbon atoms). Regarding the ring to be formed, a ring containing a sulfur atom in a formula in the ring skeleton thereof is preferably a 3-membered to 10-membered ring and particularly preferably a 5-membered to 7-membered ring containing a sulfur atom. Specific examples of the ring to be formed include a thiophene ring, a thiazole ring, a benzothiophene ring, a benzothiophene ring, a thianthrene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

In General Formula (ca-3), R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case where R²⁰⁸ and R²⁰⁹ each independently represent an alkyl group, R²⁰⁸ and R²⁰⁹ may be bonded to each other to form a ring.

In General Formula (ca-3), R²¹⁰ represents an aryl group which may have a substituent, an alkyl group which may have a substituent, an alkenyl group which may have a substituent, or a —SO₂-containing cyclic group which may have a substituent.

Examples of the aryl group as R²¹⁰ include an unsubstituted aryl group having 6 to 20 carbon atoms, and a phenyl group or a naphthyl group is preferable.

The alkyl group as R²¹⁰, a chain-like or cyclic alkyl group having 1 to 30 carbon atoms is preferable.

The alkenyl group as R²¹⁰ preferably has 2 to 10 carbon atoms.

In General Formula (ca-4) and General Formula (ca-5) described above, Y²⁰¹s each independently represent an arylene group, an alkylene group, or an alkenylene group.

Examples of the arylene group as Y²⁰¹ include groups obtained by removing one hydrogen atom from an aryl group exemplified as the aromatic hydrocarbon group as R′²⁰¹.

Examples of the alkylene group and alkenylene group as Y²⁰¹ include groups obtained by removing one hydrogen atom from the chain-like alkyl group or the chain-like alkenyl group as R′²⁰¹.

In General Formula (ca-4) and General Formula (ca-5) described above, x represents 1 or 2.

W²⁰¹ represents an (x+1)-valent linking group, that is, a divalent or trivalent linking group.

The divalent linking group as W²⁰¹ is preferably a divalent hydrocarbon group which may have a substituent, and it is preferably the same group as the divalent hydrocarbon group which may have a substituent, which is exemplified as Va²² in General Formula (u22-0) described above. The divalent linking group as W²⁰¹ may be linear, branched, or cyclic and is preferably cyclic. Among the above, it is preferably a group obtained by combining two carbonyl groups at both ends of an arylene group or a group consisting of only an arylene group. Examples of the arylene group include a phenylene group and a naphthylene group, and a phenylene group is particularly preferable.

Examples of the trivalent linking group as W²⁰¹ include a group obtained by removing one hydrogen atom from the above-described divalent linking group as W²⁰¹ and a group obtained by bonding the divalent linking group to another divalent linking group. The trivalent linking group as W²⁰¹ is preferably a group obtained by bonding two carbonyl groups to an arylene group.

Specific examples of the suitable cation represented by General Formula (ca-1) include a cation represented by each of General Formulae (ca-1-1) to (ca-1-24).

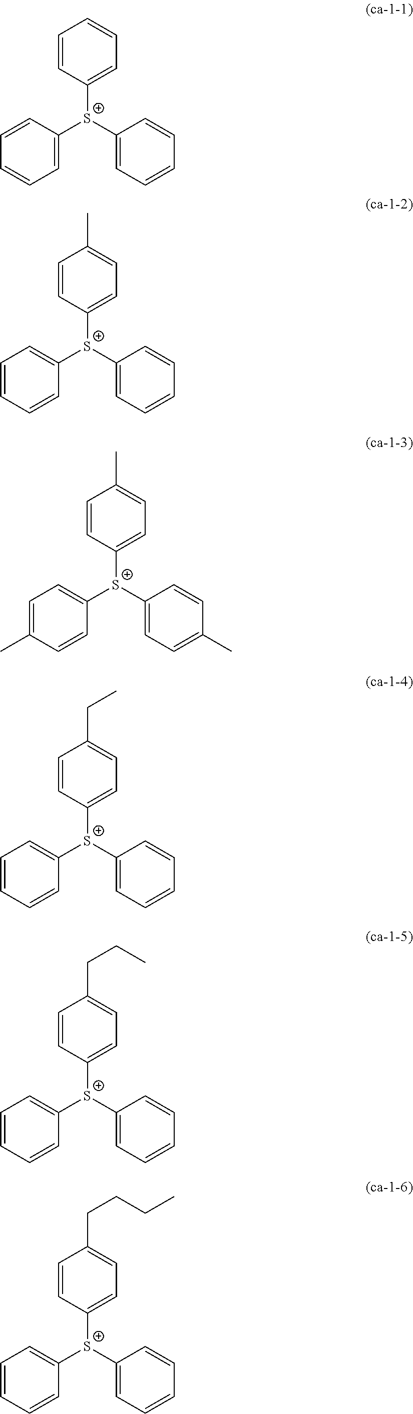

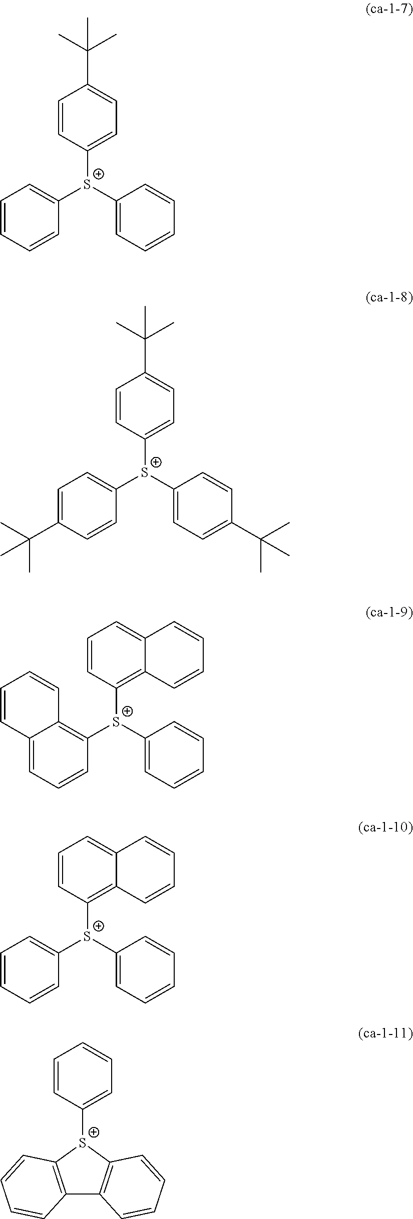

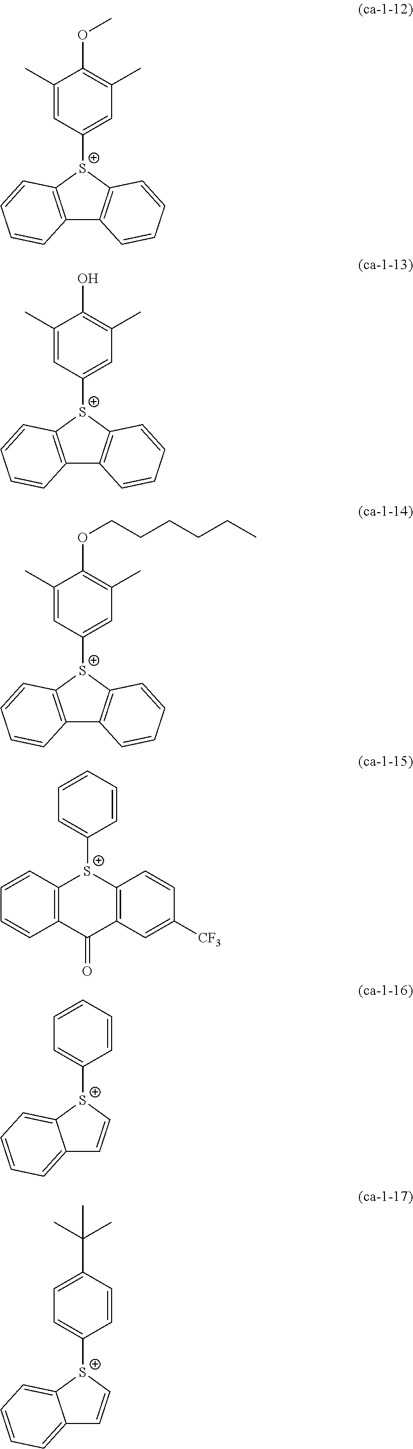

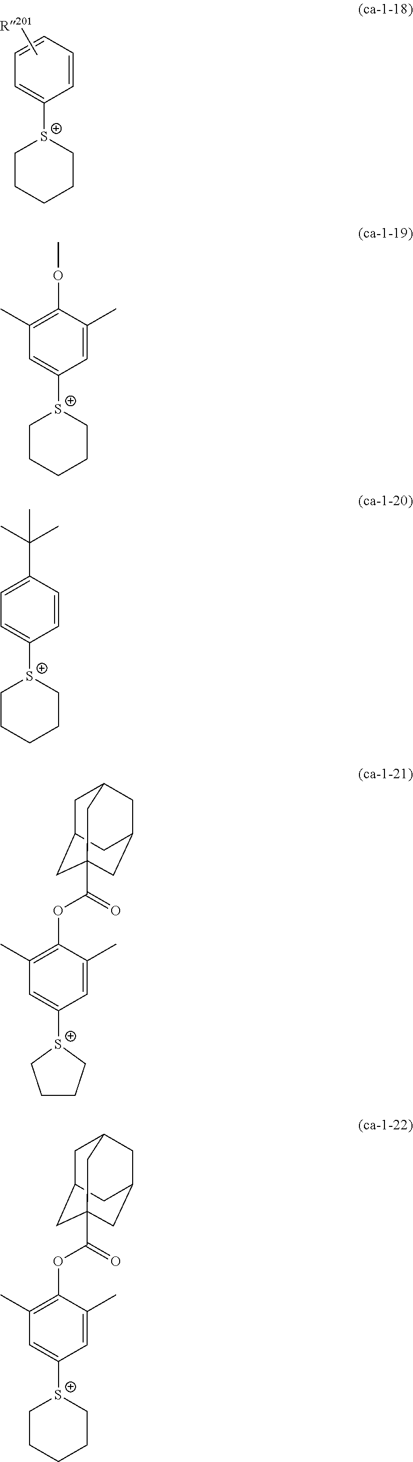

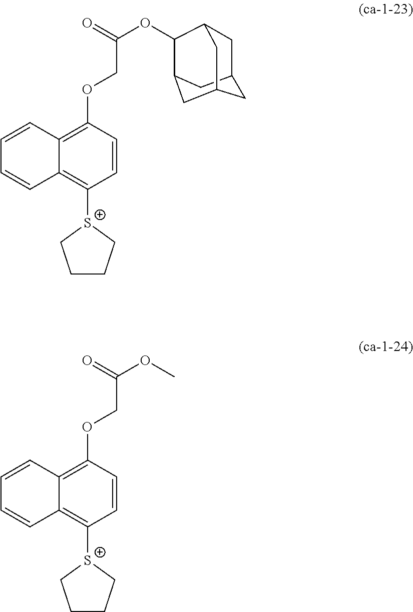

[In the formula, R″²⁰¹ represents a hydrogen atom or a substituent. The substituent is the same as those mentioned as the substituents which may be contained in R²⁰¹ to R²⁰⁷ and R²¹⁰ to R²¹².]

In addition, the cation represented by General Formula (ca-1) is also preferably cations each represented General Formulae (ca-1-25) to (ca-1-35) shown below.

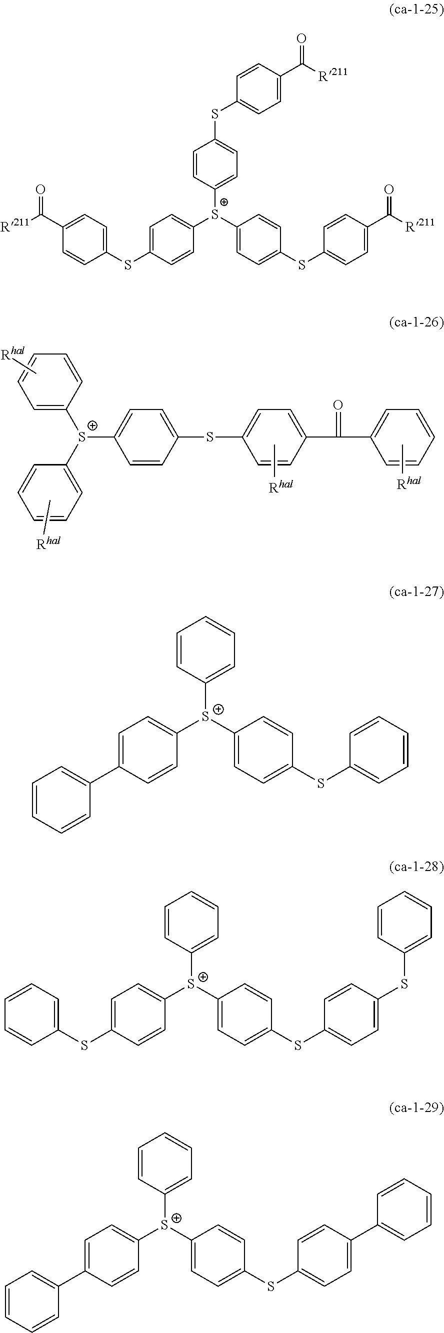

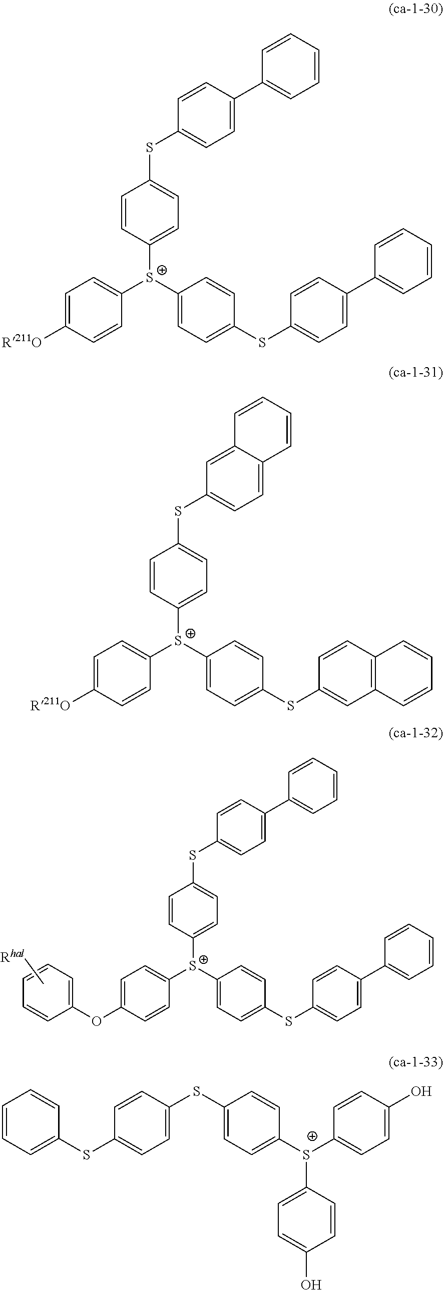

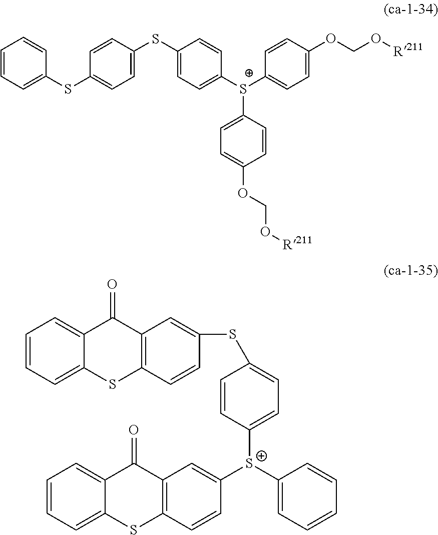

[In the formula, R′²¹¹ represents an alkyl group. R^{hal} represents a hydrogen atom or a halogen atom.]

In addition, the cation represented by General Formula (ca-1) is preferably a cation represented by each of General Formulae (ca-1-36) to (ca-1-46) shown below.

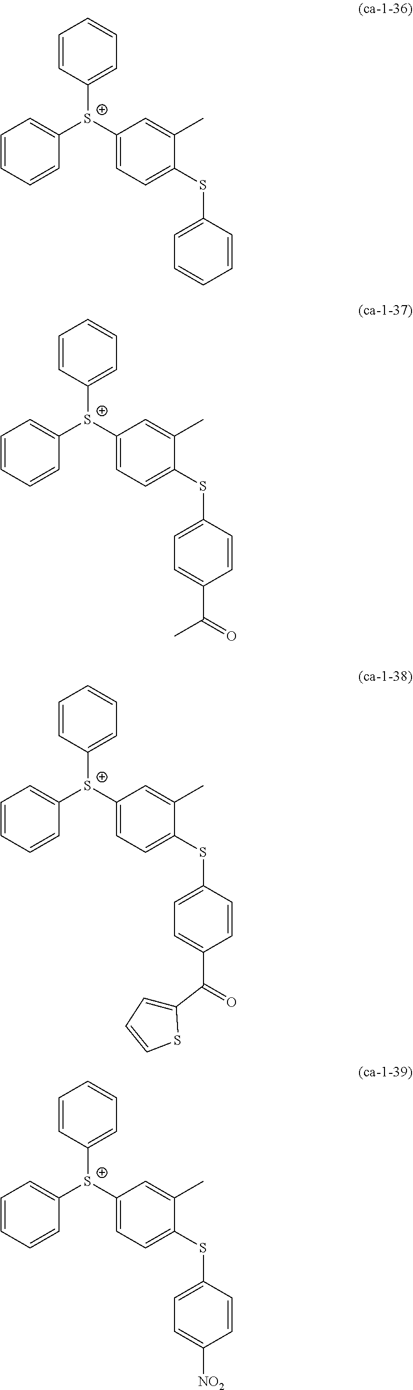

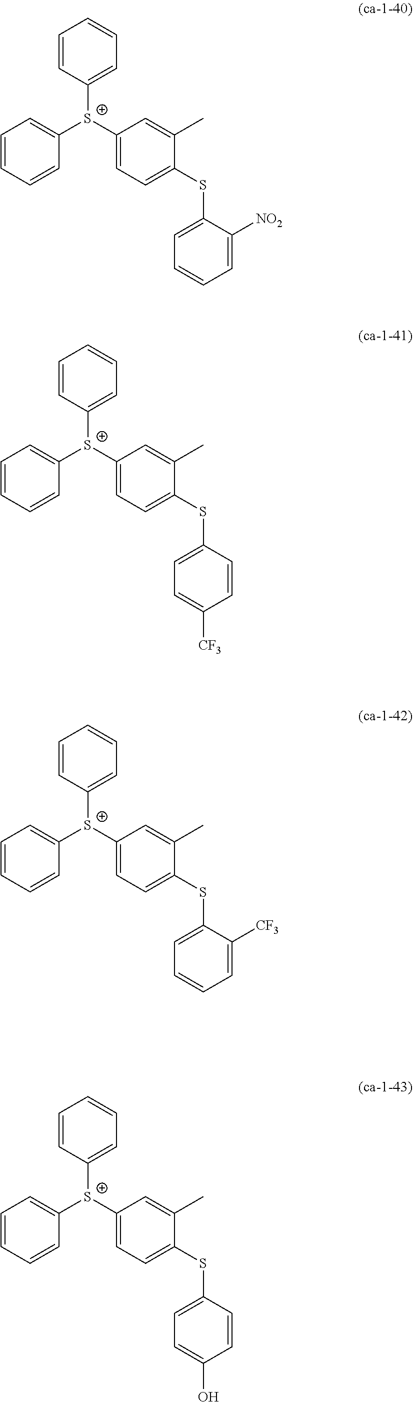

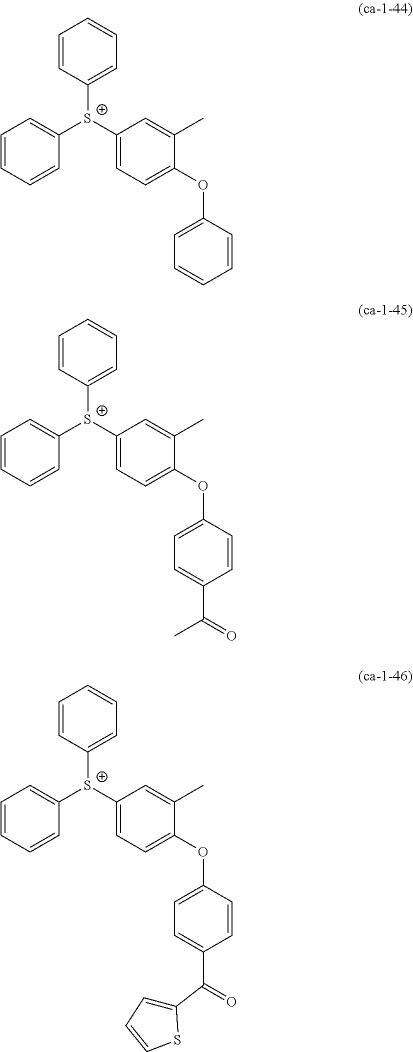

Specific examples of the suitable cation represented by General Formula (ca-2) include a diphenyliodonium cation and a bis(4-tert-butylphenyl)iodonium cation.

Specific examples of the suitable cation represented by General Formula (ca-4) include a cation represented by each of General Formulae (ca-4-1) and (ca-4-2).

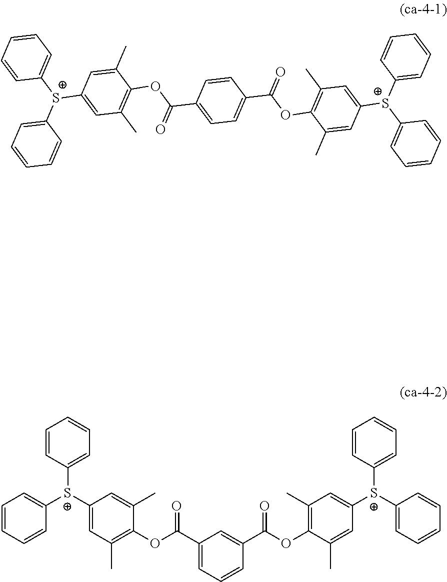

In addition, the cation represented by General Formula (ca-5) is also preferably a cation represented by each of General Formulae (ca-5-1) to (ca-5-3) shown below.

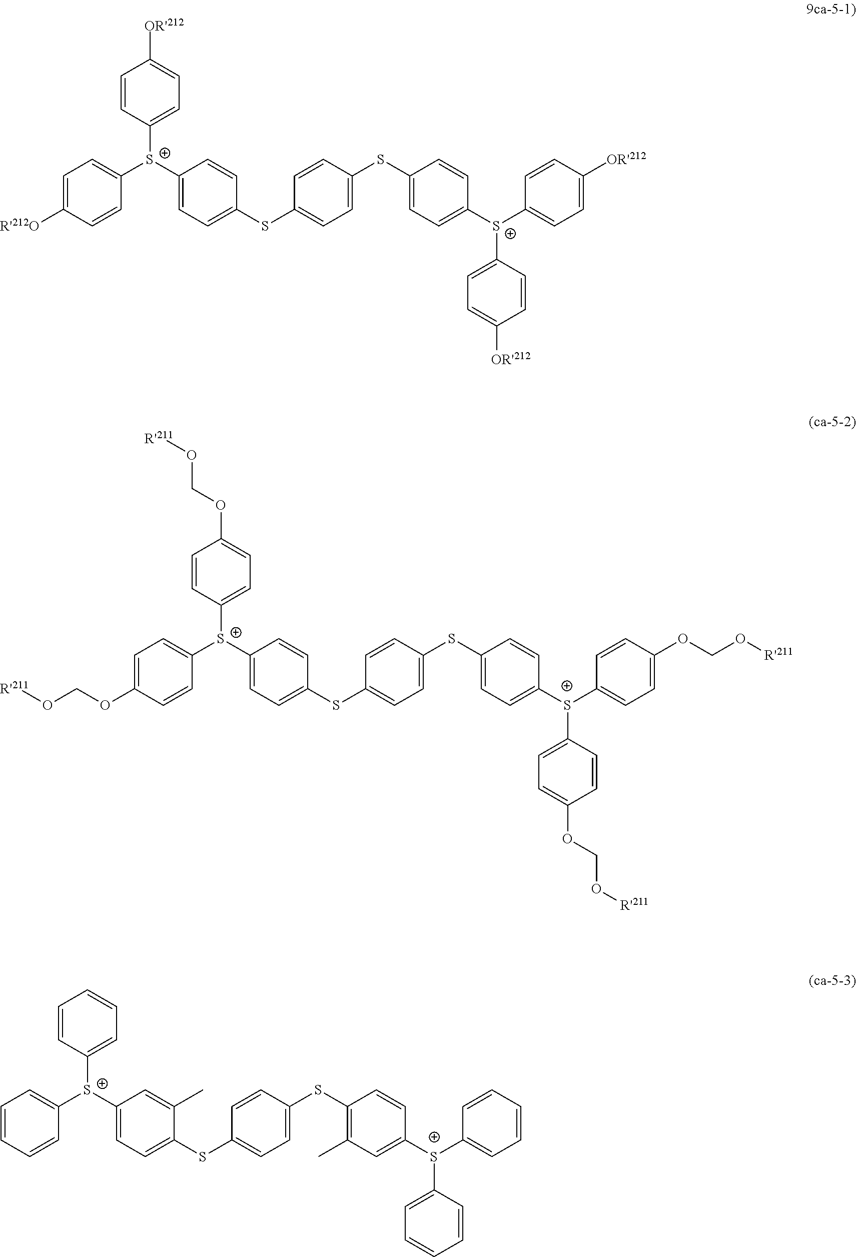

[In the formula, R′²¹² represents an alkyl group or a hydrogen atom. R′²¹¹ represents an alkyl group.]

Among the above, the cation moiety is preferably a cation represented by General Formula (ca-1), and more preferably a cation represented by each of General Formulae (ca-1-1) to (ca-1-46).

Examples of the onium salt-based acid generator include onium salts having, in the anion moiety, an anion represented by General Formula (b-an1), an anion represented by General Formula (b-an2), and an anion represented by each of General Formulae (b-1) to (b-3).

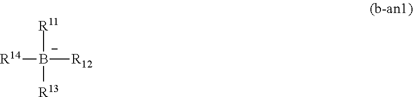

[In the formula, R¹¹ to R¹⁴ each independently represent a fluorine atom, an alkyl group which may have a substituent, or an aryl group.]

In General Formula (b-an1), the alkyl group as R¹¹ to R¹⁴ is preferably an alkyl having 1 to 20 carbon atoms, and examples thereof include the same chain-like or cyclic alkyl group as Ra′³ in General Formula (a1-r-1).

The aryl group as R¹¹ to R¹⁴ is preferably a phenyl group or a naphthyl group.

Examples of the substituent which may be contained in R¹¹ to R¹⁴ in a case where they are an alkyl group or an aryl group include a halogen atom, a halogenated alkyl group, an alkyl group, an alkoxy group, an alkylthio group, a hydroxyl group, and a carbonyl group. Examples of the alkylthio group include those having 1 to 4 carbon atoms. Among them, a halogen atom, a halogenated alkyl group, an alkyl group, an alkoxy group, or an alkylthio group is preferable.

In General Formula (b-an1), R¹¹ to R¹⁴ are preferably a fluorine atom, a fluorinated alkyl group, or a group represented by General Formula (b-an1′).

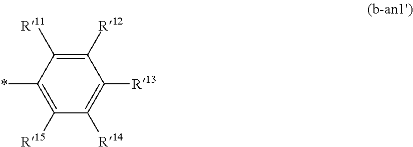

[In the formula, R′¹¹ to R′¹⁵ each independently represent a hydrogen atom, a fluorine atom, a trifluoromethyl group, an alkyl group having 1 to 4 carbon atoms, an alkoxy group, or an alkylthio group.]

In General Formula (b-an1′), examples of the alkyl group having 1 to 4 carbon atoms include a methyl group, an ethyl group, an n-propyl group, and an n-butyl group. Among these, a methyl group, an ethyl group, or an n-butyl group is preferable, and a methyl group or an ethyl group is more preferable.

In General Formula (b-an1′), specifically, the alkoxy group having 1 to 4 carbon atoms is preferably a methoxy group, an ethoxy group, an n-propoxy group, an iso-propoxy group, an n-butoxy group, or a tert-butoxy group, and more preferably a methoxy group or an ethoxy group.

In General Formula (b-an1′), the alkylthio group having 1 to 4 carbon atoms is preferably a methylthio group, an ethylthio group, an n-propylthio group, an iso-propylthio group, an n-butylthio group, or a tert-butylthio group, and more preferably a methylthio group or an ethylthio group.

Preferred specific examples of the anion moiety represented by General Formula (b-an1) include tetrakis(pentafluorophenyl)borate ([B(C₆F₅)₄]⁻), and tetrakis[(trifluoromethyl)phenyl]borate ([B(C₆H₄CF₃)₄]⁻), difluorobis(pentafluorophenyl)borate ([(C₆F₅)₂BF₂]⁻), trifluoro(pentafluorophenyl)borate ([(C₆F₅)BF₃]⁻), and tetrakis(difluorophenyl)borate ([B(C₆H₃F₂)₄]⁻). Among these, tetrakis(pentafluorophenyl)borate ([B(C₆H₃F₂)₄]⁻) is particularly preferable.

Next, the anion represented by General Formula (b-an2) will be described.

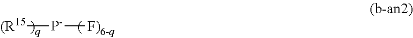

[In the formula, R¹⁵′s each independently represent a fluorinated alkyl group having 1 to 8 carbon atoms. q is in a range of 1 to 6.]

In General Formula (b-an2), specific examples of the fluorinated alkyl group having 1 to 8 carbon atoms include CF₃, CF₃CF₂, (CF₃)₂CF, CF₃CF₂CF₂, CF₃CF₂CF₂CF₂, (CF₃)₂CFCF₂, CF₃CF₂(CF₃)CF, and C(CF₃)₃.

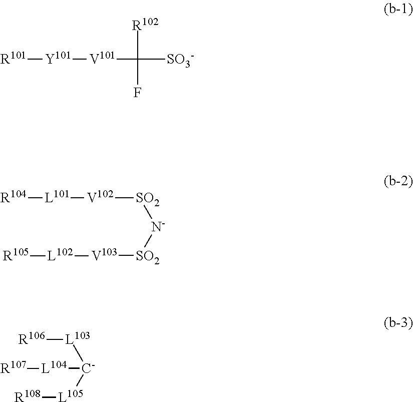

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring. Any two of R¹⁰⁶ and R¹⁰⁷ may may be bonded to each other to form a ring. R¹⁰² represents a fluorine atom or a fluorinated alkyl group having 1 to 5 carbon atoms. Y¹⁰¹ represents a single bond or a divalent linking group containing an oxygen atom. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—or —SO₂—.]

In regard to anion represented by General Formula (b-1)

In General Formula (b-1), R¹⁰¹ represents a cyclic group which may have a substituent, a chain-like alkyl group which may have a substituent, or a chain-like alkenyl group which may have a substituent.

(Cyclic group which may have substituent)

The cyclic group is preferably a cyclic hydrocarbon group, and the cyclic hydrocarbon group may be an aromatic hydrocarbon group or an aliphatic hydrocarbon group.

Examples of the aromatic hydrocarbon group as R¹⁰¹ include the aromatic hydrocarbon ring mentioned in the divalent aromatic hydrocarbon group as Va¹ of General Formula (a1-1) and an aryl group obtained by removing one hydrogen atom from an aromatic compound containing two or more aromatic rings, where a phenyl group or a naphthyl group is preferable.

Examples of the cyclic aliphatic hydrocarbon group as R¹⁰¹ include a group obtained by removing one hydrogen atom from the monocycloalkane or polycycloalkane mentioned in the divalent aliphatic hydrocarbon group as Va¹ of General Formula (a1-1), where an adamantyl group or a norbornyl group is preferable.

Further, the cyclic hydrocarbon group as R¹⁰¹ may contain a hetero atom as in the case of the heterocyclic ring or the like. Specific examples thereof include a lactone-containing cyclic group represented by each of General Formulae (a2-r-1) to (a2-r-7), a —SO₂-containing cyclic group represented by each of General Formulae (a5-r-1) to (a5-r-4), a substituted aryl group represented by each of Chemical Formulae (r-ar-1) to (r-ar-8), and a monovalent heterocyclic group represented by each of Chemical Formulae (r-hr-1) to (r-hr-16).

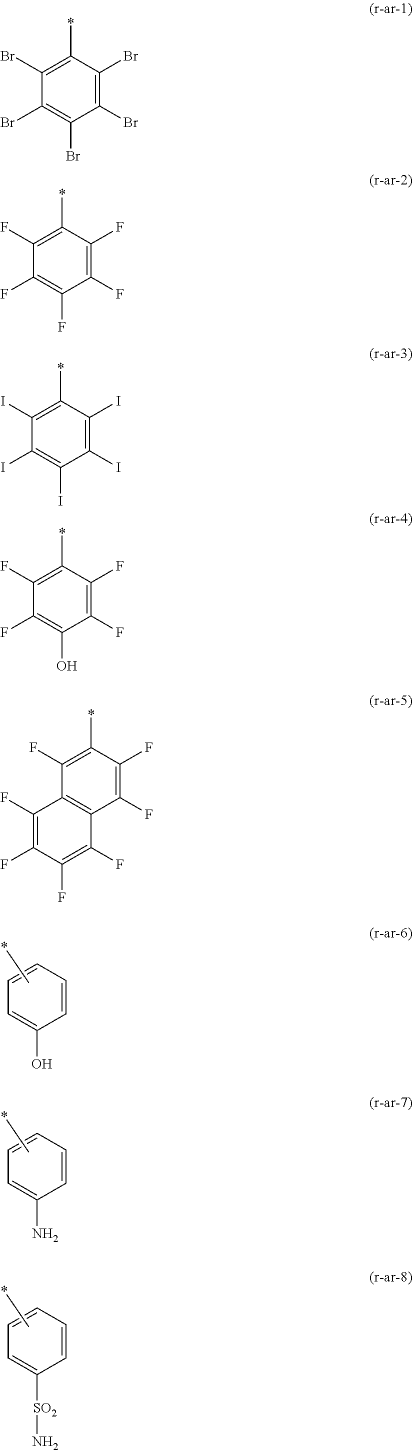

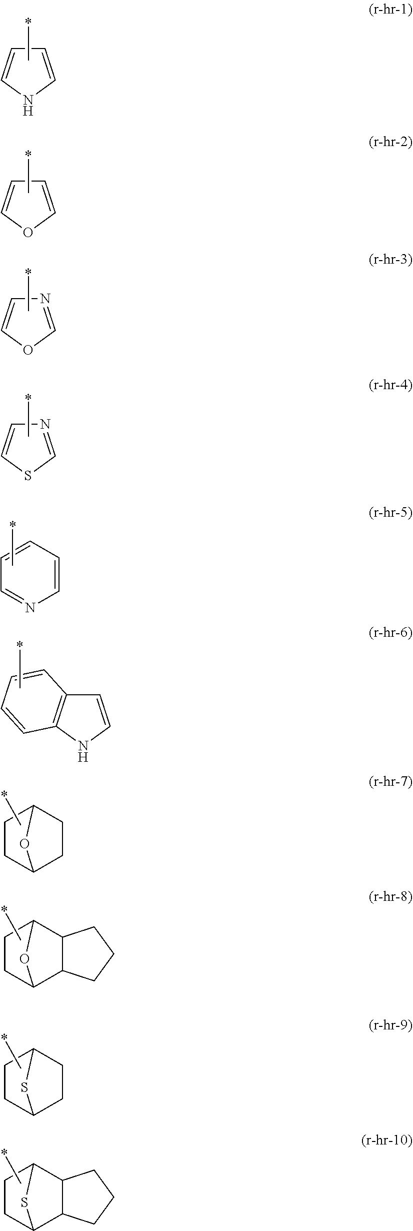

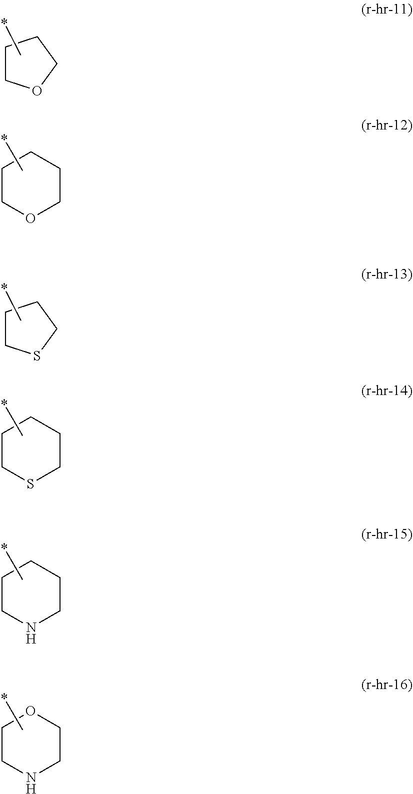

The “lactone-containing cyclic group” indicates a cyclic group that contains a ring (a lactone ring) containing a —O—C(═O)— in the ring skeleton. In a case where the lactone ring is counted as the first ring and the group contains only the lactone ring, the group is referred to as a monocyclic group. Further, in a case where the group has other ring structures, the group is referred to as a polycyclic group regardless of the structures. The lactone-containing cyclic group may be a monocyclic group or a polycyclic group.

The lactone-containing cyclic group is not particularly limited, and any lactone-containing cyclic group can be used. Specific examples thereof include a group represented by each of General Formulae (a2-r-1) to (a2-r-7) shown below.

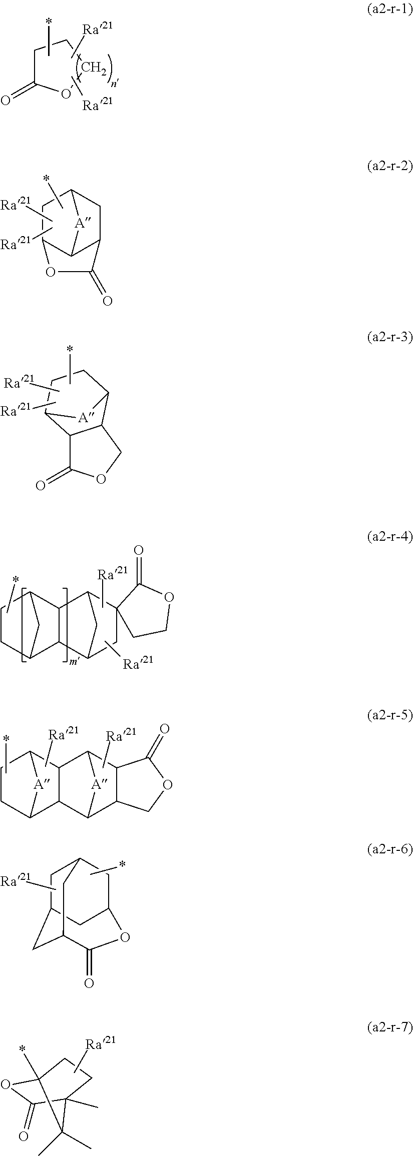

[In the formulae, each Ra′²¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom (—O—)or a sulfur atom (—S—); and n′ represents an integer in a range of 0 to 2, and m′ is 0 or 1.]

In General Formulae (a2-r-1) to (a2-r-7), the alkyl group as Ra′²¹ is preferably an alkyl group having 1 to 6 carbon atoms. The alkyl group is preferably a linear alkyl group or a branched alkyl group. Specific examples thereof include a methyl group, an ethyl group, a propyl group, an isopropyl group, an n-butyl group, an isobutyl group, a tert-butyl group, a pentyl group, an isopentyl group, a neopentyl group, and a hexyl group. Among these, a methyl group or ethyl group is preferable, and a methyl group is particularly preferable.

The alkoxy group as Ra′²¹ is preferably an alkoxy group having 1 to 6 carbon atoms. Further, the alkoxy group is preferably a linear or branched alkoxy group. Specific examples of the alkoxy groups include a group formed by linking the above-described alkyl group mentioned as the alkyl group represented by Ra′²¹ to an oxygen atom (—O—).

Examples of the halogen atom as Ra′²¹ include a fluorine atom, a chlorine atom, a bromine atom, and an iodine atom. Among these, a fluorine atom is preferable.

Examples of the halogenated alkyl group as Ra′²¹ include a group obtained by substituting part or all hydrogen atoms in the above-described alkyl group as Ra′²¹ with the above-described halogen atoms. The halogenated alkyl group is preferably a fluorinated alkyl group and particularly preferably a perfluoroalkyl group.

In —COOR″ and —OC(═O)R″ as Ra′²¹, R″ represents a hydrogen atom, an alkyl group, a lactone-containing cyclic group, a carbonate-containing cyclic group, or a —SO₂-containing cyclic group.

The alkyl group as R″ may be linear, branched, or cyclic, and preferably has 1 to 15 carbon atoms.

In a case where R″ represents a linear or branched alkyl group, it is preferably an alkyl group having 1 to 10 carbon atoms, more preferably an alkyl group having 1 to 5 carbon atoms, and particularly preferably a methyl group or an ethyl group.

In a case where R″ represents a cyclic alkyl group, the cyclic alkyl group preferably has 3 to 15 carbon atoms, more preferably 4 to 12 carbon atoms, and particularly preferably 5 to 10 carbon atoms. Specific examples thereof include a group obtained by removing one or more hydrogen atoms from a monocycloalkane, which may be or may not be substituted with a fluorine atom or a fluorinated alkyl group; and a group obtained by removing one or more hydrogen atoms from a polycycloalkane such as bicycloalkane, tricycloalkane, or tetracycloalkane. More specific examples thereof include a group obtained by removing one or more hydrogen atoms from a monocycloalkane such as cyclopentane or cyclohexane; and a group obtained by removing one or more hydrogen atoms from a polycycloalkane such as adamantane, norbornane, isobornane, tricyclodecane, or tetracyclododecane.

Examples of the lactone-containing cyclic group as R″ include the same one as the group represented by each of General Formulae (a2-r-1) to (a2-r-7).

The carbonate-containing cyclic group as R″ has the same definition as that for the carbonate-containing cyclic group described below. Specific examples of the carbonate-containing cyclic group include a group represented by each of General Formulae (ax3-r-1) to (ax3-r-3).

The —SO₂-containing cyclic group as R″ is the same as —SO₂-containing cyclic group described below. Specific examples thereof include a group represented by each of General Formulae (a5-r-1) to (a5-r-4).

The hydroxyalkyl group as Ra′²¹ preferably has 1 to 6 carbon atoms, and specific examples thereof include a group obtained by substituting at least one hydrogen atom in the alkyl group as Ra′²¹ with a hydroxyl group.

In General Formulae (a2-r-2), (a2-r-3), and (a2-r-5), as the alkylene group having 1 to 5 carbon atoms as A″, a linear or branched alkylene group is preferable, and examples thereof include a methylene group, an ethylene group, an n-propylene group, and an isopropylene group. Specific examples of the alkylene groups that contain an oxygen atom or a sulfur atom include a group obtained by interposing —O— or —S— in the terminal of the alkylene group or between the carbon atoms of the alkylene group, and examples thereof include —O—CH₂—, —CH₂—O—CH₂—, —S—CH₂—, and —CH₂—S—CH₂—. A″ is preferably an alkylene group having 1 to 5 carbon atoms or —O—, more preferably an alkylene group having 1 to 5 carbon atoms, and most preferably a methylene group.

Specific examples of the group represented by each of General Formulae (a2-r-1) to (a2-r-7) are shown below.

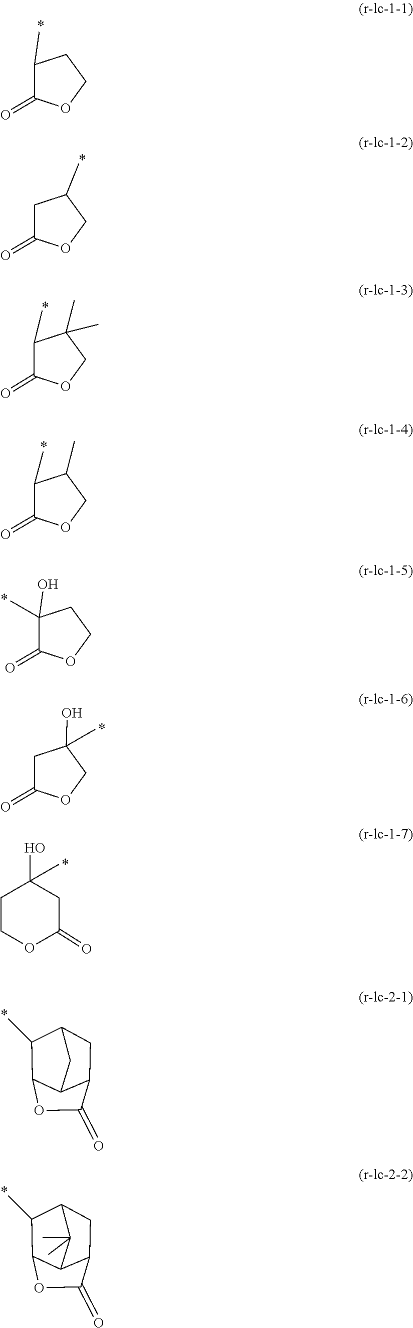

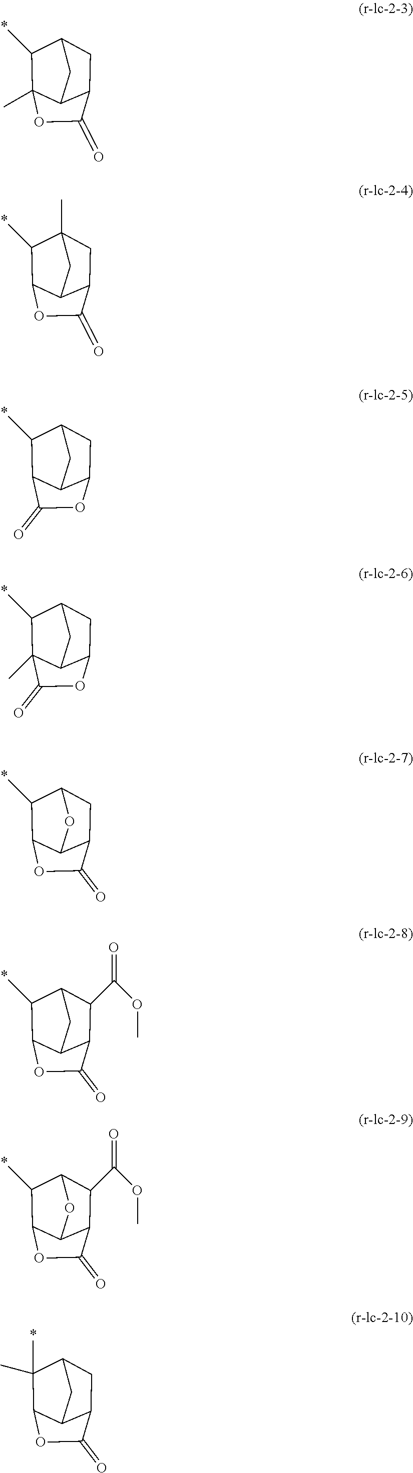

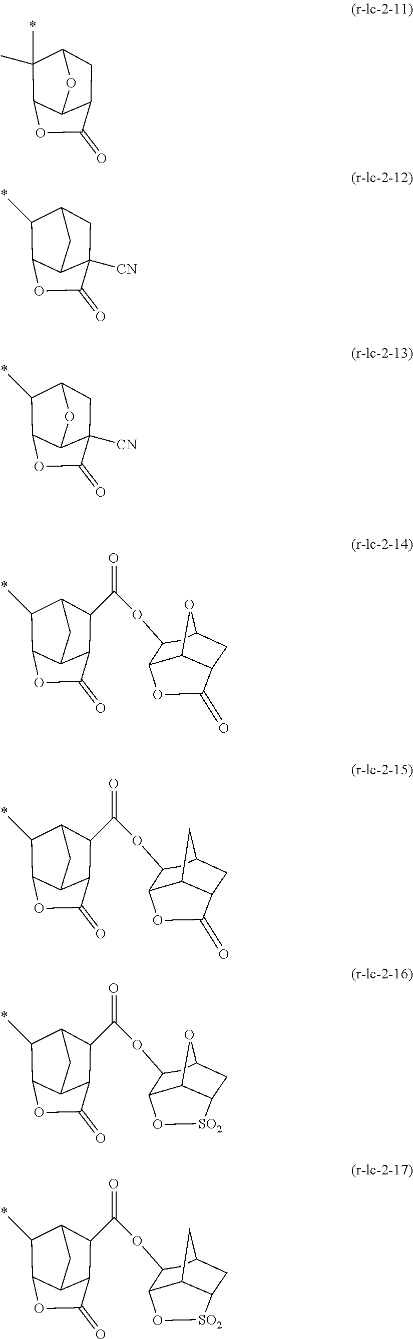

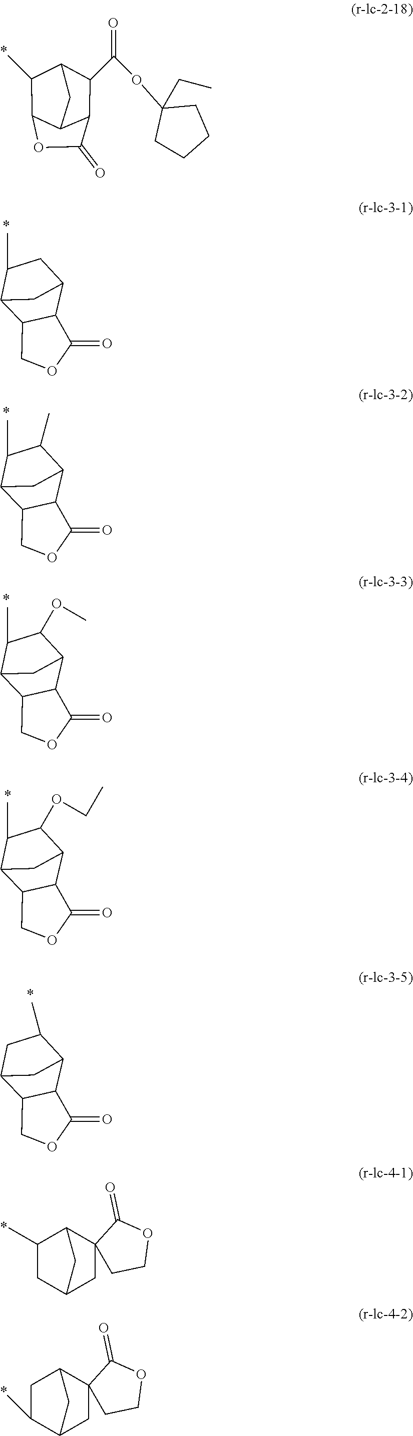

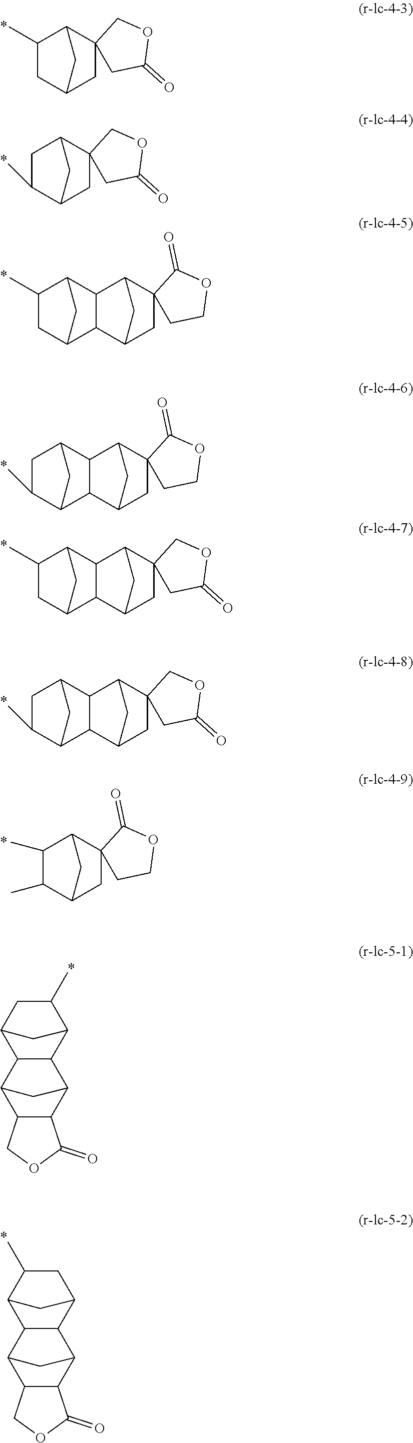

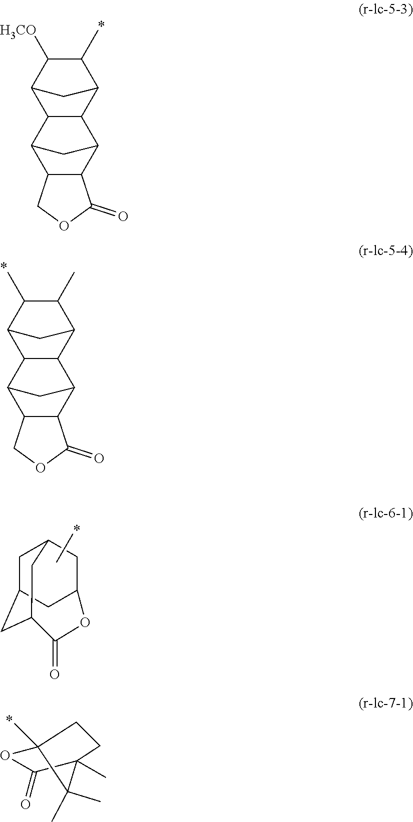

The “carbonate-containing cyclic group” indicates a cyclic group having a ring (a carbonate ring) containing —O—C(═O)—O— in the ring skeleton thereof. In a case where the carbonate ring is counted as the first ring and the group contains only the carbonate ring, the group is referred to as a monocyclic group. Further, in a case where the group has other ring structures, the group is referred to as a polycyclic group regardless of the structures. The carbonate-containing cyclic group may be a monocyclic group or a polycyclic group.

The carbonate ring-containing cyclic group is not particularly limited, and any carbonate ring-containing cyclic group may be used. Specific examples thereof include a group represented by each of General Formulae (ax3-r-1) to (ax3-r-3) shown below.

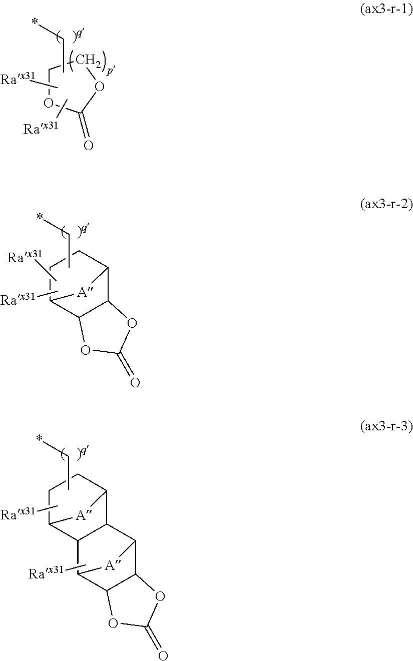

[In the formulae, Ra′^{x31}s independently represent a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom or a sulfur atom; and p′ represents an integer in a range of 0 to 3, and q′ is 0 or 1.]

In General Formulae (ax3-r-2) and (ax3-r-3), A″ has the same definition as that for A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′³¹ each include the same ones as those mentioned in the explanation on Ra′²¹ in General Formulae (a2-r-1) to (a2-r-7).

Specific examples of the group represented by each of General Formulae (ax3-r-1) to (ax3-r-3) are shown below.

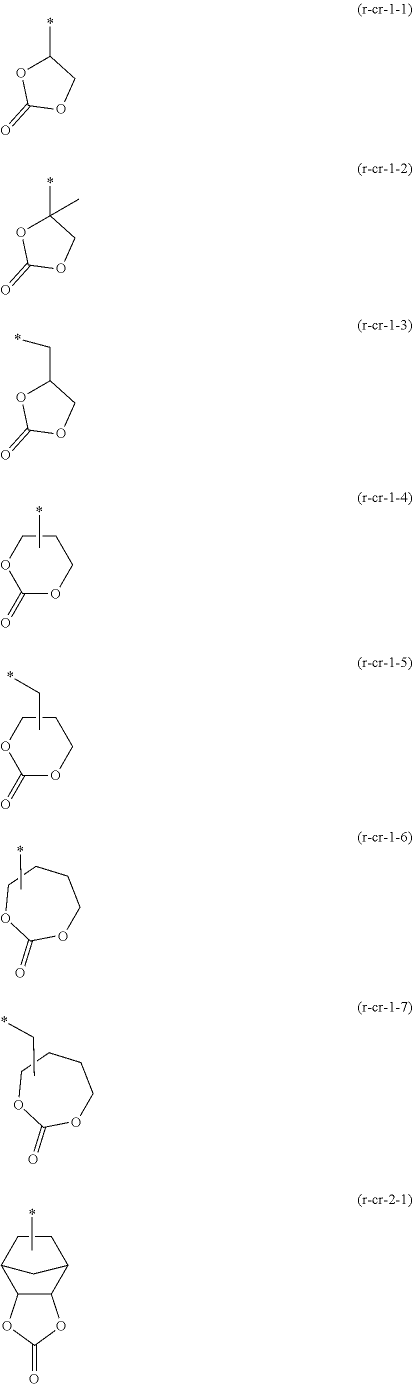

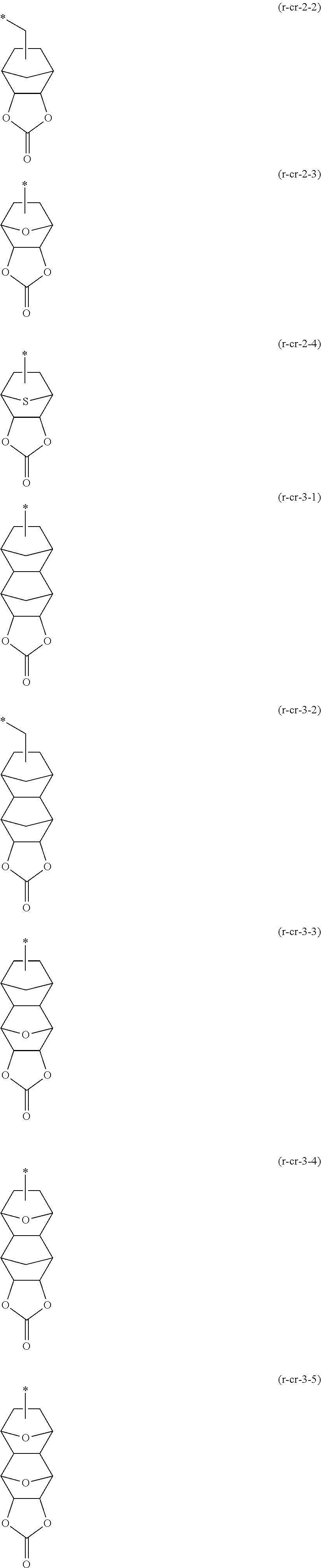

The “—SO₂-containing cyclic group” indicates a cyclic group having a ring containing —SO₂— in the ring skeleton thereof. Specifically, the —SO₂-containing cyclic group is a cyclic group in which the sulfur atom (S) in —SO₂— forms a part of the ring skeleton of the cyclic group. In a case where the ring containing —SO₂— in the ring skeleton thereof is counted as the first ring and the group contains only the ring, the group is referred to as a monocyclic group. In a case where the group further has other ring structures, the group is referred to as a polycyclic group regardless of the structures. The —SO₂-containing cyclic group may be a monocyclic group or a polycyclic group.

The —SO₂-containing cyclic group is particularly preferably a cyclic group containing —O—SO₂— in the ring skeleton thereof, in other words, a cyclic group containing a sultone ring in which —O—S—in the —O—SO₂— group forms a part of the ring skeleton thereof.

More specific examples of the —SO₂-containing cyclic group include a group represented by each of General Formulae (a5-r-1) to (a5-r-4) shown below.

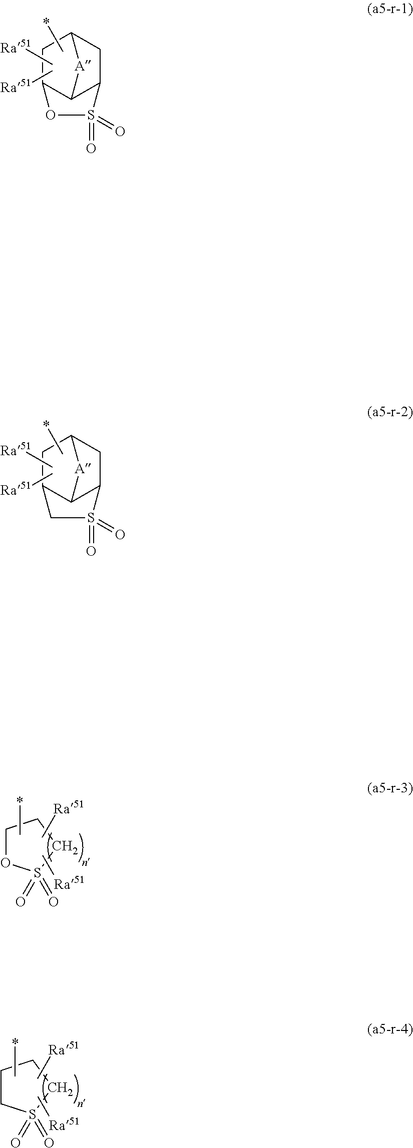

[In the formulae, each Ra′⁵¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, a carbonate-containing cyclic group, or a —SO₂-containing cyclic group; A″ represents an oxygen atom, a sulfur atom, or an alkylene group having 1 to 5 carbon atoms, which may contain an oxygen atom or a sulfur atom; and n′ represents an integer in a range of 0 to 2.]

In General Formulae (a5-r-1) and (a5-r-2), A″ has the same definition as that for A″ in General Formulae (a2-r-2), (a2-r-3) and (a2-r-5).

Examples of the alkyl group, the alkoxy group, the halogen atom, the halogenated alkyl group, —COOR″, —OC(═O)R″, and the hydroxyalkyl group as Ra′⁵¹ each include the same ones as those mentioned in the explanation on Ra′²¹ in General Formulae (a2-r-1) to (a2-r-7).

Specific examples of the group represented by each of General Formulae (a5-r-1) to (a5-r-4) are shown below. In the formulae shown below, “Ac” represents an acetyl group.

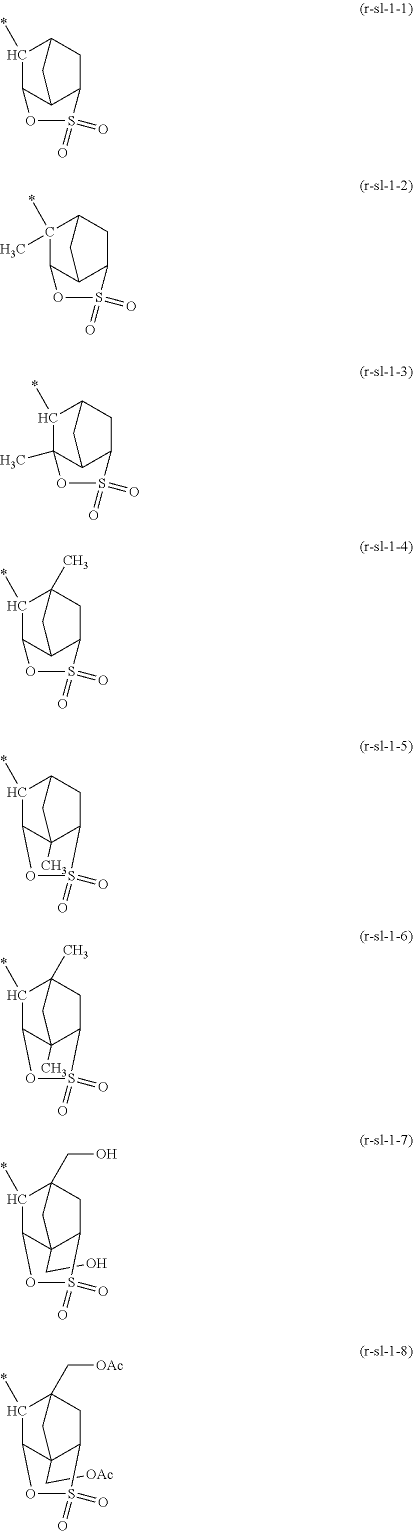

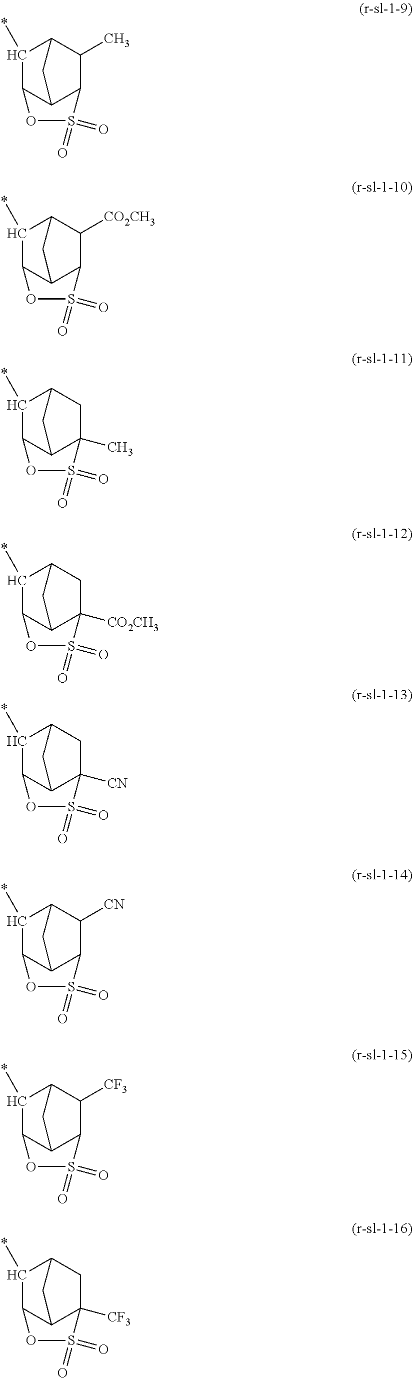

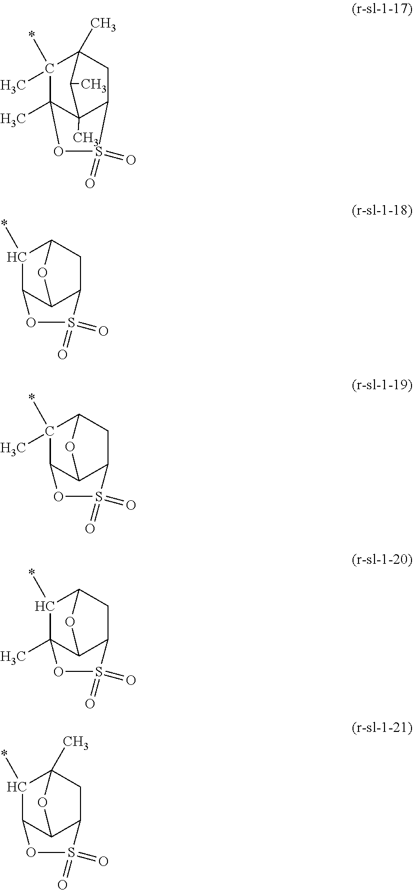

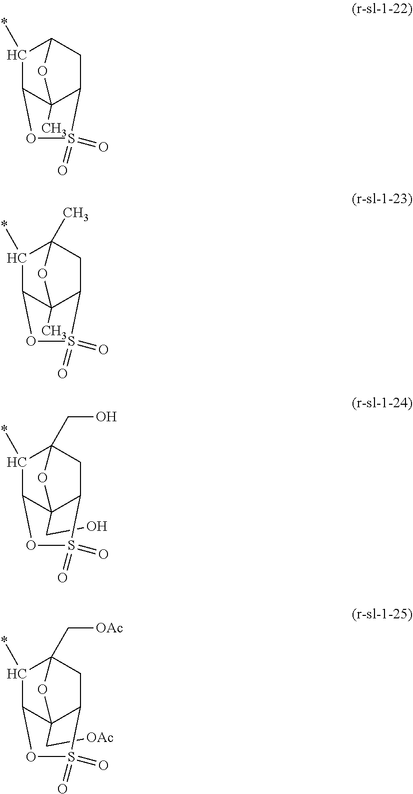

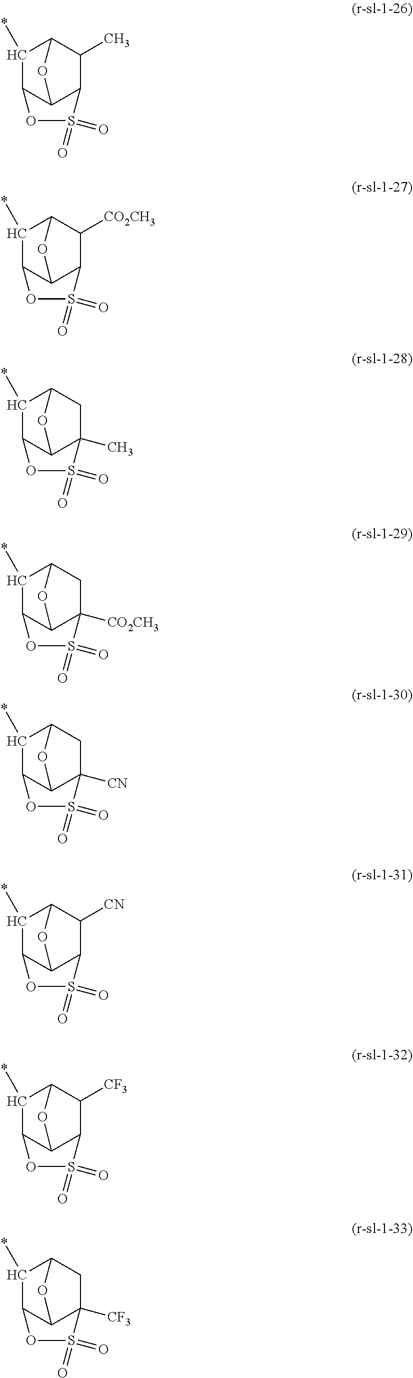

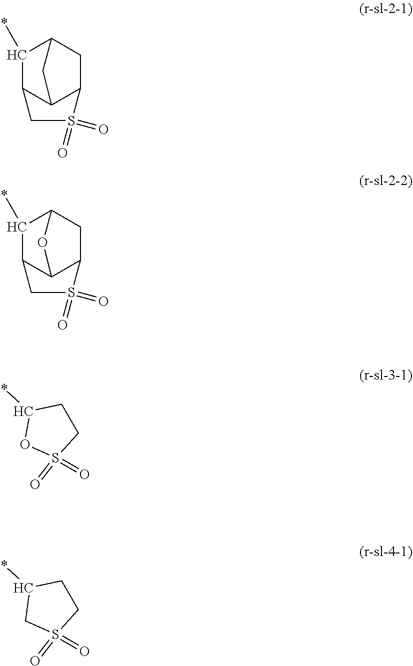

Examples of the substituent of the cyclic hydrocarbon group as R¹⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and most preferably a methyl group, an ethyl group, a propyl group, an n-butyl group, or a tert-butyl group.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Examples of the above-described halogenated alkyl group as the substituent include a group obtained by substituting part or all hydrogen atoms in an alkyl group having 1 to 5 carbon atoms such as a methyl group, an ethyl group, a propyl group, an n-butyl group, or a tert-butyl group, with the above-described halogen atom.

### (Chain-Like Alkyl Group Which May Have Substituent)

The chain-like alkyl group as R¹⁰¹ may be linear or branched.

The linear alkyl group preferably has 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecil group, an icosyl group, a henicosyl group, and a docosyl group.

The branched alkyl group preferably has 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

### (Chain-Like Alkenyl Group Which May Have Substituent)

A chain-like alkenyl group as R¹⁰¹ may be linear or branched, and the chain-like alkenyl group preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylpropenyl group and a 2-methylpropenyl group.

Among the above, the chain-like alkenyl group is preferably a propenyl group.

Examples of the substituent in the chain-like alkyl group or alkenyl group as R¹⁰¹, an alkoxy group, a halogen atom, a halogenated alkyl group, a hydroxyl group, a carbonyl group, a nitro group, an amino group, a cyclic group as R¹⁰¹ or the like may be used.

Among them, R¹⁰¹ is preferably a cyclic group which may have a substituent and more preferably a cyclic hydrocarbon group which may have a substituent. More specifically, it is preferably a phenyl group, a naphthyl group, a group obtained by removing one or more hydrogen atoms from a polycycloalkane, a lactone-containing cyclic group represented by each of General Formulae (a2-r-1) to (a2-r-7), a —SO₂-containing cyclic group represented by each of General Formulae (a5-r-1) to (a5-r-4), or the like.

In General Formula (b-1), Y¹⁰¹ represents a single bond or a divalent linking group containing an oxygen atom.

In a case where Y¹⁰¹ represents a divalent linking group containing an oxygen atom, Y¹⁰¹ may contain an atom other than the oxygen atom. Examples of the atom other than the oxygen atom include a carbon atom, a hydrogen atom, a sulfur atom, and a nitrogen atom.

Examples of the divalent linking group containing an oxygen atom include a non-hydrocarbon-based oxygen atom-containing linking group such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and a combination of the above-described non-hydrocarbon-based oxygen atom-containing linking group with an alkylene group. Furthermore, a sulfonyl group (—SO2—) may be linked to the above combination. Examples of the above combination include a linking group represented by each of General Formulae (y-a1-1) to (y-a1-7).

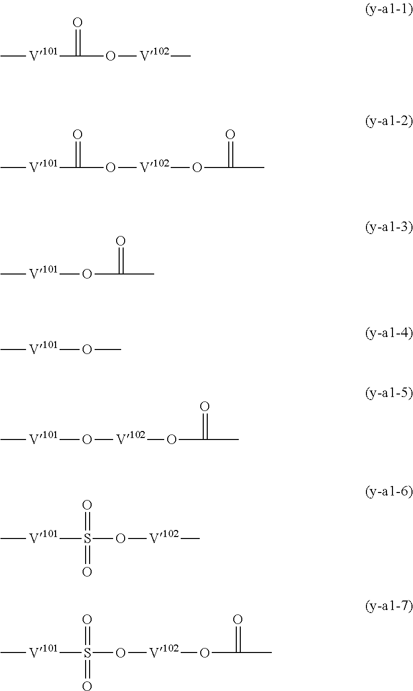

[In the formulae, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group as V′¹⁰² is preferably an alkylene group having 1 to 30 carbon atoms.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂—or —CH₂CH(CH₃)CH₂—; a tetramethylene group [—CH₂CH₂CH₂CH₂—]; an alkyltetramethylene group such as —CH(CH₃)CH₂CH₂CH₂—, or —CH₂CH(CH₃)CH₂CH₂—; and a pentamethylene group [—CH₂CH₂CH₂CH₂CH₂—].

Further, part of methylene groups in the alkylene group as V′¹⁰¹ and V′¹⁰² may be substituted with a divalent aliphatic cyclic group having 5 to 10 carbon atoms. The aliphatic cyclic group is preferably a divalent group in which one hydrogen atom has been removed from the cyclic aliphatic hydrocarbon group as Ra′³ in General Formula (a1-r-1), and a cyclohexylene group, a 1,5-adamantylene group, or a 2,6-adamantylene group is more preferable.

Y¹⁰¹ is preferably a divalent linking group containing an ester bond or an ether bond, and more preferably a linking group represented by each of General Formulae (y-a1-1) to (y-a1-5).

In General Formula (b-1), V¹⁰¹ represents a single bond, an alkylene group, or a fluorinated alkylene group. The alkylene group and the fluorinated alkylene group as V¹⁰¹ preferably have 1 to 4 carbon atoms. Examples of the fluorinated alkylene group as V¹⁰¹ include a group obtained by substituting part or all of hydrogen atoms in the alkylene group as V¹⁰¹ with a fluorine atom. Among them, V¹⁰¹ is preferably a single bond or a fluorinated alkylene group having 1 to 4 carbon atoms.

In General Formula (b-1), R¹⁰² represents a fluorine atom or a fluorinated alkyl group having 1 to 5 carbon atoms. R¹⁰² is preferably a fluorine atom or a perfluoroalkyl group having 1 to 5 carbon atoms and more preferably a fluorine atom.

In a case where Y¹⁰¹ represents a single bond, specific examples of the anion moiety of the component (b-1) include a fluorinated alkyl sulfonate anion such as a trifluoromethanesulfonate anion or a perfluorobutanesulfonate anion; and in a case where Y¹⁰¹ represents a divalent linking group containing an oxygen atom, specific examples thereof include an anion represented by any one of General Formulae (an-1) to (an-3) shown below.

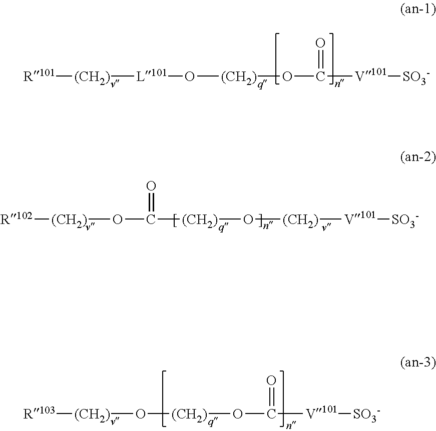

[In the formula, R″¹⁰¹ represents an aliphatic cyclic group which may have a substituent, a group represented by each of Chemical Formulae (r-hr-1) to (r-hr-6), or a chain-like alkyl group which may have a substituent; R″¹⁰² represents an aliphatic cyclic group which may have a substituent, a lactone-containing cyclic group represented by each of General Formulae (a2-r-1) to (a2-r-7), or a —SO₂-containing cyclic group represented by each of General Formulae (a5-r-1) to (a5-r-4); R″¹⁰³ represents an aromatic cyclic group which may have a substituent, an aliphatic cyclic group which may have a substituent, or a chain-like alkenyl group which may have a substituent; V″¹⁰¹ represents a fluorinated alkylene group; L″¹⁰¹ represents —C(═O)— or —SO₂—; and each v″ independently represents an integer in a range of 0 to 3, each q″ independently represents an integer in a range of 0 to 20, and n″ represents 0 or 1.]

The aliphatic cyclic group as R″¹⁰¹, R″¹⁰², and R″¹⁰³, which may have a substituent is preferably the groups exemplified as the cyclic aliphatic hydrocarbon group as R¹⁰¹. Examples of the substituent include the same one as the substituent which may be substituted for a cyclic aliphatic hydrocarbon group as R¹⁰¹.

The aromatic cyclic group which may have a substituent, as R″⁰³, is preferably the group exemplified as the aromatic hydrocarbon group for the cyclic hydrocarbon group, as R¹⁰¹. Examples of the substituent include the same one as the substituent which may be substituted for the aromatic hydrocarbon group as R¹⁰¹.

The chain-like alkyl group as R″¹⁰¹, which may have a substituent, is preferably the groups exemplified as the chain-like alkyl groups as R¹⁰¹. The chain-like alkenyl group as R″¹⁰³, which may have a substituent, is preferably the groups exemplified as the chain-like alkenyl groups as R¹⁰¹.

V″¹⁰¹ is preferably a fluorinated alkylene group having 1 to 3 carbon atoms, and particularly preferably —CF₂—, —CF₂CF₂—, —CHFCF₂—, —CF(CF₃)CF₂—, or —CH(CF₃)CF₂—.

Specific examples of the anion represented by General Formula (an-1) include the following anions. However, the present invention is not limited to these.

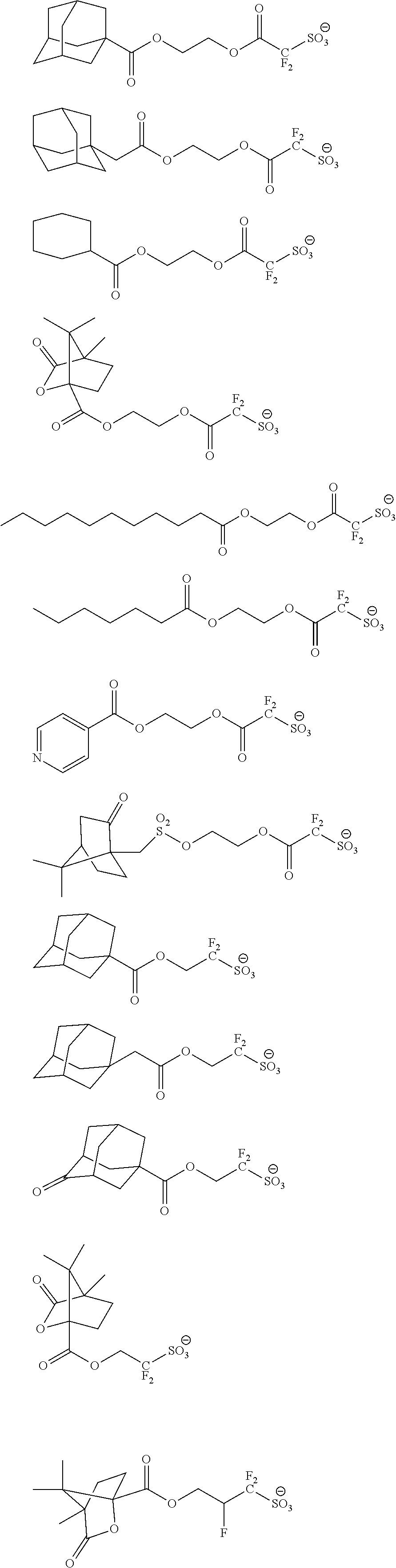

Specific examples of the anion represented by General Formula (an-2) include the following anions. However, the present invention is not limited to these.

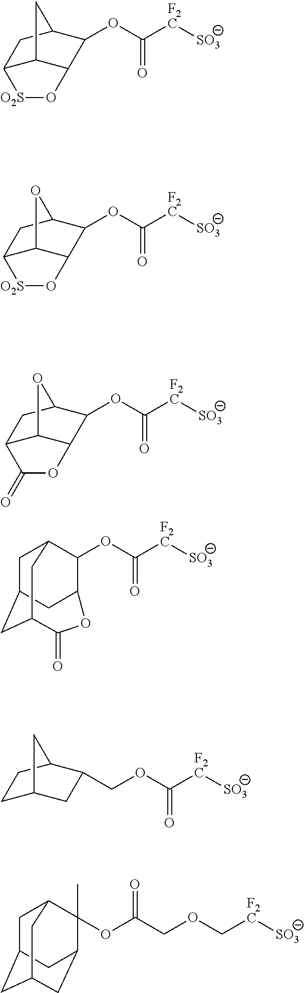

Specific examples of the anion represented by General Formula (an-3) include the following anions. However, the present invention is not limited to these.

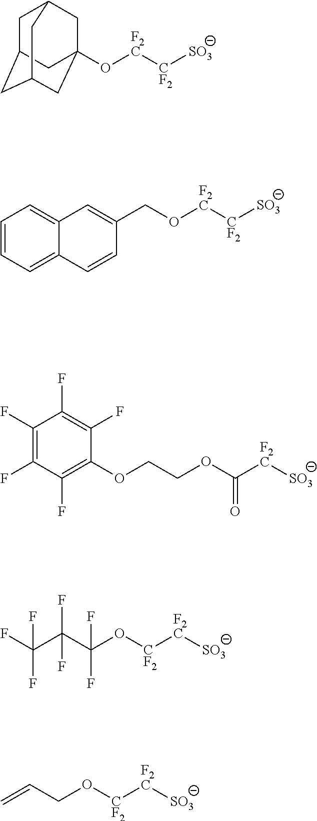

In regard to anion represented by General Formula (b-2)

In General Formula (b-2), R¹⁰⁴ and R¹⁰⁵ each independently represent a cyclic group which may have a substituent, a chain-like alkyl group which may have a substituent, or a chain-like alkenyl group which may have a substituent, and examples of each of them include the same one as R¹⁰¹ in General Formula (b-1). However, R¹⁰⁴ and R¹⁰⁵ may be bonded to each other to form a ring.

R¹⁰⁴ and R¹⁰⁵ are preferably a chain-like alkyl group which may have a substituent and more preferably a linear or branched alkyl group or a linear or branched fluorinated alkyl group.

The chain-like alkyl group preferably has 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ is small since the solubility in a resist solvent is also excellent in the above-described range of the number of carbon atoms. Further, in the chain-like alkyl group as R¹⁰⁴ and R¹⁰⁵ it is preferable that the number of hydrogen atoms substituted with a fluorine atom is large, since the acid strength increases and the transparency to high energy radiation of 200 nm or less or an electron beam is improved. The proportion of fluorine atoms in the chain-like alkyl group, that is, the fluorination rate is preferably in a range of 70% to 100% and more preferably in a range of 90% to 100%, and it is most preferable to be a perfluoroalkyl group in which all hydrogen atoms is substituted with a fluorine atom.

In General Formula (b-2), V¹⁰² and V¹⁰³ each independently represent a single bond, an alkylene group, or a fluorinated alkylene group, and examples thereof include the same one as V¹⁰¹ in General Formula (b-1).

In General Formula (b-2), L¹⁰¹ and L¹⁰² each independently represent a single bond or an oxygen atom.

Specific examples of the anion represented by General Formula (b-2) include the following anions. However, the present invention is not limited to these.

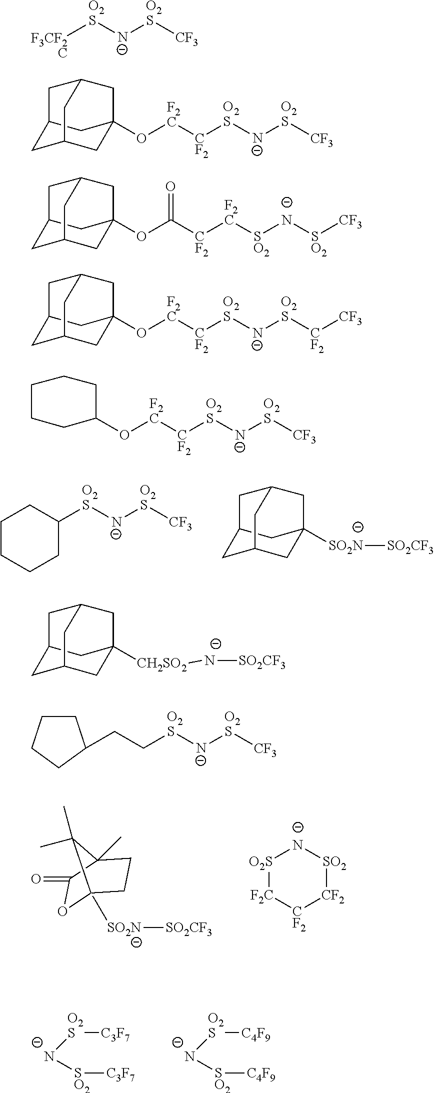

In regard to anion represented by General Formula (b-3)

In General Formula (b-3), R¹⁰⁶ to R¹⁰⁸ each independently represent a cyclic group which may have a substituent, a chain-like alkyl group which may have a substituent, or a chain-like alkenyl group which may have a substituent, and examples of each of them include the same one as R¹⁰¹ in General Formula (b-1).

L¹⁰³ to L¹⁰⁵ each independently represent a single bond, —CO—, or —SO₂—.

Specific examples of the anion represented by General Formula (b-3) include the following anions. However, the present invention is not limited to these.

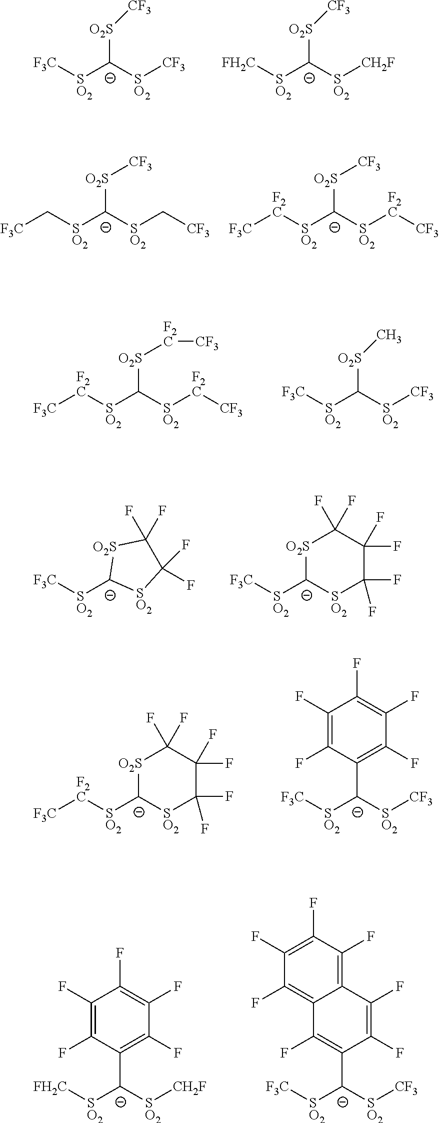

Among them, the anion moiety of the onium salt is preferably an anion represented by General Formula (b-an1), an anion represented by General Formula (b-an2), or an anion represented by General Formula (b-2), and among the above, an anion represented by General Formula (b-an2) is more preferable.

Further, the anion moiety of the onium salt may be a halogen anion, a phosphate anion, an antimonic acid anion (SbF₆⁻), or an arsenic acid anion (AsF₆⁻). Examples of the halogen anion include chlorine and bromine, and examples of the phosphate anion include PF₆⁻.

As the component (B), another acid generator other than the above may be used.

Examples of such another acid generator include halogen-containing triazine compounds such as 2,4-bis(trichloromethyl)-6-piperonyl-1,3,5-triazine, 2,4-bis(trichloromethyl)-6-[2-(2-furyl)ethenyl]-s-triazine, 2,4-bis(trichloromethyl)-6-[2-(5-methyl-2-furyl)ethenyl]-s-triazine, 2,4-bis(trichloromethyl)-6-[2-(5-ethyl-2-furyl)ethenyl]-s-triazine, 2,4-bis(trichloromethyl)-6-[2-(5-propyl-2-furyl)ethenyl]-s-triazine, 2,4-bis(trichloromethyl)-6-[2-(3,5-dimethoxyphenyl)ethenyl]-s-triazine, 2,4-bis(trichloromethyl)-6-[2-(3,5-diethoxyphenyl)ethenyl]-s-triazine, 2,4-bis(trichloromethyl)-6-[2-(3,5-dipropoxyphenyl)ethenyl]-s-triazine, 2,4-bis(trichloromethyl)-6-[2-(3-methoxy-5-ethoxyphenyl)ethenyl]-s-triazine, 2,4-bis(trichloromethyl)-6-[2-(3-methoxy-5-propoxyphenyl)ethenyl]-s-triazine, 2,4-bis(trichloromethyl)-6-[2-(3,4-methylenedioxyphenyl)ethenyl]-s-triazine, 2,4-bis(trichloromethyl)-6-(3,4-methylenedioxyphenyl)-s-triazine, 2,4-bis-trichloromethyl (3-bromo-4-methoxy)phenyl-s-triazine, 2,4-bis-trichloromethyl-6-(2-bromo methoxy)phenyl-s-triazine, 2,4-bis-trichloromethyl-6-(2-bromo-4-methoxy)styrylphenyl-s-triazine, 2,4-bis-trichloromethyl-6-(3-bromo-4-methoxy)styrylphenyl-s-triazine, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethyl)-1,3,5-triazine, 2-[2-(3,5-dimethoxyphenypethenyl]-4,6-bis(trichloromethyl)-1,3,5-triazine, 242-(3,4-dimethoxyphenypethenyl1-4,6-bis(trichloromethyl)-1,3,5-triazine, methylenedioxyphenyl)-4,6-bis(trichloromethyl)-1,3,5-triazine, tris(1,3-dibromopropyl)-1,3,5-triazine, and tris(2,3-dibromopropyl)-1,3,5-triazine; and halogen-containing triazine compounds represented by General Formula (b3), such as tris(2,3-dibromopropyl)isocyanurate.

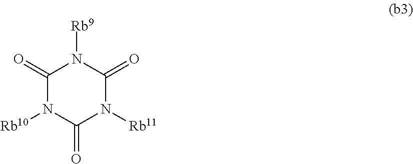

In General Formula (b3), Rb⁹, Rb¹⁰, and Rb¹¹ each independently represent a halogenated alkyl group.

Further, examples of the other acid generator include α-(p-toluenesulfonyloxyimino)-phenyl acetonitrile, α-(benzenesulfonyloxyimino)-2,4-dichlorophenyl acetonitrile, α-(benzenesulfonyloxyimino)-2,6-dichlorophenyl acetonitrile, α-(2-chlorobenzenesulfonyloxyimino)-4-methoxyphenyl acetonitrile, α-(ethylsulfonyloxyimino)-1-cyclopentenyl acetonitrile, and a compound represented by General Formula (b4), which contains an oxime sulfonate group.

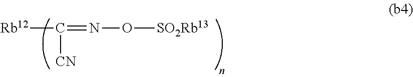

In General Formula (b4), Rb¹² represents a monovalent, divalent, or trivalent organic group, Rb¹³ represents a substituted or unsubstituted saturated hydrocarbon group, an unsaturated hydrocarbon group, or aromatic compound, and n represents the number of structures in parentheses, which are the repeating unit.

In General Formula (b4), the aromatic compound group indicates a group of a compound that exhibits physical and chemical properties peculiar to an aromatic compound, and examples thereof include aryl groups such as a phenyl group and a naphthyl group, and heteroaryl groups such as a furyl group and a thienyl group. These groups may have, on the ring, one or more proper substituents such as a halogen atom, an alkyl group, an alkoxy group, and a nitro group. Further, Rb¹³ is particularly preferably an alkyl group having 1 to 6 carbon atoms, and examples thereof include a methyl group, an ethyl group, a propyl group, and a butyl group. In particular, a compound in which Rb¹² is an aromatic compound group and Rb¹³ is an alkyl group having 1 to 4 carbon atoms is preferable.

Examples of the acid generator represented by General Formula (b4) include compounds in which in a case of n =1, Rb¹² is any one of a phenyl group, a methylphenyl group, or a methoxyphenyl group, and Rb¹³ is a methyl group, specifically, a-(methylsulfonyloxyimino)-1-phenyl acetonitrile, α-(methylsulfonyloxyimino)-1-(p-methylphenyl) acetonitrile, α-(methylsulfonyloxyimino)-1-(p-methoxyphenyl) acetonitrile, and propylsulfonyloxyimino)-2,3-dihydroxythiophene-3-ylidene](o-tolyl) acetonitrile. In a case of n=2, specific examples of the acid generator represented by General Formula (b4) include acid generators represented by the following formulae.

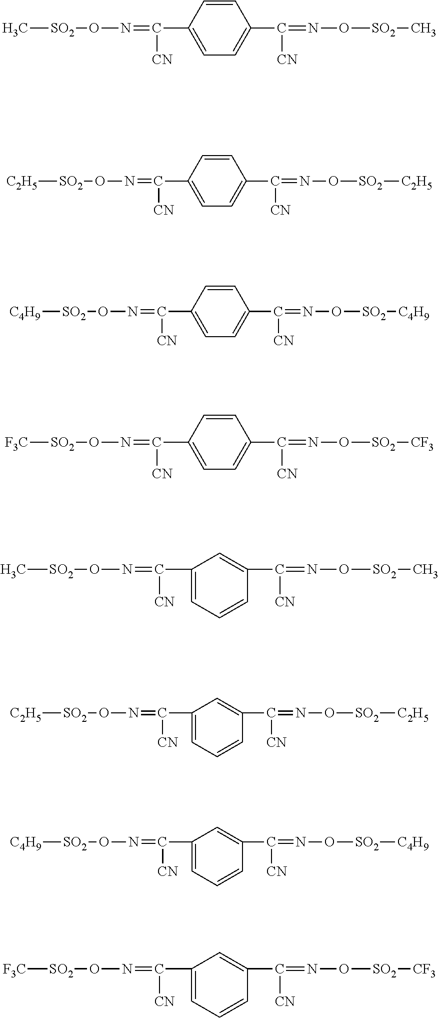

Further, examples of the other acid generator include an onium salt having a naphthalene ring in the cation moiety. “Having a naphthalene ring” means having a structure derived from naphthalene, and it means that the structure of at least two rings and the aromaticity thereof are maintained. This naphthalene ring may have a substituent such as a linear or branched alkyl group having 1 to 6 carbon atoms, a hydroxyl group, or a linear or branched alkoxy group having 1 to 6 carbon atoms. The structure derived from a naphthalene ring may be a monovalent group (having a free valence of 1) or may be a divalent group (having a free valence of 2) or a group having a higher valence; however, it may be a monovalent group (however, in this case, the free valence shall be counted by excluding the portion bonded to the above substituent). The number of naphthalene rings is preferably 1 to 3.

The cation moiety of the onium salt having a naphthalene ring in such a cation moiety is preferably a structure represented by General Formula (b5).

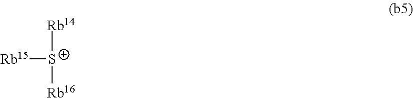

In General Formula (b5), at least one of Rb¹⁴, Rb ¹⁵, and Rb¹⁶ represents a group represented by General Formula (b6), and the rest of them represent a linear or branched alkyl group having 1 to 6 carbon atoms, a phenyl group which may have a substituent, a hydroxyl group, or a linear or branched alkoxy group having 1 to 6 carbon atoms. Alternatively, one of Rb¹⁴, Rb ¹⁵, and Rb¹⁶ represents a group represented by General Formula (b6), and the remaining two each independently represent a linear or branched alkylene group having 1 to 6 carbon atoms, where terminals thereof may be bonded to form a ring.

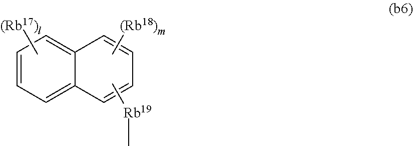

In General Formula (b6), Rb¹⁷ and Rb¹⁸ each independently represent a hydroxyl group, a linear or branched alkoxy group having 1 to 6 carbon atoms, or a linear or branched alkyl group having 1 to 6 carbon atoms, and Rb¹⁹ represents a single bond or a linear or branched alkylene group having 1 to 6 carbon atoms, which may have a substituent. 1 and m each independently represent an integer in a range of 0 to 2, and 1+m is 3 or less. However, in a case where a plurality of Rb¹⁷'s are present, they may be the same or different from each other. Further, in a case where a plurality of Rb¹⁸'s are present, they may be the same or different from each other.

Among Rb¹⁴, Rb¹⁵, and Rb¹⁶, the number of groups represented by General Formula (b6) is preferable one in terms of the stability of the compound, and the rest of them are a linear or branched alkylene group having 1 to 6 carbon atoms, where terminals thereof may be bonded to form a ring. In this case, the two alkylene groups form a 3-membered to 9-membered ring including a sulfur atom. The number of atoms (including a sulfur atom) constituting the ring is preferably 5 to 6.

Examples of the substituent which may be contained in the alkylene group include an oxygen atom (in this case, the oxygen atom and a carbon atom constituting an alkylene group form a carbonyl group) and a hydroxyl group.

Examples of the substituent which may be contained in the phenyl group include a hydroxyl group, a linear or branched alkoxy group having 1 to 6 carbon atoms, and a linear or branched alkyl group having 1 to 6 carbon atoms.

Suitable examples of the cation moiety thereof include those represented by Formulae (b7), (b8), and (b18), where a structure represented by Formula (b18) is particularly preferable.

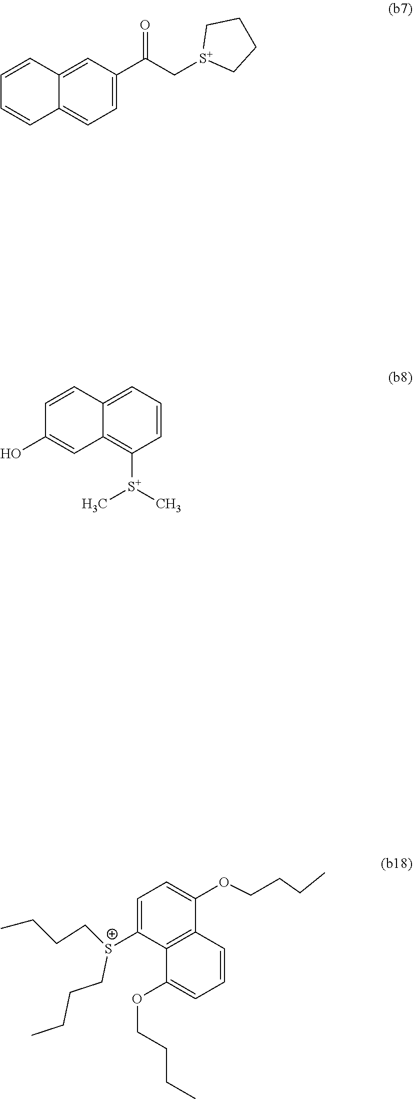 [SMILES: O=C(C[S+]1CCCC1)c1ccc2ccccc2c1 ; C[S+](C)c1cccc2ccc(O)cc12 ; CCCCOc1ccc([S+](CCCC)CCCC)c2c(OCCCC)cccc12]

Such a cation moiety may be an iodonium salt or may be a sulfonium salt; however, it is desirably a sulfonium salt in terms of acid generation efficiency and the like.

As a result, a suitable one as the anion moiety of the onium salt having a naphthalene ring in the cation moiety is desirably an anion that is capable of forming a sulfonium salt.

The anion moiety of such an acid generator is a fluoroalkyl sulfonic acid ion or aryl sulfonic acid ion, in which part or all of hydrogen atoms are fluorinated.

The alkyl group in the fluoroalkyl sulfonic acid ion may be a linear, branched, or cyclic alkyl group having 1 to 20 carbon atoms, and it preferably has 1 to 10 carbon atoms from the viewpoint of the bulkiness of acid to be generated and the diffusion distance thereof. In particular, a branched or cyclic one is preferable since it has a short diffusion distance. Further, from the viewpoint of being capable of being synthesized at a low cost, preferred examples thereof include a methyl group, an ethyl group, a propyl group, a butyl group, and an octyl group.

The aryl group in the aryl sulfonic acid ion is an aryl group having 6 to 20 carbon atoms, and examples thereof include an alkyl group, a phenyl group which may be or may not be substituted with a halogen atom, and a naphthyl group. In particular, an aryl group having 6 to 10 carbon atoms is preferable from the viewpoint of being capable of being synthesized at a low cost. Specific examples of the preferred one thereof include a phenyl group, a toluenesulfonyl group, an ethylphenyl group, a naphthyl group, and a methylnaphthyl group.

In the fluoroalkyl sulfonic acid ion or aryl sulfonic acid ion, the fluorination rate in a case where part or all of hydrogen atoms are fluorinated is preferably in a range of 10% to 100% and more preferably in a range of 50% to 100%. The particularly preferred ones are those in which all hydrogen atoms are substituted with a fluorine atom since the acid strength becomes stronger. Specific examples of such a substance include trifluoromethanesulfonate, perfluorobutanesulfonate, perfluorooctanesulfonate, and perfluorobenzenesulfonate.

Among these, examples of the preferred anion moiety include those represented by General Formula (b9).

Rb²⁰SO₃^{⊖} (b9)

In General Formula (b9), Rb²⁰ is a group represented by General Formula (b10) or (b11), or a group represented by Formula (b12).

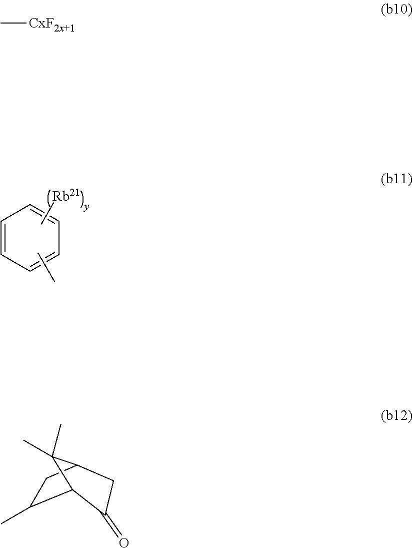

In General Formula (b10), x represents an integer in a range of 1 to 4. Further, in General Formula (b11), Rb²¹ represents a hydrogen atom, a hydroxyl group, a linear or branched alkyl group having 1 to 6 carbon atoms, or a linear or branched alkoxy group having 1 to 6 carbon atoms, and y represents an integer in a range of 1 to 3. Among the above, trifluoromethanesulfonate or perfluorobutanesulfonate is preferable from the viewpoint of safety.

Further, as the anion moiety, it is preferable to use an anion moiety containing nitrogen, which is represented by each of General Formulae (b13) and (b14).

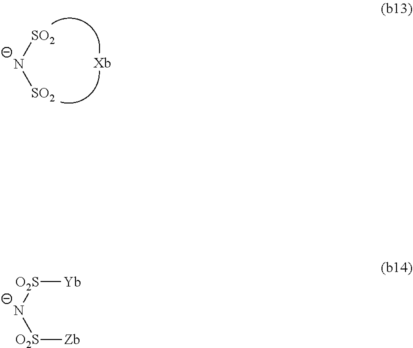

In General Formula (b13), Xb represents a linear or branched alkylene group obtained by substituting at least one hydrogen atom with a fluorine atom, where the alkylene group has 2 to 6 carbon atoms, preferably 3 to 5 carbon atoms, and most preferably 3 carbon atoms. Further, in General Formula (b14), Yb and Zb each independently represent a linear or branched alkyl group obtained by substituting at least one hydrogen atom with a fluorine atom, where the alkyl group has 1 to 10 carbon atoms, preferably 1 to 7 carbon atoms, and more preferably 1 to 3 carbon atoms.

The smaller the number of carbon atoms of the alkylene group of Xb or the number of carbon atoms of the alkyl group of Yb and Zb, the better the solubility in an organic solvent, which is preferable.

In addition, in the alkylene group of Xb or the alkyl group of Yb and Zb, the larger the number of hydrogen atoms substituted with a fluorine atom is, the stronger the acid strength is, which is preferable. The proportion of the fluorine atom in the alkylene group or alkyl group, that is, the fluorination rate is preferably in a range of 70% to 100% and more preferably in a range of 90% to 100%, and it is most preferable to be a perfluoroalkylene group or perfluoroalkyl group in which all hydrogen atoms is substituted with a fluorine atom.

Preferred examples of the onium salt having a naphthalene ring in such a cation moiety include compounds represented by General Formulae (b15), (b16), and (b17), where a compound represented by Formula (b17) is more preferable.

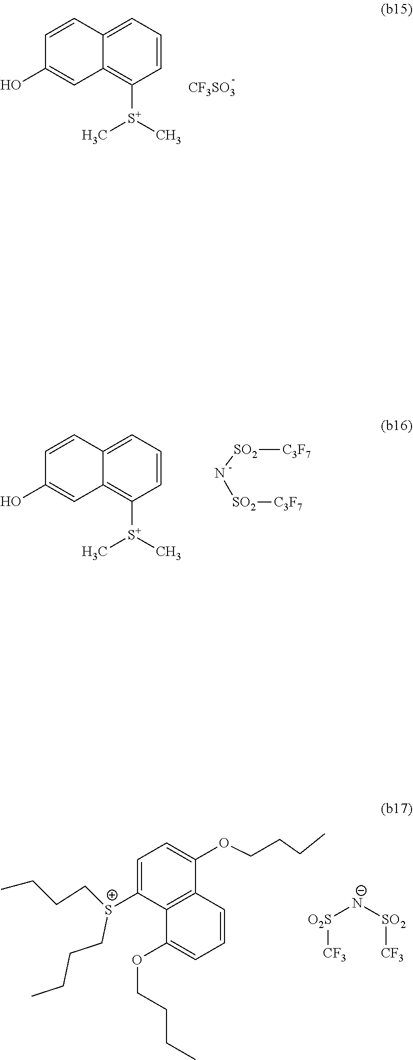

Further, examples of the other acid generator include bissulfonyldiazomethanes such as bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane; nitrobenzyl derivatives such as 2-nitrobenzyl p-toluenesulfonate, 2,6-dinitrobenzyl p-toluenesulfonate, nitrobenzyl tosylate, dinitrobenzyl tosylate, nitrobenzyl sulfonate, nitrobenzyl carbonate, and dinitrobenzyl carbonate; sulfonic acid esters such as pyrogallol trimesylate, pyrogallol tritosylate, benzyl tosylate, benzyl sulfonate, N-methylsulfonyloxysuccinimide, N-trichloromethylsulfonyloxysuccinimide, N-phenylsulfonyloxymaleimide, and N-methylsulfonyloxyphthalimide; trifluoromethanesulphonic acid esters such as N-hydroxyphthalimide and N-hydroxynaphthalimide; onium salts such as diphenyliodonium hexafluorophosphate, (4-methoxyphenyl)phenyliodonium trifluoromethanesulfonate, bis(p-tert-butylphenyl)iodonium trifluoromethanesulfonate, triphenylsulfonium hexafluorophosphate, (4-methoxyphenyl)diphenylsulfonium trifluoromethanesulfonate, and (p-tert-butylphenyl)diphenylsulfonium trifluoromethanesulfonate; benzoin tosylates such as benzoin tosylate and α-methylbenzoin tosylate; another diphenyliodonium salt; a triphenylsulfonium salt; a phenyldiazonium salt; and a benzyl carbonate.

The other preferred acid generator is a compound having a cation represented by General Formula (b5) in the cation moiety, where it is preferable that Rb¹⁷ and Rb¹⁸ in General Formula (b6) each independently represent a linear or branched alkoxy group having 1 to 6 carbon atoms, and Rb¹⁹ represents a single bond.

The acid generator (B) may be used alone, or two or more kinds thereof may be used in combination.

The content of the acid generator (B) in the resist composition is not particularly limited as long as the patterning is possible with the amount thereof, and it can be freely determined in consideration of the kind of acid generator, the resin component, other additives, and the film thickness to be used. For example, the content of the acid generator (B) is preferably in a range of 0.1 to 10 parts by mass with respect to 100 parts by mass of the resin component (the component (P)).

### <Other Components>

The resist composition that is used in the resist pattern formation method according to the present embodiment may further contain components (other components) other than the above-described component (P) and component (B), as necessary.

Examples of such other components include a component (F), a component (E), a component (C), and a component (S), which are described below.

Component (F): In regard to acid diffusion controlling agent component

It is preferable that the resist composition according to the present embodiment further contains an acid diffusion controlling agent component (hereinafter, also referred to as a “component (F)”) in order to improve the shape of the resist pattern to be used as a mold and the post-exposure stability of the resist film or the like. The component (F) is preferably a nitrogen-containing compound (hereinafter, also referred to as a “component (F1)”), and as necessary, it can contain an organic carboxylic acid or an oxo acid of phosphorus or a derivative thereof (hereinafter, also referred to as a “component (F2)”).

Component (F1): In regard to nitrogen-containing compound

Examples of the component (F1) include trimethylamine, diethylamine, triethylamine, di-n-propylamine, tri-n-propylamine, tri-n-pentylamine (triamylamine), n-hexylamine, n-heptylamine, n-octylamine, n-nonylamine, tribenzylamine, diethanolamine, triethanolamine, ethylenediamine, N,N,N′,N′-tetramethylethylenediamine, tetramethylenediamine, hexamethylenediamine, 4,4′-diaminodiphenylmethane, 4,4′-diaminodiphenyl ether, 4,4′-diaminobenzophenone, 4,4′-diaminodiphenylamine, formamide, N-methylformamide, N,N-dimethylformamide, acetamide, N-methylacetamide, N,N-dimethylacetamide, propionamide, benzamide, pyrrolidone, N-methylpyrrolidone, methylurea, 1,1-dimethylurea, 1,3-dimethylurea, 1,1,3,3-tetramethylurea, 1,3-diphenylurea, imidazole, benzimidazole, 4-methylimidazole, 8-oxyquinolin, acridine, purine, pyrrolidine, piperidine, 2,4,6-tri(2-pyridyl)-S-triazine, morpholine, 4-methylmorpholine, piperazine, 1,4-dimethylpiperazine, 1,4-diazabicyclo[2.2.2]octane, and pyridine.

The following substances can also be used as the component (F1): commercially available hindered amine compounds such as ADEKA STAB LA-52, ADEKA STAB LA-57, ADEKA STAB LA-63P, ADEKA STAB LA-68, ADEKA STAB LA-72, ADEKA STAB LA-77Y, ADEKA STAB LA-77G, ADEKA STAB LA-81, ADEKA STAB LA-82, and ADEKA STAB LA-87 (all manufactured by ADEKA Corporation); pyridines substituted with a substituent such as a hydrocarbon group at the 2,6-position or 2,4,6-position, such as 2,6-diphenylpyridine, 2,6-di-tert-butylpyridine, 2,4,6-triphenylpyridine, 2,4,6-tri-tert-butylpyridine; and piperidines substituted with a substituent such as a hydrocarbon group at a substitutable portion such as 2,6-dimethylpiperidine, 1,3,5-trimethylpiperidine, 2,4,6-trimethylpiperidine, or 2,2,6,6-tetramethylpiperidine.

The component (F1) may be used alone, or two or more kinds thereof may be used in combination.

The content of the component (F1) in the resist composition is generally in a range of 0 parts by mass or more and 5 parts by mass or less with respect to 100 parts by mass of the resin component (the component (P)), and it is preferably in a range of 0 parts by mass or more and 3 parts by mass or less, and more preferably 0 parts by mass or more and 1 part by mass or less. In a case where it is within the above range, the resist pattern shape, the post-exposure temporal stability, and the like are improved.

Component (F2): In regard to organic carboxylic acid or oxoacid of phosphorus or derivative thereof

The organic carboxylic acid as the component (F2) is preferably malonic acid, citric acid, malic acid, succinic acid, benzoic acid, or salicylic acid, and particularly preferably salicylic acid.

Examples of the oxo acid of phosphorus or derivative thereof, as the component (F2), include phosphoric acid or derivatives such as esters thereof, such as phosphoric acid, phosphoric acid di-n-butyl ester, and phosphoric acid diphenyl ester; phosphonic acid or derivatives such as esters thereof, such as phosphonic acid, phosphonic acid dimethyl ester, phosphonic acid-di-n-butyl ester, phenyl phosphonate, phosphonic acid diphenyl ester, and phosphonic acid dibenzyl ester; and phosphinic acid or derivatives such as esters thereof, such as phosphinic acid and phenyl phosphinate. Among these, phosphonic acid is particularly preferable.

The component (F2) may be used alone, or two or more kinds thereof may be used in combination.

The content of the component (F2) in the resist composition is generally in a range of 0 parts by mass or more and 5 parts by mass or less with respect to 100 parts by mass of the resin component (the component (P)), and it is preferably in a range of 0 parts by mass or more and 3 parts by mass or less, and more preferably 0 parts by mass or more and 1 part by mass or less.

Further, for the component (F), it is preferable to use the component (F2) and the component (F1) in the same amount.

Component (E): In regard to sulfur-containing compound

In a case of being used in the pattern formation on a metal substrate, the resist composition according to the present embodiment preferably further contains a sulfur-containing compound (hereinafter, also referred to as a “component (E)”).

The component (E) is a compound containing a sulfur atom that can be coordinated with a metal. It is noted that regarding a compound capable of generating two or more tautomers, in a case where at least one tautomer contains a sulfur atom that is coordinated with a metal constituting the metal layer, the compound corresponds to a sulfur-containing compound.

In a case where a resist pattern that is used as a plating mold is formed on a surface consisting of a metal such as Cu, defects in the cross-sectional shape such as footing easily occur. However, in a case where the resist composition contains the component (E), defects in the cross-sectional shape such as footing hardly occur even in a case where a resist pattern is formed on a surface of a substrate, consisting of a metal.

In a case where the resist composition is used in the pattern formation on a substrate other than the metal substrate, it is not particularly necessary for the resist composition to contain the component (E). It is noted that no particular defects are caused in a case where the resist composition that is used in the pattern formation on a substrate other than the metal substrate contains the component (E).

The sulfur atom that can be coordinated with a metal is included in a sulfur-containing compound as a mercapto group (—SH), a thiocarboxy group (—CO—SH), a dithiocarboxy group (—CS—SH), a thiocarbonyl group (—CS—), or the like.

The component (E) is preferably one having a mercapto group since it is easy to be coordinated with a metal and is excellent in the effect of suppressing footing.

Preferred examples of the sulfur-containing compound having a mercapto group include a compound represented by General Formula (e1).

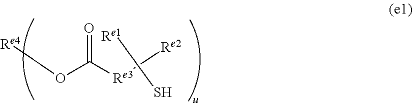

[In the formula, R^{e1} and R^{e2} each independently represent a hydrogen atom or an alkyl group. R^{e3} represents a single bond or an alkylene group. R^{e4} represents a u-valent aliphatic group which may contain an atom other than the carbon atom. u represents an integer of 2 or more and 4 or less.]

In a case where R^{e1} and R^{e2} are an alkyl group, the alkyl group may be linear or branched, and it is preferably linear. In a case where R^{e1} and R^{e2} are an alkyl group, the number of carbon atoms of the alkyl group is not particularly limited as long as the object of the present invention is not impaired. The number of carbon atoms of the alkyl group is preferably 1 or more and 4 or less, particularly preferably 1 or 2, and most preferably 1. The combination of R^{e1} and R^{e2} is preferably a combination in which one is a hydrogen atom and the other is an alkyl group, and it is particularly preferably a combination in which one is a hydrogen atom and the other is a methyl group.

In a case where R^{e3} is an alkylene group, the alkylene group may be linear or branched, and it is preferably linear. In a case where R^{e3} is an alkylene group, the number of carbon atoms of the alkylene group is not particularly limited as long as the object of the present invention is not impaired. The number of carbon atoms of the alkylene group is preferably 1 or more and 10 or less, more preferably 1 or more and 5 or less, particularly preferably 1 or 2, and most preferably 1.

R^{e4} represents an aliphatic group having a valence of 2 or more and 4 or less, which may contain an atom other than the carbon atom. Examples of the atom other than the carbon atom, which may be contained in R^{e4}, include a nitrogen atom, an oxygen atom, a sulfur atom, a fluorine atom, a chlorine atom, a bromine atom, and an iodine atom. The structure of the aliphatic group which is Re^{e4} may be linear, may be branched, or may be cyclic, and it may be a structure obtained by combining these structures.

Among the compounds represented by General Formula (e1), a compound represented by General Formula (e2) is more preferable.

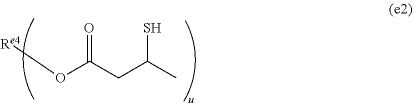

[In General Formula (e2), R^{e4} and u are the same as those in General Formula (e1).]

Among the compounds represented by General Formula (e2), the following compounds are preferable.

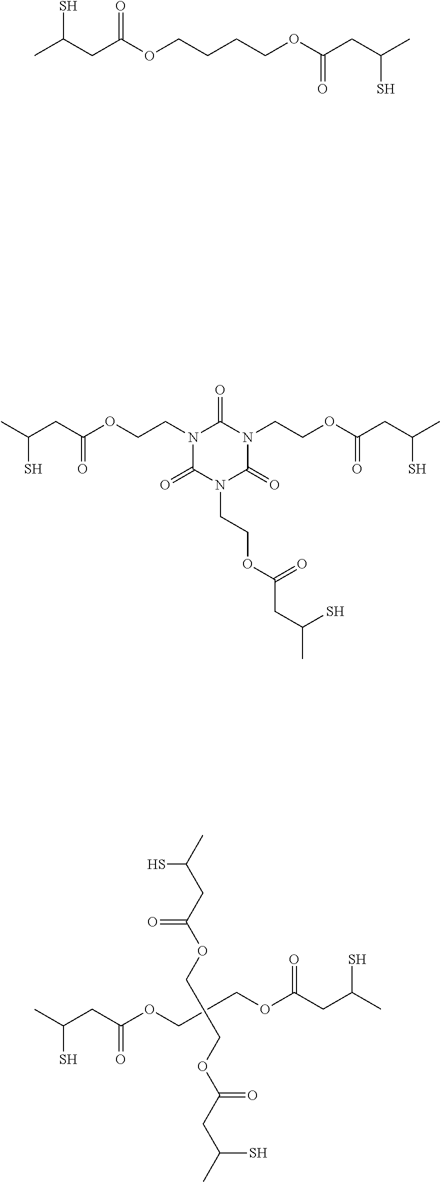

Preferred examples of the sulfur-containing compound having a mercapto group also include compounds represented by General Formulae (e3-L1) to (e3-L7).

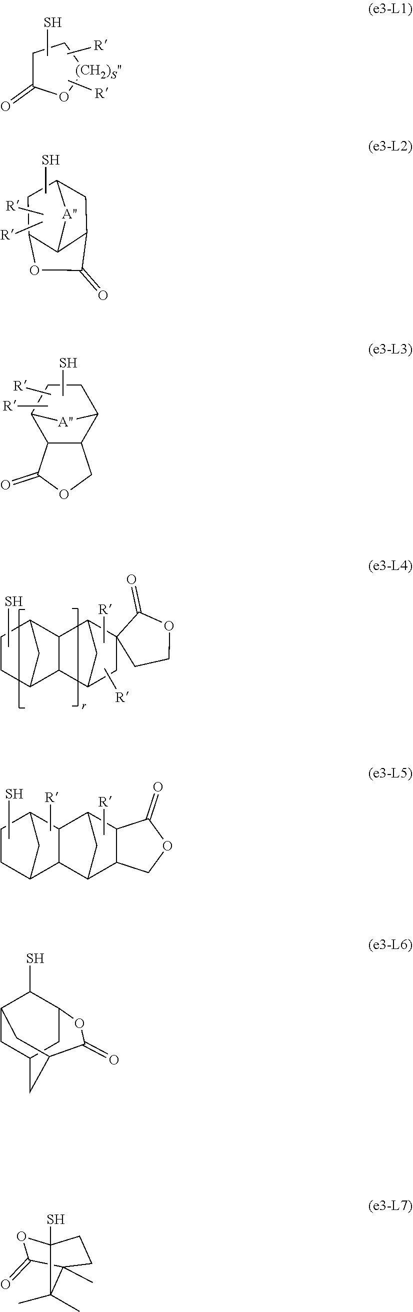

[In Formulae (e3-L1) to (e3-L7), R′, s″, A″, and r are the same as Ra′²¹, n′, A″, and m′ in General Formulae (a2-r-1) to (a2-r-7).]

Suitable specific examples of the sulfur-containing compound having a mercapto group represented by General Formulae (e3-L1) to (e3-L7) include the following compounds.

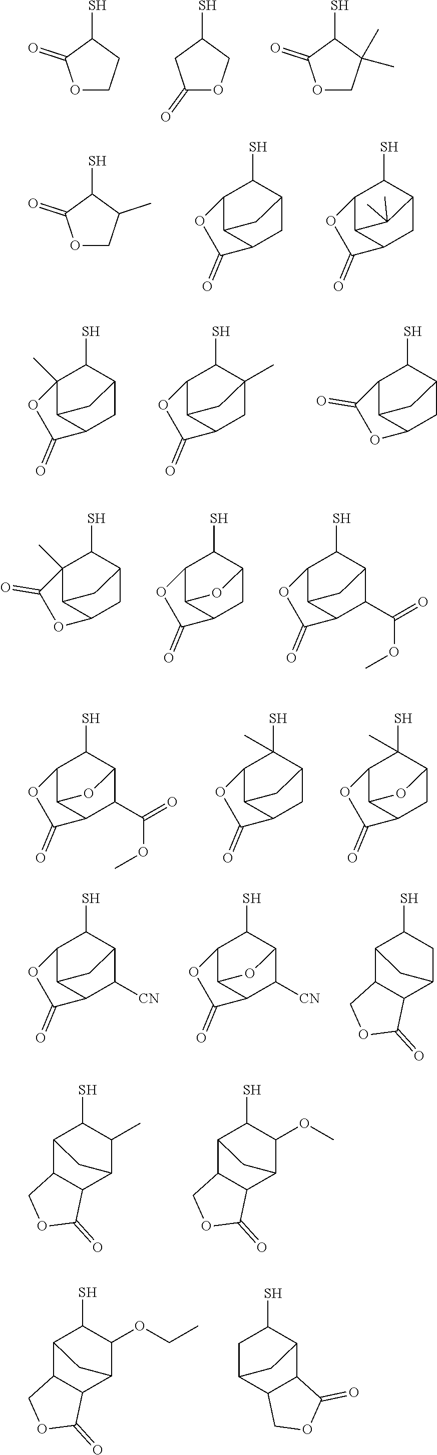

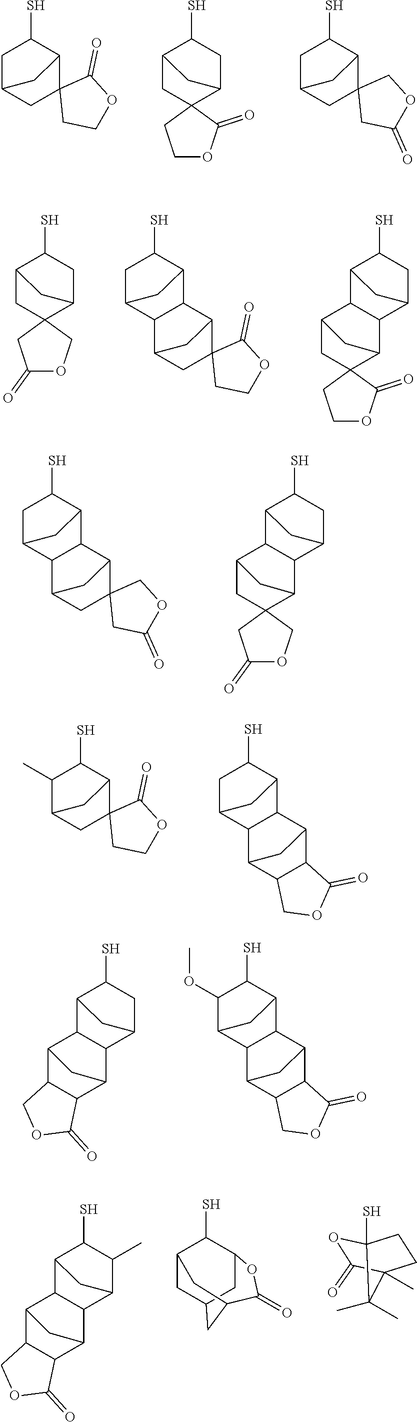

Preferred examples of the sulfur-containing compound having a mercapto group also include a compound represented by each of General Formulae (e3-1) to (e3-4).

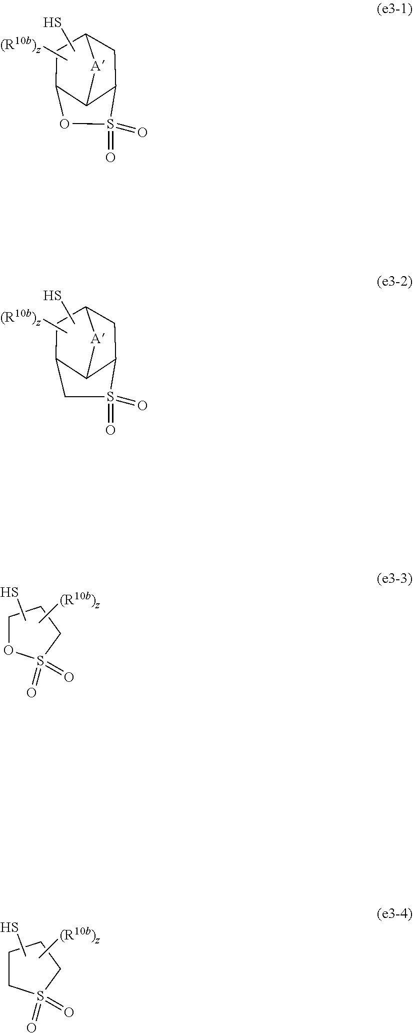

[R^{10b} in General Formulae (e3-1) to (e3-4) is the same as Ra′⁵¹ in General Formulae (a5-r-1) to (a5-r-4). z is an integer in a range of 0 to 4.]

Suitable specific examples of the mercapto compound represented by General Formulae (e3-1) to (e3-4) include the following compounds.

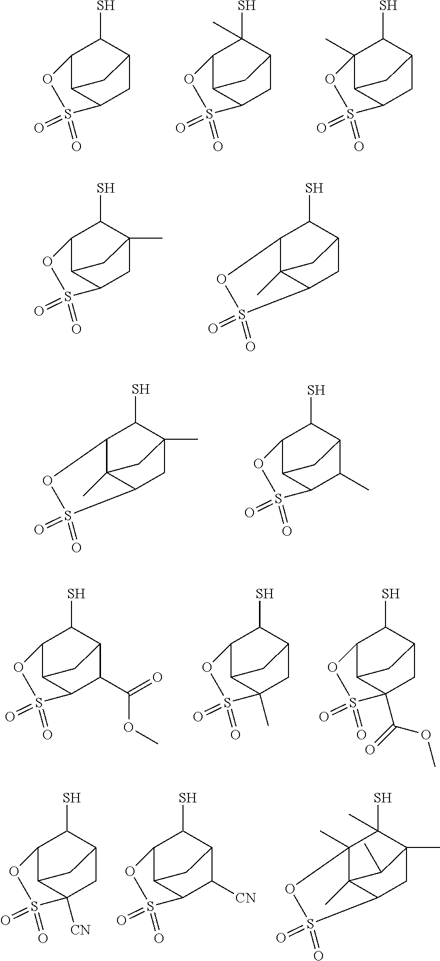

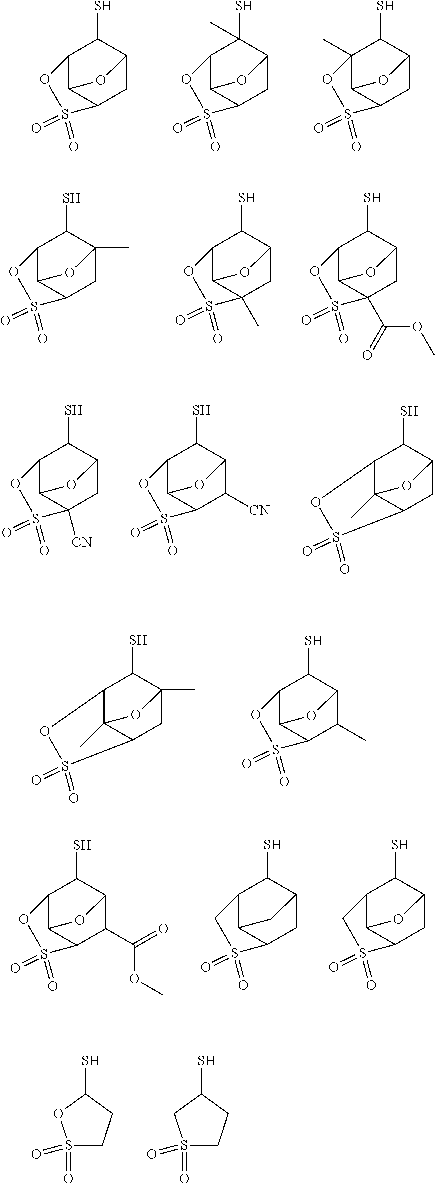

In addition, suitable examples of the compound having a mercapto group include compounds represented by General Formula (e4).

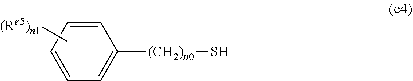

[In General Formula (e4), R^{e5} is a group selected from the group consisting of a hydroxyl group, an alkyl group having 1 or more and 4 or fewer carbon atoms, an alkoxy group having 1 or more and 4 or fewer carbon atoms, an alkylthio group having 1 or more and 4 or fewer carbon atoms, a hydroxyalkyl group having 1 or more and 4 or fewer carbon atoms, a mercaptoalkyl group having 1 or more and 4 or fewer carbon atoms, a halogenated alkyl group having 1 or more and 4 or fewer carbon atoms, and a halogen atom. n1 represents an integer of 0 or more and 3 or less. n0 represents an integer of 0 or more and 3 or less. In a case where n1 represents 2 or 3, a plurality of R^{e5}′s may be the same or different from each other.]

In a case where R^{e5} is an alkyl group having 1 to 4 carbon atoms, which may have a hydroxyl group, specific examples of the alkyl group include a methyl group, an ethyl group, an n-propyl group, an isopropyl group, an n-butyl group, an isobutyl group, a sec-butyl group, and a tert-butyl group. Among these alkyl groups, a methyl group, a hydroxymethyl group, or an ethyl group is preferable.

In a case where R^{e5} is an alkoxy group having 1 or more and 4 or fewer carbon atoms, examples of the alkoxy group include a methoxy group, an ethoxy group, an n-propyloxy group, an isopropyloxy group, an n-butyloxy group, an isobutyloxy group, a sec-butyloxy group, or a tert-butyloxy group. Among these alkoxy groups, a methoxy group or an ethoxy group is preferable, and a methoxy group is more preferable.

In a case where R^{e5} is an alkylthio group having 1 or more and 4 or fewer carbon atoms, specific examples of the alkylthio group include a methylthio group, an ethylthio group, an n-propylthio group, an isopropylthio group, an n-butylthio group, an isobutylthio group, a sec-butylthio group, and a tert-butylthio group. Among these alkylthio groups, a methylthio group or an ethylthio group is preferable, and a methylthio group is more preferable.

In a case where R^{e5} is a hydroxyalkyl group having 1 or more and 4 or fewer carbon atoms, specific examples of the hydroxyalkyl group include a hydroxymethyl group, a 2-hydroxyethyl group, a 1-hydroxyethyl group, a 3-hydroxy-n-propyl group, and a 4-hydroxy-n-butyl group. Among these hydroxyalkyl groups, a hydroxymethyl group, a 2-hydroxyethyl group, or a 1-hydroxyethyl group is preferable, and a hydroxymethyl group is more preferable.

In a case where R^{e5} is a mercaptoalkyl group having 1 or more and 4 or fewer carbon atoms, specific examples of the mercaptoalkyl group include a mercaptomethyl group, a 2-mercaptoethyl group, a 1-mercaptoethyl group, a 3-mercapto-n-propyl group, and a 4-mercapto-n-butyl group. Among these mercaptoalkyl groups, a mercaptomethyl group, a 2-mercaptoethyl group, or a 1-mercaptoethyl group is preferable, and a mercaptomethyl group is more preferable.

In a case where R^{e5} is a halogenated alkyl group having 1 or more and 4 or fewer carbon atoms, examples of the halogen atom contained in the halogenated alkyl group include a fluorine atom, a chlorine atom, a bromine atom, and an iodine atom. In a case where R^{e5} is a halogenated alkyl group having 1 or more and 4 or fewer carbon atoms, specific examples of the halogenated alkyl group include a chloromethyl group, a bromomethyl group, an iodomethyl group, a fluoromethyl group, a dichloromethyl group, a dibromomethyl group, a difluoromethyl group, a trichloromethyl group, a tribromomethyl group, a trifluoromethyl group, a 2-chloroethyl group, a 2-bromoethyl group, a 2-fluoroethyl group, a 1,2-dichloroethyl group, a 2,2-difluoroethyl group, a 1-chloro-2-fluoroethyl group, a 3-chloro-n-propyl group, a 3-bromo-n-propyl group, a 3-fluoro-n-propyl group, and a 4-chloro-n-butyl group. Among these halogenated alkyl groups, a chloromethyl group, a bromomethyl group, an iodomethyl group, a fluoromethyl group, a dichloromethyl group, a dibromomethyl group, a difluoromethyl group, a trichloromethyl group, a tribromomethyl group, a trifluoromethyl group, a chloromethyl group, a dichloromethyl group, a trichloromethyl group, or a trifluoromethyl group is more preferable.

In a case where R^{e5} is a halogen atom, specific examples of the halogen atom include a fluorine atom, a chlorine atom, a bromine atom, and an iodine atom.

In General Formula (e4), n1 represents an integer of 0 or more and 3 or less, and it is preferably 1. In a case where n1 represents 2 or 3, a plurality of Re^{e5}'s may be the same or different from each other.

In the compound represented by General Formula (e4), the substitution position of R^{e5} on the benzene ring is not particularly limited. The substitution position of R^{e5} on the benzene ring is preferably the meta position or the para position with respect to the bonding position of —(CH₂)ₙ₀—SH.

The compound represented by General Formula (e4) is preferably a compound having, as R^{e5}, at least one group selected from the group consisting of an alkyl group, a hydroxyalkyl group, and a mercaptoalkyl group, and it is more preferably a compound having, as R^{e5}, one group selected from the group consisting of an alkyl group, a hydroxyalkyl group, and a mercaptoalkyl group.

In a case where the compound represented by General Formula (e4) has, as R^{e5}, one group selected from the group consisting of an alkyl group, a hydroxyalkyl group, and a mercaptoalkyl group, the substitution position of an alkyl group, a hydroxyalkyl group, or a mercaptoalkyl group on the benzene ring is preferably the meta-position or the para-position with respect to the bonding position of —(CH₂)ₙ₀—SH, and it is more preferably the para-position.

In General Formula (e4), n0 represents an integer of 0 or more and 3 or less. n is preferably 0 or 1 and more preferably 0 since the compound can be easily prepared and easily available.

Specific examples of the compound represented by General Formula (e4) include p-mercaptophenol, p-thiocresol, m-thiocresol, 4-(methylthio)benzenethiol, 4-methoxybenzenethiol, 3-methoxybenzenethiol. 4-ethoxybenzenethiol, 4-isopropyloxybenzenethiol, 4-tert-butoxybenzenethiol, 3,4-dimethoxybenzenethiol, 3,4,5-trimethoxybenzenethiol, 4-ethylbenzenethiol, 4-isopropylbenzenethiol, 4-n-butylbenzenethiol, 4-tert-butylbenzenethiol, 3-ethylbenzenethiol, 3-isopropylbenzenethiol, 3-n-butylbenzenethiol, 3-tert-butylbenzenethiol, 3,5-dimethylbenzenethiol, 3,4-dimethylbenzenethiol, 3-tert-butyl-4-methylbenzenethiol, 3-tert-4-methylbenzenethiol, 3-tert-butyl-5-methylbenzenethiol, 4-tert-butyl-3-methylbenzenethiol, 4-mercaptobenzyl alcohol, 3-mercaptobenzyl alcohol, 4-(mercaptomethyl)phenol, 3-(mercaptomethyl)phenol, 1,4-di(mercaptomethyl)phenol, 1,3-di(mercaptomethyl)phenol, 4-fluorobenzenethiol, 3-fluorobenzenethiol, 4-chlorobenzenethiol, 3-chlorobenzenethiol, 4-bromobenzenethiol, 4-iodobenzenethiol, 3-bromobenzenethiol, 3,4-dichlorobenzenethiol, 3,5-dichlorobenzenethiol, 3,4-difluorobenzenethiol, 3,5-difluorobenzenethiol, 4-mercaptocatechol, 2,6-di-tert-butyl mercaptophenol, 3,5-di-tert-butyl-4-methoxybenzenethiol, -bromo-3-methylbenzenethiol, 4-(trifluoromethyl)benzenethiol, 3-(trifluoromethyl)benzenethiol, 3,5-bis(trifluoromethyl)benzenethiol, 4-methylthiobenzenethiol, 4-ethylthiobenzenethiol, 4-n-butylthiobenzenethiol, and 4-tert-butylthiobenzenethiol.

Examples of the sulfur-containing compound having a mercapto group include a compound containing a nitrogen-containing aromatic heterocyclic ring substituted with a mercapto group and a tautomer of the compound containing a nitrogen-containing aromatic heterocyclic ring substituted with a mercapto group.

Suitable specific examples of the nitrogen-containing aromatic heterocyclic ring include imidazole, pyrazole, 1,2,3-triazole, 1,2,4-triazole, oxazole, thiazole, pyridine, pyrimidine, pyridazine, pyrazine, 1,2,3-triazine, 1,2,4-triazine, 1,3,5-triazine, indole, indazole, benzimidazole, benzoxazole, benzothiazole, 1H-benzotriazole, quinoline, isoquinoline, cinnoline, phthalazine, quinazoline, quinoxaline, and 1,8-naphthyridine.

Suitable specific examples of each of the nitrogen-containing heterocyclic compound and the tautomer of the nitrogen-containing heterocyclic compound, which are suitable as the sulfur-containing compound, include the following compounds.

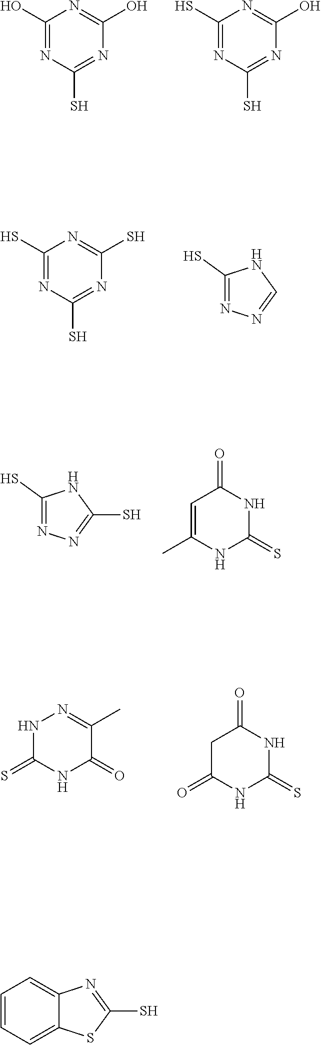

The component (E) may be used alone, or two or more kinds thereof may be used in combination.

In a case where the resist composition contains the component (E), the content of the component (E) in the resist composition is preferably 0.01 part by mass or more and 5 parts by mass, more preferably 0.02 parts by mass or more and 3 parts by mass or less, and particularly preferably 0.02 parts by mass or more and 2 parts by mass or less, with respect to 100 parts by mass of the resin component (the component (P).

Component (C): In regard to Lewis acidic compound

The resist composition according to the present embodiment may contain a Lewis acidic compound (hereinafter, also referred to as a “component (C)”).

Here, the “Lewis acidic compound” means a compound that has an empty orbital capable of receiving at least one electron pair and thus acts as an electron pair acceptor.

The component (C) is not particularly limited as long as it is a compound that corresponds to the above definition and is recognized as a Lewis acidic compound by those skilled in the art. As the component (C), a compound that does not correspond to the Bronsted acid (the protonic acid) is preferably used.

Specific examples of the component (C) include boron fluoride, an ether complex of boron fluoride (for example, BF₃.Et₂O, BF₃.Me₂O, or BF₃.THF, where Et indicates an ethyl group, Me indicates a methyl group, and THF indicates tetrahydrofuran), an organic boron compound (for example, tri-n-octyl borate, tri-n-butyl borate, triphenyl borate, or triphenyl boron), titanium chloride, aluminum chloride, aluminum bromide, gallium chloride, gallium bromide, indium chloride, thallium trifluoroacetate, tin chloride, zinc chloride, zinc bromide, zinc iodide, zinc trifluoromethanesulfonate, zinc acetate, zinc nitrate, zinc tetrafluoroborate, manganese chloride, manganese bromide, nickel chloride, nickel bromide, nickel cyanide, nickel acetylacetonate, cadmium chloride, cadmium bromide, stannous chloride, stannous bromide, stannous sulfate, and stannous tartrate.

Further, examples of another specific example of the component (C), include a chloride of a rare earth metal element, a bromide thereof, a sulfate thereof, a nitrate thereof, a carboxylate thereof, and a trifluoromethanesulfonate thereof, as well as cobalt chloride, ferrous chloride, and yttrium chloride.

Here, examples of the rare earth metal element include lanthanum, cerium, praseodymium, neodymium, samarium, europium, gadolinium, terbium, dysprosium, holmium, erbium, thulium, ytterbium, and lutetium.

The component (C) preferably contains a Lewis acidic compound containing an element of the Group 13 in the periodic table, since it is easily available and the effect of the addition thereof is good.

Here, examples of the element of the Group 13 in the periodic table include boron, aluminum, gallium, indium, and thallium.

Among the above-described elements of the Group 13 of the periodic table, boron is preferable since the component (C) is easily available and the effect of addition is particularly excellent. That is, the component (C) is preferably a component that contains a Lewis acidic compound containing boron.

Examples of the Lewis acidic compound containing boron include boron fluoride, an ether complex of boron fluoride, boron halides such as boron chloride and boron bromide, and various organic boron compounds. The Lewis acidic compound containing boron is preferably an organic boron compound since the content rate of the halogen atom in the Lewis acidic compound is low and the resist composition can be easily applied to use applications in which a low halogen content is required.

Preferred examples of the organic boron compound include those represented by General Formula (c1):

B(R^{c1})ₙ₁(OR^{c2})(₃₋ₙ₁) (c1)

[(In General Formula (c1), R^{c1} and R^{c2} each independently represent a hydrocarbon group having 1 or more and 20 or fewer carbon atoms. The hydrocarbon group may have one or more substituents, n1 represents an integer in a range of 0 to 3. In a case where a plurality of R^{c1}'s are present, two of the plurality of R^{c1}'s may be bonded to each other to form a ring. In a case where a plurality of OR^{c2}'s are present, two of the plurality of R^{c2}'s may be bonded to each other to form a ring.]

The resist composition preferably contains one or more kinds of the boron compounds represented by General Formula (c1) as the component (C).

In General Formula (cl), in a case where R^{c1} and R^{c2} represent a hydrocarbon group, the number of carbon atoms of the hydrocarbon group is 1 or more and 20 or less. The hydrocarbon group having 1 or more and 20 or fewer carbon atoms may be an aliphatic hydrocarbon group, may be an aromatic hydrocarbon group, or may be a hydrocarbon group consisting of a combination of an aliphatic group and an aromatic group.

The hydrocarbon group having 1 or more and 20 or fewer carbon atoms is preferably a saturated aliphatic hydrocarbon group or an aromatic hydrocarbon group. The number of carbon atoms of the hydrocarbon group as R^{c1} and R^{c2} is preferably 1 or more and 10 or less. In a case where the hydrocarbon group is an aliphatic hydrocarbon group, the number of carbon atoms thereof is more preferably 1 or more and 6 or less, and particularly preferably 1 or more and 4 or less.

The hydrocarbon group as R^{c1} and R^{c2} may be a saturated hydrocarbon group or may be an unsaturated hydrocarbon group, and it is preferably a saturated hydrocarbon group.

In a case where the hydrocarbon group as R^{c1} and R^{c2} is an aliphatic hydrocarbon group, the aliphatic hydrocarbon group may have a linear, branched, or cyclic structure, or it may be a combination of these structures.

Suitable specific examples of the aromatic hydrocarbon group include a phenyl group, a naphthalene-1-yl group, a naphthalene-2-yl group, a 4-phenylphenyl group, a 3-phenylphenyl group, and a 2-phenylphenyl group. Among these, a phenyl group is preferable.

The saturated aliphatic hydrocarbon group is preferably an alkyl group. Suitable specific examples of the alkyl group include a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, a 2-ethylhexyl group, an n-nonyl group, and an n-decyl group.

The hydrocarbon group as R^{c1} and R^{c2} may have one or more substituents. Examples of the substituent include a halogen atom, a hydroxyl group, an alkyl group, an aralkyl group, an alkoxy group, a cycloalkyloxy group, an aryloxy group, an aralkyloxy group, an alkylthio group, an cycloalkylthio group, an arylthio group, an aralkylthio group, an acyl group, an acyloxy group, an acylthio group, an alkoxycarbonyl group, a cycloalkyloxycarbonyl group, an aryloxycarbonyl group, an amino group, an N-monosubstituted amino group, an N,N-disubstituted amino group, a carbamoyl group (—CO—NH₂), an N-monosubstituted carbamoyl group, an N,N-disubstituted carbamoyl group, a nitro group, and a cyano group.

The number of carbon atoms of the substituent is not particularly limited as long as the object of the present invention is not impaired; however, it is preferably 1 or more and 10 or less and more preferably 1 or more and 6 or less.

Suitable specific examples of the organic boron compound represented by General Formula (cl) include the following compounds. In the following formulae, Pen indicates a pentyl group, Hex indicates a hexyl group, Hep indicates a heptyl group, Oct indicates an octyl group, Non indicates a nonyl group, and Dec indicates a decyl group.

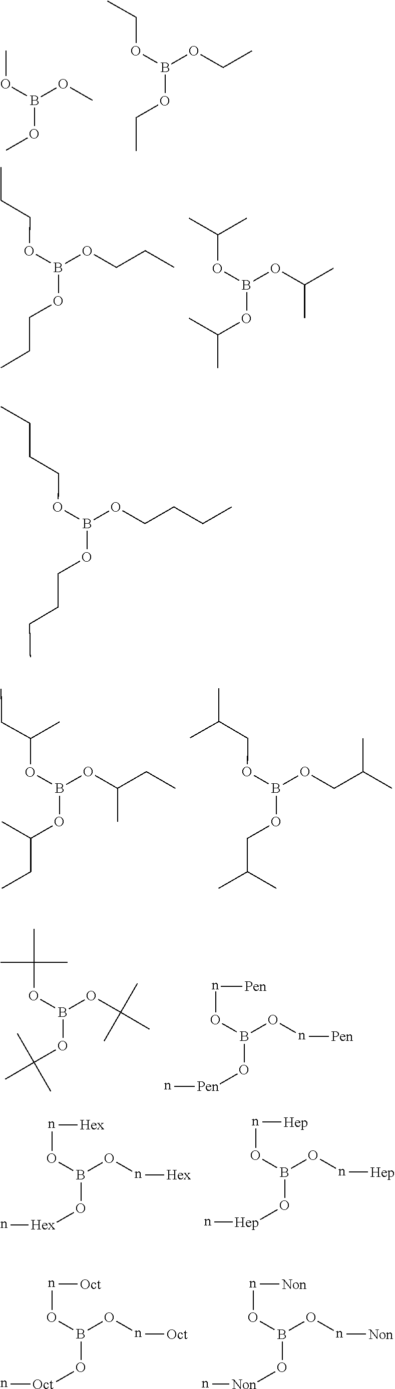

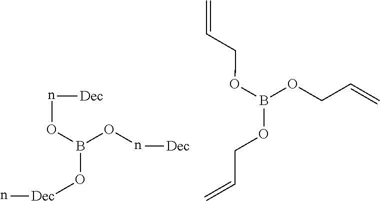

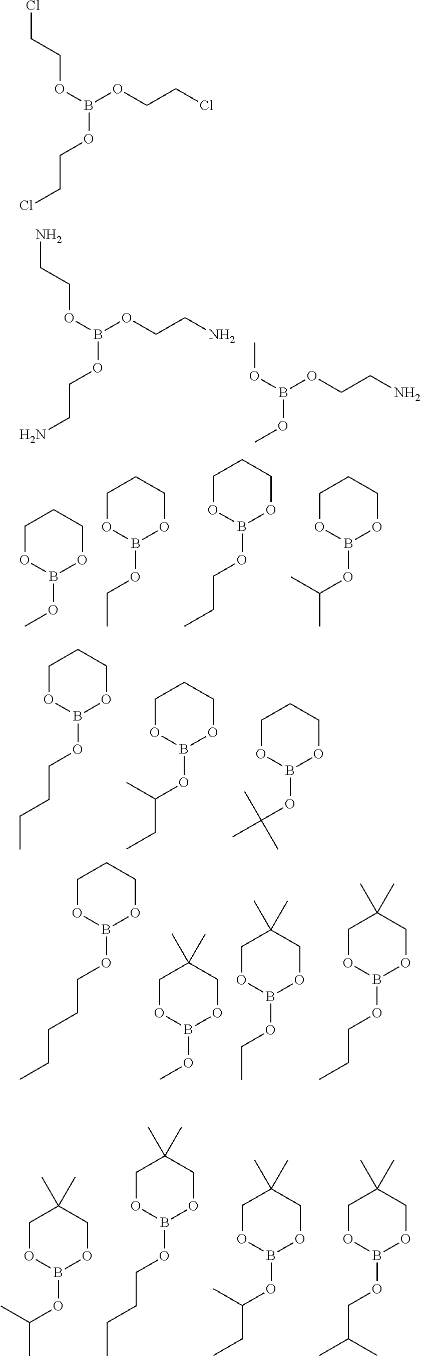

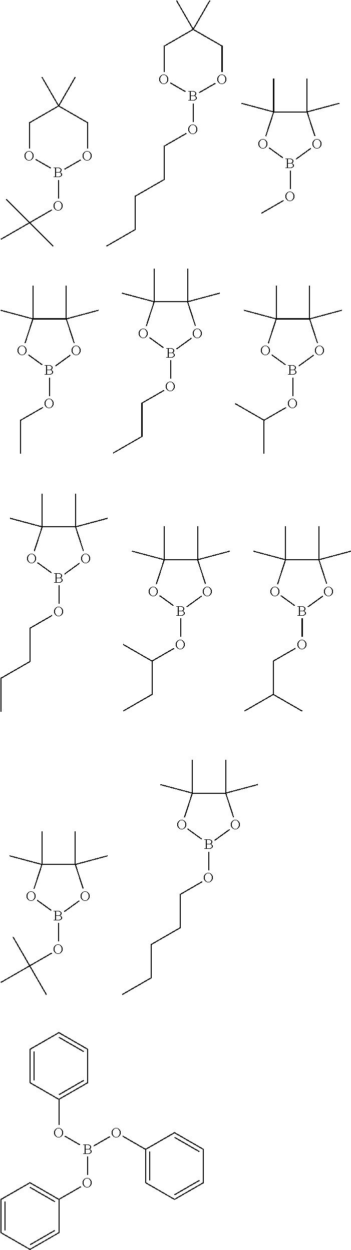

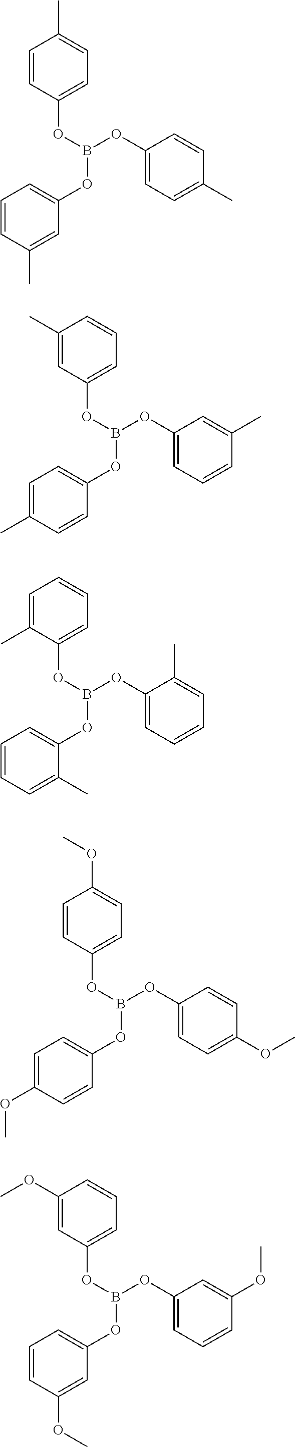

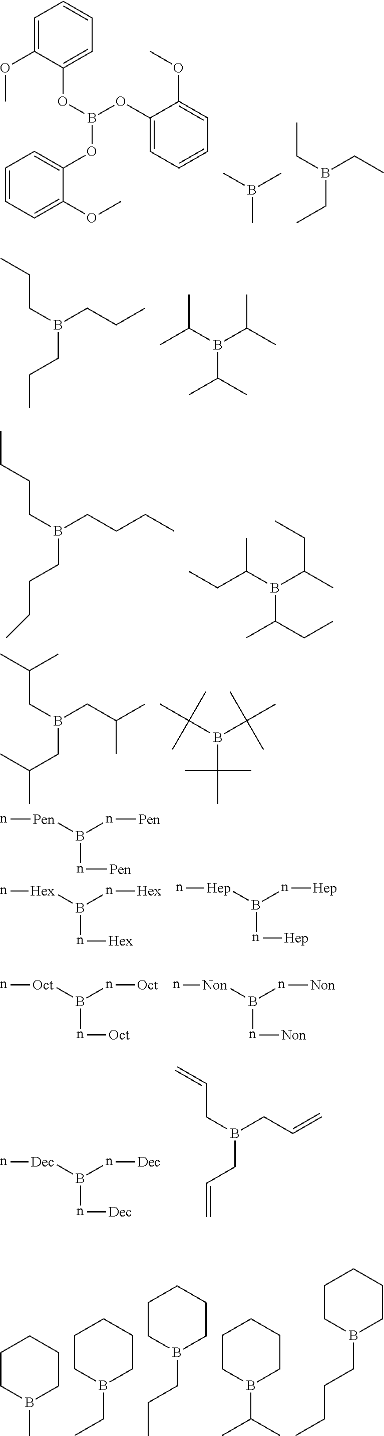

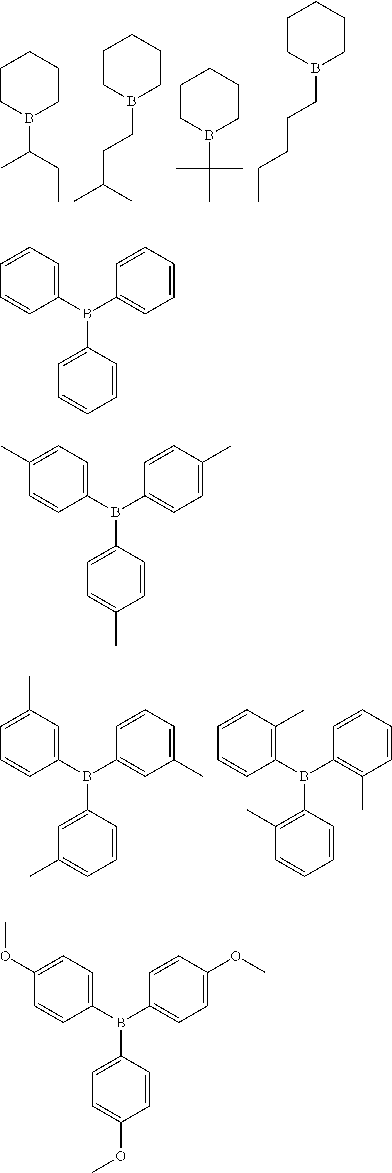

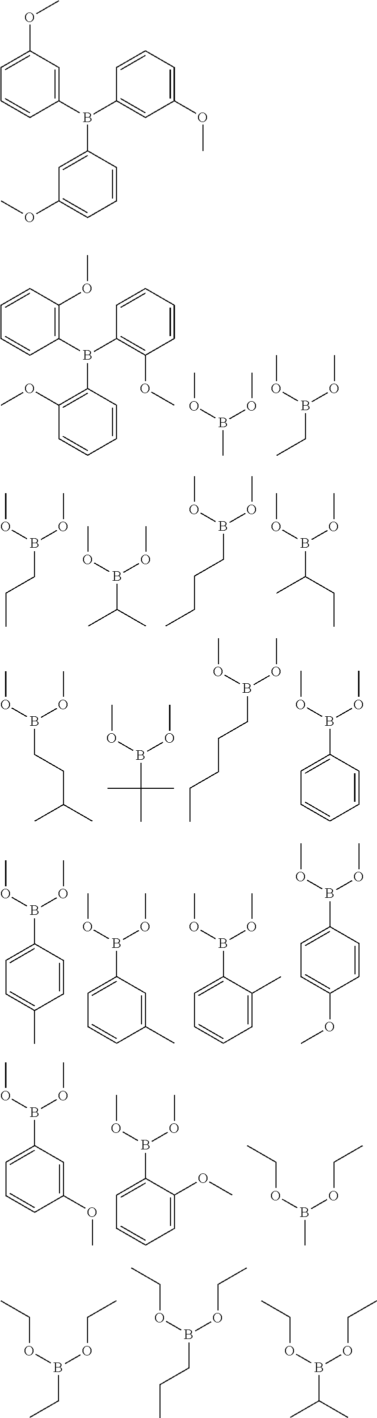

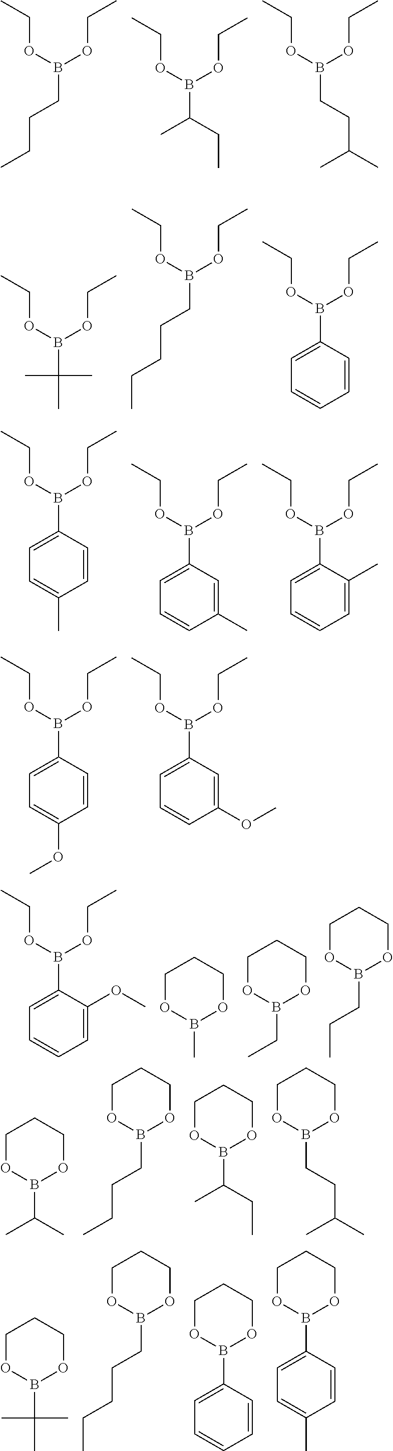

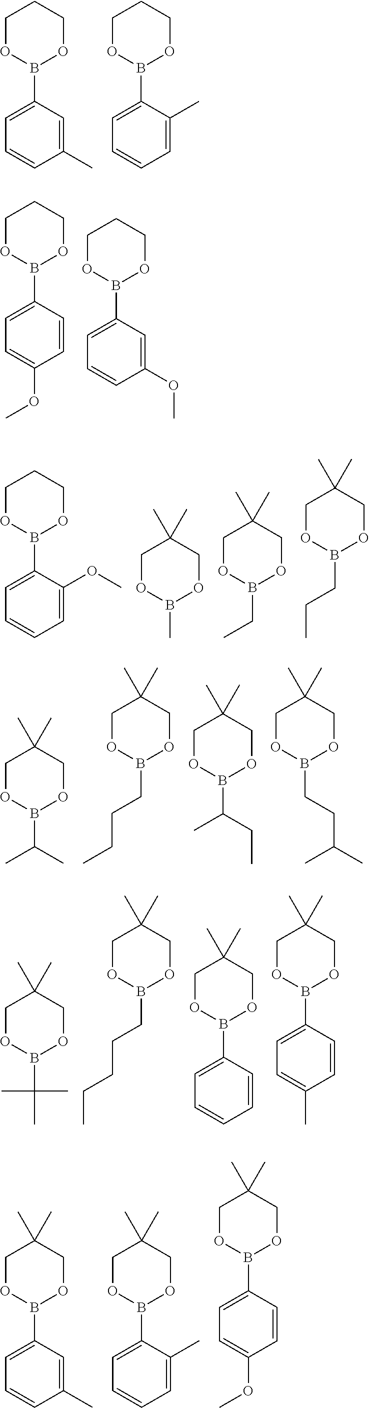

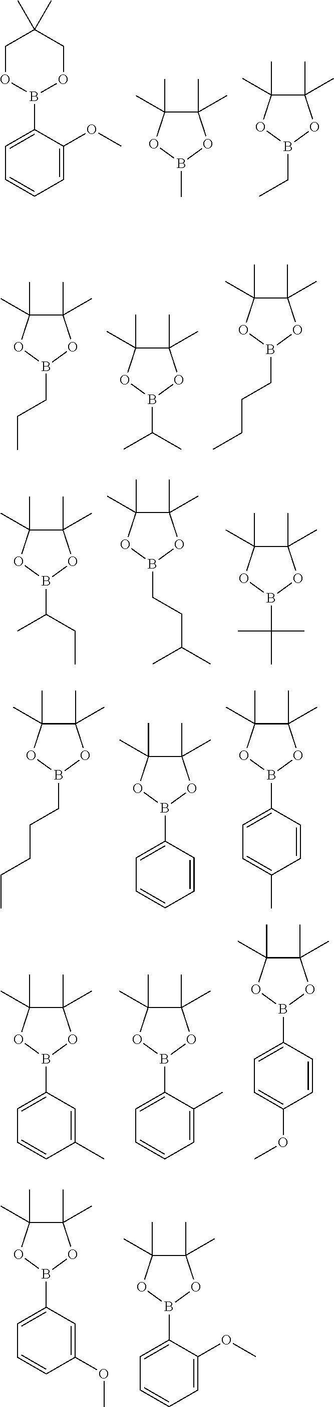

The component (C) may be used alone, or two or more kinds thereof may be used in combination.

In a case where the resist composition contains the component (C), the content of the component (C) in the resist composition is preferably in a range of 0.01 parts by mass or more and 5 parts by mass or less, more preferably in a range of 0.01 parts by mass or more and 3 parts by mass or less, and still more preferably in a range of 0.05 parts by mass or more and 2 parts by mass or less, with respect to 100 parts by mass of the resin component (P).

As desired, other miscible additives can also be added to the resist composition. For example, for improving the performance of the resist film, an additive resin, a dissolution inhibitor, a plasticizer, a stabilizer, a colorant, a halation prevention agent, and a dye can be appropriately contained therein.

### <<Component (S): In Regard to Organic Solvent Component>>

The resist composition can be produced by dissolving materials in the organic solvent component (the component (S)).

The component (S) may be any organic solvent which can dissolve the respective components to be used to obtain a homogeneous solution, and any one or two or more organic solvents can be appropriately selected and used from those which are known in the related art as the solvent for a chemical amplification-type resist.

Examples of the component (S) include lactones such as γ-butyrolactone (GBL); ketones such as acetone, methyl ethyl ketone (MEK), cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate, polyhydric alcohol derivatives such as compounds having an ether bond, such as a monoalkyl ether (such as monomethyl ether, monoethyl ether, monopropyl ether or monobutyl ether) or monophenyl ether of any Among these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl 3-methoxypropionate, and ethyl ethoxypropionate; aromatic organic solvents such as anisole, ethylbenzyl ether, cresyl methyl ether, diphenyl ether, dibenzyl ether, phenetole, butylphenyl ether, ethyl benzene, diethyl benzene, pentyl benzene, isopropyl benzene, toluene, xylene, cymene and mesitylene; and dimethylsulfoxide (DMSO).

The component (S) may be used alone or may be used as a mixed solvent of two or more thereof.

Among them, PGMEA, 3-methoxybutyl acetate, butyl acetate, or 2-heptanone is preferable.

The using amount of the component (S) is not particularly limited, and it is appropriately set, depending on the thickness of the coating film, to a concentration at which the component (S) can be applied onto a substrate or the like. Generally, in a case where it is used in such a use application in which the film thickness of the resist film that is obtained by a spin coating method or the like is 1 μm or more, it is preferable that the solid content concentration of the resist composition is to be a concentration in a range of 15% by mass to 65% by mass.

The resist composition may further contain a polyvinyl resin in order to improve the plasticity. Specific examples of the polyvinyl resin include polyvinyl chloride, polystyrene, polyhydroxystyrene, polyvinyl acetate, polyvinylbenzoic acid, polyvinyl methyl ether, polyvinyl ethyl ether, polyvinyl alcohol, polyvinyl pyrrolidone, polyvinyl phenol, and a copolymer thereof The polyvinyl resin is preferably polyvinyl methyl ether in terms of the low glass transition point.

In addition, the resist composition may further contain an adhesion auxiliary agent in order to improve the adhesiveness to the substrate.

Furthermore, the resist composition may further contain a surfactant in order to improve the coatability, the defoaming property, the leveling property, or the like. As the surfactant, for example, a fluorine-based surfactant or a silicone-based surfactant is preferably used.

Specific examples of the fluorine-based surfactant include, which are not limited to, BM-1000 and BM-1100 (all manufactured by BM Chemie); MEGAFACE F142D, MEGAFACE F172, MEGAFACE F173, and MEGAFACE F183 (all manufactured by DIC Corporation); Florard FC-135, Florard FC-170C, Florard FC-430, and Florard FC-431 (all manufactured by Sumitomo 3M Limited); Surflon S-112, Surflon S-113, Surflon S-131, Surflon S-141, and Surflon S-145 (all manufactured by AGC Inc.); and commercially available fluorine-based products such as SH-28PA, SH-190, SH-193, SZ-6032, and SF-8428 (all manufactured by Toray Silicone Co., Ltd.).

As the silicone-based surfactant, it is possible to preferably use an unmodified silicone-based surfactant, a polyether-modified silicone-based surfactant, a polyester-modified silicone-based surfactant, an alkyl-modified silicone-based surfactant, an aralkyl-modified silicone-based surfactant, a reactive silicone-based surfactant, or the like.

As the silicone-based surfactant, it is possible to use a commercially available silicone-based surfactant. Specific examples of the commercially available silicone-based surfactant include Paintad M (manufactured by DuPont Toray Specialty Materials K.K.); Topica K1000, Topica K2000, and Topica K5000 (all manufactured by TAKACHIHO SANGYO CO., LTD.); XL-121 (a polyether-modified silicone-based surfactant, manufactured by Clariant AG); and BYK-310 (a polyester-modified silicone-based surfactant, manufactured by BYK Additives & Instruments).

Furthermore, the resist composition may further contain an acid, an acid anhydride, or a high boiling point solvent in order to finely adjust the solubility in an alkali developing solution.

Examples of the acid and the acid anhydride include monocarboxylic acids such as acetic acid, propionic acid, n-butyric acid, isobutyric acid, n-valeric acid, isovaleric acid, benzoic acid, and cinnamic acid; polyvalent carboxylic acids such as a hydroxymonocarboxylic acid such as lactic acid, 2-hydroxybutyric acid, 3-hydroxybutyric acid, salicylic acid, m-hydroxybenzoic acid, p-hydroxybenzoic acid, 2-hydroxycinnamic acid, 3-hydroxycinnamic acid, 4-hydroxycinnamic acid, 5-hydroxyisophthalic acid, or syringic acid; oxalic acid, succinic acid, glutaric acid, adipic acid, maleic acid, itaconic acid, hexahydrophthalic acid, phthalic acid, isophthalic acid, terephthalic acid, 1,2-cyclohexanedicarboxylic acid, 1,2,4-cyclohexanetricarboxylic acid, butanetetracarboxylic acid, trimellitic acid, or pyromellitic acid; cyclopentanetetracarboxylic acid, butanetetracarboxylic acid, and 1,2,5,8-naphthalenetetracarboxylic acid; and acid anhydrides such as itaconic anhydride, succinic anhydride, citraconic anhydride, dodecenylsuccinic anhydride, tricarbanyl anhydride, maleic anhydride, hexahydrophthalic anhydride, methyltetrahydrophthalic anhydride, hymic anhydride, 1,2,3,4-butanetetracarboxylic acid anhydride, cyclopentanetetracarboxylic acid dianhydride, phthalic anhydride, pyromellitic anhydride, trimellitic anhydride, benzophenonetetracarboxylic anhydride, ethylene glycol bis anhydrous trimellitate, and glycerin tris anhydrous trimellitate.

Examples of the high boiling point solvent include N-methylformamide, N,N-dimethylformamide, N-methylformanilide, N-methylacetamide, N,N-dimethylacetamide, N-methylpyrrolidone, dimethyl sulfoxide, benzyl ethyl ether, dihexyl ether, acetonyl acetone, isophorone, caproic acid, capric acid, 1-octanol, 1-nonanol, benzyl alcohol, benzyl acetate, ethyl benzoate, diethyl oxalate, diethyl maleate, y-butyrolactone, ethylene carbonate, propylene carbonate, phenylcellosolve acetate, and ethyl phthalyl ethyl glycolate.

The using amount of the compound for finely adjusting the solubility in an alkali developing solution, as described above, can be adjusted depending on the use application and the coating method, and it is particularly limited as long as the composition can be uniformly mixed. However, it is set to 60% by mass or less and preferably 40% by mass or less with respect to the total mass of the composition to be obtained.

In the resist pattern formation method according to the present embodiment described above, for the base resin of the resist composition, the polymeric compound (p10) having the constitutional unit (a0) is employed as the component (P1), and the polymeric compound (p20), which has both the constitutional unit (u0) containing a phenolic hydroxyl group and the constitutional unit (u1) containing an acid decomposable group having a polarity that is increased under action of acid, is employed as the component (P2). Since both the developing solution solubility of the component (p10) having the constitutional unit (a0) and the resolution of the component (p20) having the constitutional unit (u1) are provided, there is provided a resolution by which a fine pattern can be formed without a residue even on a substrate having height difference.

A mixed state is present in the mixed resin of the component (p10) and the component (p20), the dissolution rate (DR_{MIX}) of which is smaller than the dissolution rate (DR_{P1}) of the component (p10) and smaller than the dissolution rate (DR_{P2}) of the component (p20).

Although the reason for this is not clear, it is conceived to be due to, for example, the fact that the neutralization reaction with the alkali component in the alkali developing solution becomes difficult to proceed due to the steric hindrance caused by a hydrogen bond between the —COOH moiety of the constitutional unit (a0) of the component (p10), which is an alkali-soluble portion, and the —OH moiety of the constitutional unit (u0) of the component (p20) containing a phenolic hydroxyl group, which is an alkali-soluble portion, whereby the solubility as the mixed resin is decreased. Therefore, in a case where the component (p10) and the component (p20) are mixed to be a mixed resin, the solubility of the mixed resin in an alkali developing solution can be decreased. As a result, there is provided a resolution by which a fine pattern can be formed without a residue even on a substrate having height difference while suppressing the reduction of the developed film in the unexposed portions of the resist film.

In the present embodiment, a resist composition having both the first resin component (P1) and the second resin component (P2) is employed as the preferred combination of the mixed resin, where a mixing ratio satisfying the relationship of specific dissolution rates (that is, DR_{MIX}<DR_{P1} and DR_{MIX}<DR_{P2}) is present. That is, a combination of resins, in which the dissolution rate of a mixed resin in an alkali developing solution is a small value as compared with the dissolution rate of each single resin in an alkali developing solution, is selected. This makes it possible for the difference in solubility (the dissolution contrast) between the unexposed portions and the exposed portions of the resist film in the developing solution to be further increased. In addition, the film reduction in the unexposed portions of the resist film is suppressed, and the residue of the exposed portions of the resist film is hardly generated. Further, it is possible to form a resist pattern having higher sensitivity and higher resolution.

According to the resist pattern formation method according to the present embodiment, even in a case where a copper substrate in which a skirt shape formation or a residue formation easily occurs is used, the residue in the exposed portions of the resist film is hardly generated, and thus a resist pattern having a good shape can be formed.

### (Production Method for Resist Composition)

The production method for a resist composition according to the present embodiment is a production method for a resist composition in which an acid is generated upon exposure and the solubility in an alkali developing solution is increased under action of acid, and it has a step of mixing the first resin component (P1) and the second resin component (P2).

The first resin component (P1) contains a polymeric compound (p10) having a constitutional unit (a0) derived from acrylic acid in which a hydrogen atom bonded to a carbon atom at an α-position may be substituted with a substituent, and the second resin component (P2) contains a polymeric compound (p20) having both a constitutional unit (u0) containing a phenolic hydroxyl group and a constitutional unit (u1) containing an acid decomposable group having a polarity that is increased under action of acid.

Examples of the preferred combination of the first resin component (P1) and the second resin component (P2) include a combination of the first resin component (P1) and the second resin component (P2), in which in a case where a dissolution rate of the first resin component (P1) in an alkali developing solution is denoted by DRpi, a dissolution rate of the second resin component (P2) in an alkali developing solution is denoted by DR_{P2}, and a dissolution rate of a mixed resin of the first resin component (P1) and the second resin component (P2), in an alkali developing solution, is denoted by DR_{MIX}, a mixing ratio satisfying the following expressions are present,

DR_{MIX}<DR_{P1} and DR_{MIX}<DR_{P2}

The component (P1) and the component (P2), and the resist composition containing these are the same as those in the explanation on <Resist composition>described above.

The component (P1) and the component (P2) can be mixed by a known method, and they may be dispersed and mixed, as necessary, using a disperser such as a dissolver, a homogenizer, or a three-roll mill.

The dissolution rates of the component (P1), the component (P2), and the mixed resin thereof in an alkali developing solution are controlled by appropriately selecting the kind of the raw material monomer of each resin, the combination or mixing ratio between the component (P1) and the component (P2), and the like.

### EXAMPLES

Hereinafter, the present invention will be described in more detail based on Examples, but the present invention is not limited to these Examples.

### <Resin Component>

In present Examples, the following polymeric compounds were used.

<<Component (P1): Polymeric Compound (p10)>>

p10-1 to p10-5: Acrylic resins having constitutional units derived from the following monomers (m1) to (m7) at the unit ratio shown in Table 1.

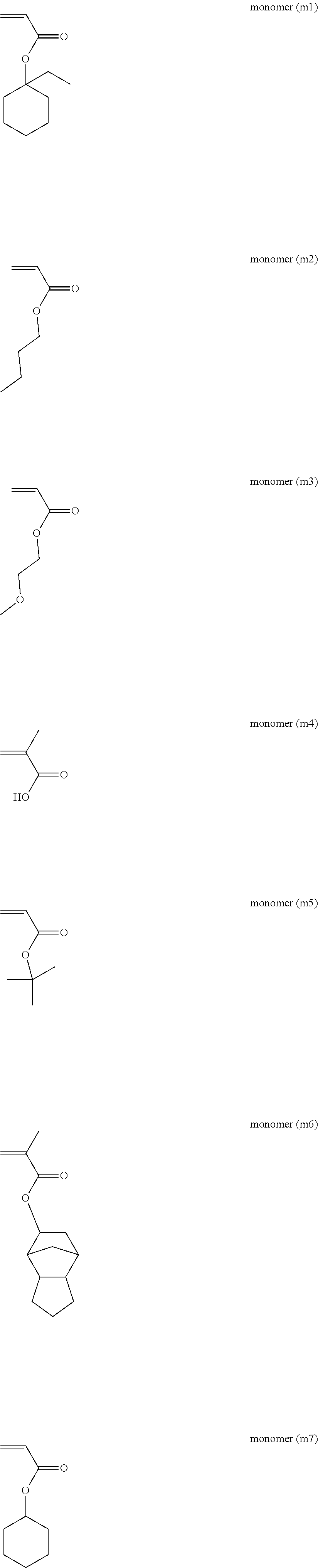

TABLE 1

| Polymeric | Unit ratio derived from each monomer (molar ratio) | | | | | | | | Weight average |
|---|---|---|---|---|---|---|---|---|---|
| compound | Monomer | Monomer | Monomer | Monomer | Monomer | Monomer | Monomer | Total | molecular weigh |
| (p10) | (ml) | (m2) | (m3) | (m4) | (m5) | (m6) | (m7) | (% by mole) | (Mw) |
| p10-1 | 29 | 8 | 22 | 23 | — | 18 | — | 100 | 40000 |
| p10-2 | 17 | 8 | 22 | 23 | — | 30 | — | 100 | 40000 |
| p10-3 | 33 | 13 | 37 | 17 | — | — | — | 100 | 40000 |
| p10-4 | — | 22 | 24 | 13 | 41 | — | — | 100 | 100000 |
| p10-5 | — | 13 | 37 | 17 | — | — | 33 | 100 | 40000 |

<<Component (P2): Polymeric Compound (p20)>>

p20-1: A resin having 35% by mole of a constitutional unit obtained by introducing an ethoxyethyl group as an acid dissociable group into polyhydroxystyrene (weight average molecular weight: 10,000).

p20-2: A resin having 26% by mole of a constitutional unit obtained by introducing a t-Boc group as an acid dissociable group into polyhydroxystyrene (weight average molecular weight: 10,000).

p20-3: A resin having hydroxystyrene, styrene, and t-butyl acrylate at a unit ratio (a molar ratio) of 60:15:25, and having a weight average molecular weight of 11,000.

p20-4: A resin having hydroxystyrene, styrene, and t-butyl acrylate at a unit ratio (a molar ratio) of 70:5:25, and having a weight average molecular weight of 11,000.

p20-5: A resin having hydroxystyrene, styrene, and t-butyl acrylate at a unit ratio (a molar ratio) of 60:25:15, and having a weight average molecular weight of 9,000.

<<Component (P3): Polymeric Compound (p30)>>

p30-1: A novolak resin obtained by subjecting a mixture of m-cresol and p-cresol (m-cresol/p-cresol >60/40 (in terms of molar ratio)) and formaldehyde to addition condensation in the presence of an acid catalyst to obtain a reaction product and separating the reaction product with water+methanol to have a weight average molecular weight of 16,000 to 17,000

p30-2: A copolymer having hydroxystyrene and styrene at a unit ratio (molar ratio) of 85:15 and having a weight average molecular weight of 2,500.

p30-3: A copolymer having hydroxystyrene and styrene at a unit ratio (molar ratio) of 75:25 and having a weight average molecular weight of 2,500.

### <Measurement of Dissolution Rate of Resin in Alkali Developing Solution>

The dissolution rates of resins (resins alone and the mixed resin) in an alkali developing solution were measured according to the following procedures (1′) to (6′).

A procedure (1′): Propylene glycol monomethyl ether acetate (PGMEA), 100 parts by mass of a resin, and 0.05 to 0.1 parts by mass of a surfactant (BYK-310, manufactured by BYK Additives & Instruments) are mixed, and then a resin solution having a resin concentration at which a resin film having a thickness of about 4 μm can be formed in the next film forming step (the procedure (2)) is prepared.

A procedure (2′): After spin-coating a silicon wafer with the resin solution, it is subjected to a film formation heating treatment (PAB) at 120° C. for 120 seconds on a hot plate to form a film, thereby forming a resin film having a thickness of about 4 μm.

A procedure (3′): The film thickness of the resin film (the initial film thickness X) is measured by using a film thickness measuring device (an optical interference type film thickness measuring device: Nanospec, model 3000).

A procedure (4′): The silicon wafer on which the resin film has been formed is developed with an alkali developing solution under the following developing conditions.

Developing conditions: The silicon wafer on which the resin film has been formed is subjected to Dip development at 23° C. with an aqueous solution of 5% by mass of TMAH.

A procedure (5′): During Dip development, the time (the dissolution time Z) taken until the formed resin film is completely dissolved is measured.

A procedure (6′): The dissolution rate (DR) of the resin in the alkali developing solution is calculated.

DR(nm/s)=(X)/(Z)

### [Measurement Result of Dissolution Rate]

The dissolution rate (DR) of each of the polymeric compound p20-3, another resin, and the mixed resin of the polymeric compound p20-3 and the other resin was measured in an alkali developing solution. The obtained results are shown in Table 2 and Table 3.

As the other resin, a polymeric compound p10-3, a polymeric compound p10-4, a polymeric compound p10-5, a polymeric compound p20-2, a polymeric compound p20-4, a polymeric compound p30-2, and a polymeric compound p30-3 were used.

Tables 2 and 3 both show the dissolution rates (DR) in a case where an aqueous solution of 5% by mass of TMAH is used as the developing solution.

TABLE 2

| Aqueous solution of 5% by | | | | | | | |
|---|---|---|---|---|---|---|---|
| mass of TMAH | | Dissolution rate (DR) in alkali developing solution | | | | | |
| Mixed resin (mass ratio) | | [nm/s] | | | | | |
| p20-3 | Another resin | p10-3 | p10-4 | p30-2 | p30-3 | p20-4 | p10-5 |
| 100 | 0 | 34.34 | 34.34 | 34.34 | 34.34 | 34.34 | 34.34 |
| 90 | 10 | 28.75 | 27.08 | 57.25 | 44.71 | 47.80 | 30.93 |
| 80 | 20 | 26.64 | 24.30 | 85.31 | 57.27 | 62.79 | 33.86 |
| 70 | 30 | 29.25 | 27.00 | 128.19 | 76.92 | 81.59 | 41.32 |
| 60 | 40 | 39.97 | 35.26 | 186.59 | 98.92 | 108.07 | 61.17 |
| 50 | 50 | 69.73 | 58.47 | 260.73 | 123.01 | 136.83 | 109.73 |
| 40 | 60 | 157.77 | 160.25 | 336.97 | 161.58 | 171.19 | 275.95 |
| 30 | 70 | 391.48 | 501.55 | 429.75 | 203.13 | 212.42 | 784.46 |
| 20 | 80 | 927.78 | 1390.01 | 535.46 | 250.19 | 257.49 | 2061.25 |
| 10 | 90 | 2018.05 | 3314.10 | 651.56 | 303.65 | 308.15 | >4000 |
| 0 | 100 | >4000 | >4000 | 780.65 | 363.44 | 363.10 | >4000 |

TABLE 3

| Aqueous solution of 5% by | | | | | | |
|---|---|---|---|---|---|---|
| mass of TMAH | | Dissolution rate (DR) in alkali developing solution | | | | |
| Mixed resin (mass ratio) | | [nm/s] | | | | |
| p20-3 | Another resin | p20-4 | p10-3 | p10-4 | p10-1 | p20-2 |
| 100 | 0 | 39.12 | 39.12 | 39.12 | 39.12 | 39.12 |
| 90 | 10 | 51.36 | 37.85 | 36.20 | 26.81 | 39.13 |
| 80 | 20 | 63.19 | 41.07 | 37.10 | 19.97 | 39.32 |
| 70 | 30 | 78.89 | 48.61 | 41.34 | 14.12 | 39.65 |
| 60 | 40 | 98.54 | 63.19 | 51.43 | 11.41 | 40.15 |
| 50 | 50 | 126.76 | 96.43 | 74.79 | 10.59 | 40.53 |
| 40 | 60 | 159.09 | 187.95 | 170.01 | 13.55 | 40.84 |
| 30 | 70 | 198.69 | 425.01 | 498.75 | 19.53 | 41.13 |
| 20 | 80 | 245.54 | 960.15 | 1371.95 | 30.13 | 41.45 |
| 10 | 90 | 300.15 | 2038.85 | 3252.85 | 44.85 | 41.75 |
| 0 | 100 | 363.10 | >4000 | >4000 | 65.01 | 42.97 |

From the results shown in Tables 2 to 3, it is confirmed that in all of the combination of the polymeric compound p20-3 and the polymeric compound p20-4, the combination of the polymeric compound p20-3 and the polymeric compound p20-2, the combination of the polymeric compound p20-3 and the polymeric compound p30-2, and the combination of the polymeric compound p20-3 and the polymeric compound p30-3, the relationship between dissolution rate (DR′_{MIX}) of the mixed resin of each combination in an alkali developing solution, the dissolution rate (DR′ₚ₂₀₋₃) of the polymeric compound p20-3 in an alkali developing solution, and the dissolution rate (DR′ (other resin) of each of the other resins alone in an alkali developing solution) satisfies,

DR′ (other resin)<DR′_{MIX}<DR′ₚ₂₀₋₃

In addition, from the results shown in Tables 2 to 3, in all of the combination of the polymeric compound p20-3 and the polymeric compound p10-1, the combination of the polymeric compound p20-3 and the polymeric compound p10-3, the combination of the polymeric compound p20-3 and the polymeric compound p10-4, and the combination of the polymeric compound p20-3 and the polymeric compound p10-5, it is possible to confirm compositions (in terms of mass ratio) of a mixed resin, in which a dissolution rate of a mixed resin in an alkali developing solution is a small value as compared with a dissolution rate of each single resin in an alkali developing solution (that is, in a case where resins are mixed, it can be confirmed whether or not the composition has an effect of suppressing dissolution).

### <Formation of Resist Pattern>

### Examples 1 to 19 and Comparative Examples 1 to 34

In the formation of the resist pattern of each example, each component shown in Tables 4 to 12 was mixed and dissolved in a propylene glycol monomethyl ether acetate (PGMEA) solvent to prepare and subsequently use each resist composition (solid content concentration: 30% by mass).

TABLE 4

| | Component (P) | | | | | | | | | |
|---|---|---|---|---|---|---|---|---|---|---|
| | Component | | Component | | Component | Component | Component | Component | Component | Component |
| | (P1) | | (P2) | | (P3) | (B) | (F1) | (F2) | (E) | (Add) |
| Comparative | — | — | (P2)-3 | | — | (B)-1 | (F1)-1 | (F2)-1 | (E)-1 | Add-1 |
| Example 1 | | | [100] | | | [1.2] | [0.05] | [0.08] | [0.02] | [0.05] |
| Comparative | — | — | (P2)-4 | | — | (B)-1 | (F1)-1 | (F2)-1 | (E)-1 | Add-1 |
| Example 2 | | | [100] | | | [1.2] | [0.05] | [0.08] | [0.02] | [0.05] |
| Comparative | — | — | (P2)-5 | | — | (B)-1 | (F1)-1 | (F2)-1 | (E)-1 | Add-1 |
| Example 3 | | | [100] | | | [1.2] | [0.05] | [0.08] | [0.02] | [0.05] |
| Comparative | — | — | (P2)-3 | (P2)-4 | — | (B)-1 | (F1)-1 | (F2)-1 | (E)-1 | Add-1 |
| Example 4 | | | [70] | [30] | | [1.2] | [0.05] | [0.08] | [0.02] | [0.05] |
| Comparative | (P1)-3 | | — | — | — | (B)-1 | (F1)-1 | (F2)-1 | (E)-1 | Add-1 |
| Example 5 | [100] | | | | | [1.2] | [0.05] | [0.08] | [0.02] | [0.05] |
| Comparative | (P1)-4 | | — | — | — | (B)-1 | (F1)-1 | (F2)-1 | (E)-1 | Add-1 |
| Example 6 | [100] | | | | | [1.2] | [0.05] | [0.08] | [0.02] | [0.05] |
| Comparative | — | — | — | — | (P3)-2 | (B)-1 | (F1)-1 | (F2)-1 | (E)-1 | Add-1 |
| Example 7 | | | | | [100] | [1.2] | [0.05] | [0.08] | [0.02] | [0.05] |
| Comparative | — | — | — | — | (P3)-3 | (B)-1 | (F1)-1 | (F2)-1 | (E)-1 | Add-1 |
| Example 8 | | | | | [100] | [1.2] | [0.05] | [0.08] | [0.02] | [0.05] |

TABLE 5

| | Component (P) | | | | | | | | | |
|---|---|---|---|---|---|---|---|---|---|---|
| | Component | | Component | | Component | Component | Component | Component | Component | Component |
| | (P1) | | (P2) | | (P3) | (B) | (F1) | (F2) | (E) | (Add) |
| Example 1 | (P1)-3 | — | (P2)-3 | — | — | (B)-1 | (F1)-1 | (F2)-1 | (E)-1 | Add-1 |
| | [30] | | [70] | | | [1.2] | [0.05] | [0.08] | [0.02] | [0.05] |
| Example 2 | (P1)-4 | — | (P2)-3 | — | — | (B)-1 | (F1)-1 | (F2)-1 | (E)-1 | Add-1 |
| | [30] | | [70] | | | [1.2] | [0.05] | [0.08] | [0.02] | [0.05] |
| Comparative | — | — | (P2)-3 | — | (P3)-2 | (B)-1 | (F1)-1 | (F2)-1 | (E)-1 | Add-1 |
| Example 9 | | | [70] | | [30] | [1.2] | [0.05] | [0.08] | [0.02] | [0.05] |
| Comparative | — | — | (P2)-3 | — | (P3)-3 | (B)-1 | (F1)-1 | (F2)-1 | (E)-1 | Add-1 |
| Example 10 | | | [70] | | [30] | [1.2] | [0.05] | [0.08] | [0.02] | [0.05] |

TABLE 6

| | Component (P) | | | | | | | | | |
|---|---|---|---|---|---|---|---|---|---|---|
| | Component | | Component | | Component | Component | Component | Component | Component | Component |
| | (P1) | | (P2) | | (P3) | (B) | (F1) | (F2) | (E) | (Add) |
| Example 3 | (P1)-3 | — | (P2)-4 | — | — | (B)-1 | (F1)-1 | (F2)-1 | (E)-1 | Add-1 |
| | [30] | | [70] | | | [1.2] | [0.05] | [0.08] | [0.02] | [0.05] |
| Example 4 | (P1)-4 | — | (P2)-4 | — | — | (B)-1 | (F1)-1 | (F2)-1 | (E)-1 | Add-1 |
| | [30] | | [70] | | | [1.2] | [0.05] | [0.08] | [0.02] | [0.05] |
| Comparative | — | — | (P2)-4 | — | (P3)-2 | (B)-1 | (F1)-1 | (F2)-1 | (E)-1 | Add-1 |
| Example 11 | | | [70] | | [30] | [1.2] | [0.05] | [0.08] | [0.02] | [0.05] |
| Comparative | — | — | (P2)-4 | — | (P3)-3 | (B)-1 | (F1)-1 | (F2)-1 | (E)-1 | Add-1 |
| Example 12 | | | [70] | | [30] | [1.2] | [0.05] | [0.08] | [0.02] | [0.05] |

TABLE 7

| | Component (P) | | | | | | | | | |
|---|---|---|---|---|---|---|---|---|---|---|
| | Component | | Component | | Component | Component | Component | Component | Component | Component |
| | (P1) | | (P2) | | (P3) | (B) | (F1) | (F2) | (E) | (Add) |
| Comparative | (P1)-1 | | — | — | — | (B)-1 | (F1)-1 | (F2)-1 | (E)-1 | Add-1 |
| Example 13 | [100] | | | | | [1.2] | [0.05] | [0.08] | [0.02] | [0.05] |
| Comparative | (P1)-2 | | — | — | — | (B)-1 | (F1)-1 | (F2)-1 | (E)-1 | Add-1 |
| Example 14 | [100] | | | | | [1.2] | [0.05] | [0.08] | [0.02] | [0.05] |
| Example 5 | (P1)-1 | — | (P2)-5 | — | — | (B)-1 | (F1)-1 | (F2)-1 | (E)-1 | Add-1 |
| | [30] | | [70] | | | [1.2] | [0.05] | [0.08] | [0.02] | [0.05] |
| Example 6 | (P1)-2 | — | (P2)-5 | — | — | (B)-1 | (F1)-1 | (F2)-1 | (E)-1 | Add-1 |
| | [30] | | [70] | | | [1.2] | [0.05] | [0.08] | [0.02] | [0.05] |
| Example 7 | (P1)-3 | — | (P2)-5 | — | — | (B)-1 | (F1)-1 | (F2)-1 | (E)-1 | Add-1 |
| | [30] | | [70] | | | [1.2] | [0.05] | [0.08] | [0.02] | [0.05] |
| Example 8 | (P1)-4 | — | (P2)-5 | — | — | (B)-1 | (F1)-1 | (F2)-1 | (E)-1 | Add-1 |
| | [30] | | [70] | | | [1.2] | [0.05] | [0.08] | [0.02] | [0.05] |

TABLE 8

| | Component (P) | | | | | | | | | |
|---|---|---|---|---|---|---|---|---|---|---|
| | Component | | Component | | Component | Component | Component | Component | Component | Component |
| | (P1) | | (P2) | | (P3) | (B) | (F1) | (F2) | (E) | (Add) |
| Comparative | — | — | (P2)-1 | | — | (B)-1 | (F1)-1 | (F2)-1 | (E)-1 | Add-1 |
| Example 15 | | | [100] | | | [1.2] | [0.05] | [0.08] | [0.02] | [0.05] |
| Comparative | — | — | (P2)-1 | (P2)-2 | — | (B)-1 | (F1)-1 | (F2)-1 | (E)-1 | Add-1 |
| Example 16 | | | [70] | [30] | | [1.2] | [0.05] | [0.08] | [0.02] | [0.05] |
| Comparative | — | — | (P2)-1 | (P2)-4 | — | (B)-1 | (F1)-1 | (F2)-1 | (E)-1 | Add-1 |
| Example 17 | | | [70] | [30] | | [1.2] | [0.05] | [0.08] | [0.02] | [0.05] |
| Example 9 | (P1)-1 | — | (P2)-1 | — | — | (B)-1 | (F1)-1 | (F2)-1 | (E)-1 | Add-1 |
| | [30] | | [70] | | | [1.2] | [0.05] | [0.08] | [0.02] | [0.05] |
| Example 10 | (P1)-3 | — | (P2)-1 | — | — | (B)-1 | (F1)-1 | (F2)-1 | (E)-1 | Add-1 |
| | [30] | | [70] | | | [1.2] | [0.05] | [0.08] | [0.02] | [0.05] |
| Example 11 | (P1)-4 | — | (P2)-1 | — | — | (B)-1 | (F1)-1 | (F2)-1 | (E)-1 | Add-1 |
| | [30] | | [70] | | | [1.2] | [0.05] | [0.08] | [0.02] | [0.05] |

TABLE 9

| | Component (P) | | | | | | | | | |
|---|---|---|---|---|---|---|---|---|---|---|
| | Component | | Component | | Component | Component | Component | Component | Component | Component |
| | (P1) | | (P2) | | (P3) | (B) | (F1) | (F2) | (E) | (Add) |
| Comparative | — | — | (P2)-2 | | — | (B)-1 | (F1)-1 | (F2)-1 | (E)-1 | Add-1 |
| Example 18 | | | [100] | | | [1.2] | [0.05] | [0.08] | [0.02] | [0.05] |
| Comparative | — | — | (P2)-4 | (P2)-2 | — | (B)-1 | (F1)-1 | (F2)-1 | (E)-1 | Add-1 |
| Example 19 | | | [70] | [30] | | [1.2] | [0.05] | [0.08] | [0.02] | [0.05] |
| Comparative | (P1)-2 | (P1)-3 | — | — | — | (B)-1 | (F1)-1 | (F2)-1 | (E)-1 | Add-1 |
| Example 20 | [70] | [30] | | | | [1.2] | [0.05] | [0.08] | [0.02] | [0.05] |
| Comparative | (P1)-1 | (P1)-3 | — | — | — | (B)-1 | (F1)-1 | (F2)-1 | (E)-1 | Add-1 |
| Example 21 | [70] | [30] | | | | [1.2] | [0.05] | [0.08] | [0.02] | [0.05] |
| Comparative | (P1)-1 | (P1)-4 | — | — | — | (B)-1 | (F1)-1 | (F2)-1 | (E)-1 | Add-1 |
| Example 22 | [70] | [30] | | | | [1.2] | [0.05] | [0.08] | [0.02] | [0.05] |
| Comparative | (P1)-1 | — | — | — | (P3)-2 | (B)-1 | (F1)-1 | (F2)-1 | (E)-1 | Add-1 |
| Example 23 | [30] | | | | [70] | [1.2] | [0.05] | [0.08] | [0.02] | [0.05] |
| Comparative | (P1)-1 | — | — | — | (P3)-3 | (B)-1 | (F1)-1 | (F2)-1 | (E)-1 | Add-1 |
| Example 24 | [30] | | | | [70] | [1.2] | [0.05] | [0.08] | [0.02] | [0.05] |
| Comparative | (P1)-2 | — | — | — | (P3)-3 | (B)-1 | (F1)-1 | (F2)-1 | (E)-1 | Add-1 |
| Example 25 | [30] | | | | [70] | [1.2] | [0.05] | [0.08] | [0.02] | [0.05] |
| Comparative | (P1)-3 | — | — | — | (P3)-3 | (B)-1 | (F1)-1 | (F2)-1 | (E)-1 | Add-1 |
| Example 26 | [30] | | | | [70] | [1.2] | [0.05] | [0.08] | [0.02] | [0.05] |
| Comparative | — | — | — | — | (P3)-1 | (B)-1 | (F1)-1 | (F2)-1 | (E)-1 | Add-1 |
| Example 27 | | | | | [100] | [1.2] | [0.05] | [0.08] | [0.02] | [0.05] |
| Comparative | (P11)-1 | — | — | — | (P3)-1 | (B)-1 | (F1)-1 | (F2)-1 | (E)-1 | Add-1 |
| Example 28 | [30] | | | | [70] | [1.2] | [0.05] | [0.08] | [0.02] | [0.05] |
| Comparative | (P1)-3 | — | — | — | (P3)-1 | (B)-1 | (F1)-1 | (F2)-1 | (E)-1 | Add-1 |
| Example 29 | [30] | | | | [70] | [1.2] | [0.05] | [0.08] | [0.02] | [0.05] |

TABLE 10

| | Component (P) | | | | | | | | |
|---|---|---|---|---|---|---|---|---|---|
| | Component | | Component | | Component | Component | Component | Component | Component |
| | (P1) | | (P2) | | (B) | (F1) | (F2) | (E) | (Add) |
| Comparative | — | — | (P2)-3 | | (B)-1 | (F1)-1 | (F2)-1 | (E)-1 | Add-1 |
| Example 1 | | | [100] | | [1.2] | [0.05] | [0.08] | [0.02] | [0.05] |
| Example 12 | (P1)-3 | — | (P2)-3 | — | (B)-1 | (F1)-1 | (F2)-1 | (E)-1 | Add-1 |
| | [10] | | [90] | | [1.2] | [0.05] | [0.08] | [0.02] | [0.05] |
| Example 13 | (P1)-3 | — | (P2)-3 | — | (B)-1 | (F1)-1 | (F2)-1 | (E)-1 | Add-1 |
| | [20] | | [80] | | [1.2] | [0.05] | [0.08] | [0.02] | [0.05] |
| Example 1 | (P1)-3 | — | (P2)-3 | — | (B)-1 | (F1)-1 | (F2)-1 | (E)-1 | Add-1 |
| | [30] | | [70] | | [1.2] | [0.05] | [0.08] | [0.02] | [0.05] |
| Example 14 | (P1)-3 | — | (P2)-3 | — | (B)-1 | (F1)-1 | (F2)-1 | (E)-1 | Add-1 |
| | [40] | | [60] | | [1.2] | [0.05] | [0.08] | [0.02] | [0.05] |
| Example 15 | (P1)-3 | — | (P2)-3 | — | (B)-1 | (F1)-1 | (F2)-1 | (E)-1 | Add-1 |
| | [50] | | [50] | | [1.2] | [0.05] | [0.08] | [0.02] | [0.05] |

TABLE 11

| | Component (P) | | | | | | | | |
|---|---|---|---|---|---|---|---|---|---|
| | Component | | Component | | Component | Component | Component | Component | Component |
| | (P1) | | (P2) | | (B) | (F1) | (F2) | (E) | (Add) |
| Comparative | — | — | (P2)-3 | | (B)-1 | (F1)-1 | (F2)-1 | (E)-1 | Add-1 |
| Example 1 | | | [100] | | [1.2] | [0.05] | [0.08] | [0.02] | [0.05] |
| Example 16 | (P1)-5 | — | (P2)-3 | — | (B)-1 | (F1)-1 | (F2)-1 | (E)-1 | Add-1 |
| | [10] | | [90] | | [1.2] | [0.05] | [0.08] | [0.02] | [0.05] |
| Example 17 | (P1)-5 | — | (P2)-3 | — | (B)-1 | (F1)-1 | (F2)-1 | (E)-1 | Add-1 |
| | [20] | | [80] | | [1.2] | [0.05] | [0.08] | [0.02] | [0.05] |
| Example 18 | (P1)-5 | — | (P2)-3 | — | (B)-1 | (F1)-1 | (F2)-1 | (E)-1 | Add-1 |
| | [30] | | [70] | | [1.2] | [0.05] | [0.08] | [0.02] | [0.05] |
| Example 19 | (P1)-5 | — | (P2)-3 | — | (B)-1 | (F1)-1 | (F2)-1 | (E)-1 | Add-1 |
| | [40] | | [60] | | [1.2] | [0.05] | [0.08] | [0.02] | [0.05] |

TABLE 12

| | Component (P) | | | | | | | | |
|---|---|---|---|---|---|---|---|---|---|
| | Component | | Component | | Component | Component | Component | Component | Component |
| | (P1) | | (P2) | | (B) | (F1) | (F2) | (E) | (Add) |
| Comparative | — | — | (P2)-3 | | (B)-1 | (F1)-1 | (F2)-1 | (E)-1 | Add-1 |
| Example 1 | | | [100] | | [1.2] | [0.05] | [0.08] | [0.02] | [0.05] |
| Comparative | — | — | (P2)-3 | (P2)-4 | (B)-1 | (F1)-1 | (F2)-1 | (E)-1 | Add-1 |
| Example 30 | | | [90] | [10] | [1.2] | [0.05] | [0.08] | [0.02] | [0.05] |
| Comparative | — | — | (P2)-3 | (P2)-4 | (B)-1 | (F1)-1 | (F2)-1 | (E)-1 | Add-1 |
| Example 31 | | | [80] | [20] | [1.2] | [0.05] | [0.08] | [0.02] | [0.05] |
| Comparative | — | — | (P2)-3 | (P2)-4 | (B)-1 | (F1)-1 | (F2)-1 | (E)-1 | Add-1 |
| Example 4 | | | [70] | [30] | [1.2] | [0.05] | [0.08] | [0.02] | [0.05] |
| Comparative | — | — | (P2)-3 | (P2)-4 | (B)-1 | (F1)-1 | (F2)-1 | (E)-1 | Add-1 |
| Example 32 | | | [60] | [40] | [1.2] | [0.05] | [0.08] | [0.02] | [0.05] |
| Comparative | — | — | (P2)-3 | (P2)-4 | (B)-1 | (F1)-1 | (F2)-1 | (E)-1 | Add-1 |
| Example 33 | | | [50] | [50] | [1.2] | [0.05] | [0.08] | [0.02] | [0.05] |
| Comparative | — | — | (P2)-3 | (P2)-4 | (B)-1 | (F1)-1 | (F2)-1 | (E)-1 | Add-1 |
| Example 34 | | | [40] | [60] | [1.2] | [0.05] | [0.08] | [0.02] | [0.05] |

| | | | | | | | | |
|---|---|---|---|---|---|---|---|---|
| Comparative | — | — | (P2)-4 | (B)-1 | (F1)-1 | (F2)-1 | (E)-1 | Add-1 |
| Example 2 | | | [100] | [1.2] | [0.05] | [0.08] | [0.02] | [0.05] |

In Tables 4 to 12, each abbreviation has the following meaning. The numerical values in the brackets are blending amounts (parts by mass).

(P1)-1: The above-described polymeric compound p10-1.

(P1)-2: The above-described polymeric compound p10-2.

(P1)-3: The above-described polymeric compound p10-3.

(P1)-4: The above-described polymeric compound p10-4.

(P1)-5: The above-described polymeric compound p10-5.

(P2)-1: The above-described polymeric compound p20-1.

(P2)-2: The above-described polymeric compound p20-2.

(P2)-3: The above-described polymeric compound p20-3.

(P2)-4: The above-described polymeric compound p20-4.

(P2)-5: The above-described polymeric compound p20-5.

(P3)-1: The above-described polymeric compound p30-1.

(P3)-2: The above-described polymeric compound p30-2.

(P3)-3: The above-described polymeric compound p30-3.

(B)-1: An acid generator consisting of a compound represented by Chemical Formula (B-1) shown below.

(F1)-1: Triamylamine.

(F2)-1: Salicylic acid.

(E)-1: A sulfur-containing compound represented by Chemical Formula (E-1) shown below.

Add-1: A surfactant, BYK-310 (manufactured by BYK Additives & Instruments).

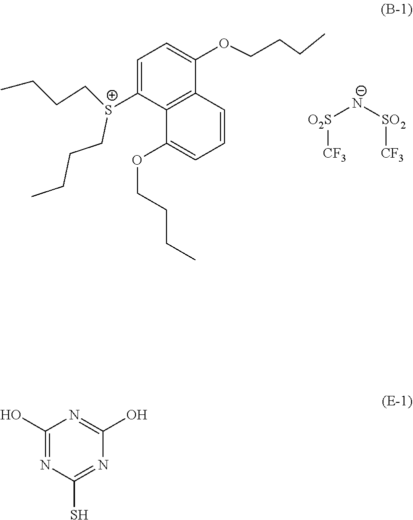 [SMILES: CCCCOc1ccc([S+](CCCC)CCCC)c2c(OCCCC)cccc12 ; O=S(=O)([N-]S(=O)(=O)C(F)(F)F)C(F)(F)F ; Oc1nc(O)nc(S)n1]

Step of forming resist film on support:

As a substrate for evaluation, a silicon substrate which had been subjected to hexamethyldisilazane (HMDS) treatment was used.

Each of the resist compositions prepared as described above was applied onto the silicon substrate using a spinner, subjected to heating treatment (post-applied baking (PAB)) at a temperature of 120° C. for 120 seconds on a hot plate, and dried to form a resist film having a film thickness of 4 μm (4,000 nm).

Step of exposing resist film:

Next, the resist film was selectively exposed through a mask pattern using an exposure apparatus Low NA i-Line stepper (FPA-5510iV, manufactured by CANON INC.).

Next, it was placed on a hot plate and subjected to post-exposure heating (PEB) treatment at 110° C. for 90 seconds.

Step of subjecting exposed resist film to alkali development:

Next, using a developing device (Clean Track ACTS, manufactured by Tokyo Electron Limited), alkali development was carried out at 23° C. for 60 seconds using an aqueous solution of 2.38% by mass of tetramethylammonium hydroxide (TMAH) (product name: “NMD-3”, manufactured by TOKYO OHKA KOGYO CO., LTD.).

### [Measurement of Film Reduction]

For the film reduction (nm), the film thickness (the initial film thickness X1) of the resist film formed in [Step of forming resist film on support] described above was measured by using a film thickness measuring device (an optical interference type film thickness measuring device: Nanospec, model 3000).

Next, the film thickness (the film thickness Y1 after development) of the resist pattern after the alkali development in [Step of subjecting exposed resist film to alkali development] described above had been carried out was measured by using a film thickness measuring device (an optical interference type film thickness measuring device: Nanospec, model 3000).

Then, the film reduction (nm) was calculated according to the following expression.

Film reduction (nm)=(initial film thickness X1)−(film thickness Y1 after development)

### [Measurement of Dissolution Rate (DR) in Alkali Developing Solution]

The dissolution rate (DR) (nm/s) in an alkali developing solution was calculated according to the following expression.

DR (nm/s)=film reduction (nm)/60 (seconds)

### [Measurement of 10 μm Es]

The exposure amount at which the pattern separation was achieved was checked in a case where in <Formation of resist pattern> described above, the target size was set to a 1:1 space-and-line pattern (hereinafter referred to as an “SL pattern”) having a space width of 10 μm. The results are shown in the table as “10 μm Es (mJ/cm²)”.

### [Measurement of 10 μm Eop]

The exposure amount at which a pattern was formed almost according to the mask size was checked in a case where in <Formation of resist pattern>described above, the target size was set to a 1:1 space-and-line pattern (hereinafter referred to as an “SL pattern”) having a space width of 10 μm. The results are shown in the table as “10 μm Eop (mJ/cm²)”.

### [Evaluation of Reso at 10 μm Eop]

At the exposure amount (10 μm Eop) at which a pattern was formed almost according to the mask size, it was checked which size of the mask, at which the separation resolution was achieved, could be obtained in a case where in <Formation of resist pattern> described above, the target size was set to a 1:1 space-and-line pattern (hereinafter referred to as an “SL pattern”) having a space width of 10 μm. This is shown in the table as “Reso (nm) at 10 μm Eop”.

### [Evaluation of Separation Resolution]

The place where the finest mask was separated and resolved was checked by changing the exposure amount In <Formation of resist pattern> described above. This is shown in the table as “Separation resolution (μm)”.

### [Calculation of (Eop−Es)/Eop]

(Eop−Es)/Eop was calculated using the values of 10 μm Eop and 10 μm Es, obtained as described above.

It is meant that the closer the value of “(Eop−Es)/Eop” is to 1, the more the residue margin is, that is, the more reduced the residue is.

This is conceived to be due to the fact that in a case of the residue affected by the height difference of the substrate, the exposure amount is insufficient in the exposure environment of the residue portion, and thus the solubility of the residue portion in an alkali developing solution is decreased. For this reason, the resist resolution is improved on the side of the lower exposure amount than Eop, and thus the residue due to low exposure generated in the residue portion can be reduced. As a result, it is possible to easily evaluate the residue margin by determining “(Eop−Es)/Eop”.

The results of the film reduction (nm), the dissolution rate (DR) in an alkali developing solution, 10 μm Es, 10 μm Eop, Reso at 10 μm Eop, the separation resolution, and (Eop−Es)/Eop determined in the resist pattern formation method of each example are shown Tables 13 to 21.

TABLE 13

| | | | | | Reso at | | |
|---|---|---|---|---|---|---|---|
| | Film | | 10 μm | 10 μm | 10 μm | | |
| | reduction | DR | Es | Eop | Eop | Separation | (Eop − |
| | [nm] | [nm/s] | [mJ/cm²] | [mJ/cm²] | [mJ/cm²] | resolution | Es)/Eop |
| Comparative | 6 | 0.11 | 730 | 1720 | 3 μm | 3 μm | 0.58 |
| Example 1 | | | | | | | |
| Comparative | 282 | 4.71 | 90 | 340 | 1.5 μm | 1.5 μm | 0.74 |
| Example 2 | | | | | | | |
| Comparative | 13 | 0.22 | 660 | 1410 | 3 μm | 3 μm | 0.53 |
| Example 3 | | | | | | | |
| Comparative | 19 | 0.32 | 540 | 1350 | 3 μm | 2 μm | 0.60 |
| Example 4 | | | | | | | |
| Comparative | >4000 | — | — | — | — | — | — |
| Example 5 | | | | | | | |
| Comparative | >4000 | — | — | — | — | — | — |
| Example 6 | | | | | | | |
| Comparative | >4000 | — | — | — | — | — | — |
| Example 7 | | | | | | | |
| Comparative | 1010 | 16.83 | — | — | — | — | — |
| Example 8 | | | | | | | |

TABLE 14

| | | | | | Reso at | | |
|---|---|---|---|---|---|---|---|
| | Film | | 10 μm | 10 μm | 10 μm | | |
| | reduction | DR | Es | Eop | Eop | Separation | (Eop − |
| | [nm] | [nm/s] | [mJ/cm²] | [mJ/cm²] | [mJ/cm²] | resolution | Es)/Eop |
| Example 1 | 17 | 0.28 | 110 | 540 | 2 μm | 1.0 μm | 0.80 |
| Example 2 | 18 | 0.30 | 290 | 1130 | 2 μm | 1.0 μm | 0.74 |
| Comparative | 131 | 2.18 | 370 | 1150 | 3 μm | 2 μm | 0.68 |
| Example 9 | | | | | | | |
| Comparative | 28 | 0.46 | 420 | 1260 | 3 μm | 2 μm | 0.67 |
| Example 10 | | | | | | | |

TABLE 15

| | | | | | Reso at | | |
|---|---|---|---|---|---|---|---|
| | Film | | | | 10 μm | | |
| | reduction | DR | 10 μm | 10 μm | Eop | Separation | (Eop − |
| | [nm] | [nm/s] | Es | Eop | [mJ/cm²] | resolution | Es)/Eop |
| Example 3 | 265 | 4.42 | 70 | 230 | 1.5 μm | 0.75 μm | 0.70 |
| Example 4 | 283 | 4.71 | 70 | 260 | 1.5 μm | 0.75 μm | 0.73 |
| Comparative | 727 | 12.12 | 50 | 60 | 2 μm | 1.0 μm | 0.17 |
| Example 11 | | | | | | | |
| Comparative | 381 | 6.35 | 70 | 130 | 1.5 μm | 0.8 μm | 0.46 |
| Example 12 | | | | | | | |

TABLE 16

| | | | | | Reso at | | |
|---|---|---|---|---|---|---|---|
| | Film | | | | 10 μm | | |
| | reduction | DR | 10 μm | 10 μm | Eop | Separation | (Eop − |
| | [nm] | [nm/s] | Es | Eop | [mJ/cm²] | resolution | Es)/Eop |
| Comparative | 530 | 8.84 | 50 | — | — | — | — |
| Example 13 | | | | | | | |
| Comparative | −218 | −3.63 | 80 | — | — | — | — |
| Example 14 | | | | | | | |
| Example 5 | 10 | 0.17 | 140 | 560 | 2 μm | 2 μm | 0.75 |
| Example 6 | 6 | 0.10 | 200 | 780 | 2 μm | 2 μm | 0.74 |
| Example 7 | 18 | 0.29 | 100 | 280 | 1.5 μm | 0.8 μm | 0.64 |
| Example 8 | 9 | 0.16 | 150 | 630 | 1.5 μm | 0.9 μm | 0.76 |

TABLE 17

| | | | | | Reso at | | |
|---|---|---|---|---|---|---|---|
| | Film | | | | 10 μm | | |
| | reduction | DR | 10 μm | 10 μm | Eop | Separation | (Eop − |
| | [nm] | [nm/s] | Es | Eop | [mJ/cm²] | resolution | Es)/Eop |
| Comparative | 74 | 1.24 | 70 | 270 | 1.5 μm | 1.0 μm | 0.74 |
| Example 15 | | | | | | | |
| Comparative | 78 | 1.30 | 110 | 430 | 1.5 μm | 1.0 μm | 0.74 |
| Example 16 | | | | | | | |
| Comparative | 100 | 1.66 | 70 | 280 | 1.5 μm | 1.0 μm | 0.75 |
| Example 17 | | | | | | | |
| Example 9 | 63 | 1.06 | 70 | 290 | 1.5 μm | 1.0 μm | 0.76 |
| Example 10 | 21 | 0.35 | 70 | 360 | 1.5 μm | 0.75 μm | 0.81 |
| Example 11 | 64 | 1.07 | 60 | 370 | 1.5 μm | 0.75 μm | 0.84 |

TABLE 18

| | | | | | Reso at | | |
|---|---|---|---|---|---|---|---|
| | Film | | | | 10 μm | | |
| | reduction | DR | 10 μm | 10 μm | Eop | Separation | (Eop − |
| | [nm] | [nm/s] | Es | Eop | [mJ/cm²] | resolution | Es)/Eop |
| Comparative | 84 | 1.40 | 400 | 1250 | 3 μm | 3 μm | 0.68 |
| Example 18 | | | | | | | |
| Comparative | 253 | 4.21 | 120 | 450 | 1.5 μm | 1.5 μm | 0.73 |
| Example 19 | | | | | | | |
| Comparative | >4000 | — | — | — | — | — | — |
| Example 20 | | | | | | | |
| Comparative | >4000 | — | — | — | — | — | — |
| Example 21 | | | | | | | |
| Comparative | >4000 | — | — | — | — | — | — |
| Example 22 | | | | | | | |
| Comparative | 545 | 9.08 | 70 | 80 | 2 μm | 2 μm | 0.13 |
| Example 23 | | | | | | | |
| Comparative | 19 | 0.31 | 80 | 140 | 1.5 μm | 0.9 μm | 0.43 |
| Example 24 | | | | | | | |
| Comparative | 28 | 0.47 | 100 | 140 | 1.5 μm | 1.5 μm | 0.29 |
| Example 25 | | | | | | | |
| Comparative | 570 | 9.50 | 70 | 90 | 1.5 μm | 0.9 μm | 0.22 |
| Example 26 | | | | | | | |
| Comparative | 130 | 2.17 | — | — | — | — | — |
| Example 27 | | | | | | | |
| Comparative | 14 | 0.23 | 120 | 280 | 2 μm | 2 μm | 0.57 |
| Example 28 | | | | | | | |
| Comparative | 121 | 2.01 | 80 | 150 | 1.0 μm | 0.75 μm | 0.47 |
| Example 29 | | | | | | | |

From the results shown in Tables 13 to 18, it can be found that in the resist pattern formation method of Example to which the present invention has been applied, the reduction of the developed film is suppressed, the sensitivity is high, and the residue hardly is generated as compared with the resist pattern formation method of Comparative Example corresponding to each resist pattern formation method of Example.

TABLE 19

| | | | | | Reso at | | |
|---|---|---|---|---|---|---|---|
| | Film | | | | 10 μm | | |
| | reduction | DR | 10 μm | 10 μm | Eop | Separation | (Eop − |
| | [nm] | [nm/s] | Es | Eop | [mJ/cm²] | resolution | Es)/Eop |
| Comparative | 6 | 0.11 | 730 | 1720 | 3 μm | 3 μm | 0.58 |
| Example 1 | | | | | | | |
| Example 12 | 6 | 0.10 | 230 | 940 | 3 μm | 1.5 μm | 0.76 |
| Example 13 | 5 | 0.08 | 140 | 740 | 3 μm | 1.5 μm | 0.81 |
| Example 1 | 17 | 0.28 | 110 | 540 | 2 μm | 1.0 μm | 0.80 |
| Example 14 | 66 | 1.09 | 90 | 300 | 1.5 μm | 0.75 μm | 0.70 |
| Example 15 | 268 | 4.47 | 80 | 260 | 1.5 μm | 1 μm | 0.69 |

From the results shown in Table 19, it can be confirmed that in a case where a mixed resin of the polymeric compound p20-3 and the polymeric compound p10-3 is employed in the resist composition, the mass ratio represented by p10-3/p20-3 is in a range of p10-3/p20-3 >1/9 to 5/5, the high sensitivity is improved, the resolution is improved, and the residue is hardly generated.

TABLE 20

| | | | | | Reso at | | |
|---|---|---|---|---|---|---|---|
| | Film | | | | 10 μm | | |
| | reduction | DR | 10 μm | 10 μm | Eop | Separation | (Eop − |
| | [nm] | [nm/s] | Es | Eop | [mJ/cm²] | resolution | Es)/Eop |
| Comparative | 6 | 0.11 | 730 | 1720 | 3 μm | 3 μm | 0.58 |
| Example 1 | | | | | | | |
| Example 16 | 4 | 0.07 | 520 | 1350 | 1.5 μm | 1.5 μm | 0.61 |
| Example 17 | 10 | 0.16 | 280 | 750 | 1.5 μm | 1.5 μm | 0.63 |
| Example 18 | 24 | 0.39 | 110 | 440 | 1.5 μm | 0.9 μm | 0.75 |
| Example 19 | 285 | 4.75 | 70 | 240 | 0.8 μm | 0.75 μm | 0.71 |

From the results shown in Table 20, it can be confirmed that in a case where a mixed resin of the polymeric compound p20-3 and the polymeric compound p10-5 is employed in the resist composition, the mass ratio represented by p10-5/p20-3 is in a range of p10-5/p20-3 >1/9 to 4/6, the high sensitivity is improved, the resolution is improved, and the residue is hardly generated.

TABLE 21

| | | | | | Reso at | | |
|---|---|---|---|---|---|---|---|
| | Film | | | | 10 μm | | |
| | reduction | DR | 10 μm | 10 μm | Eop | Separation | (Eop − |
| | [nm] | [nm/s] | Es | Eop | [mJ/cm²] | resolution | Es)/Eop |
| Comparative | 6 | 0.11 | 730 | 1720 | 3 μm | 3 μm | 0.58 |
| Example 1 | | | | | | | |
| Comparative | 8 | 0.14 | 650 | 1600 | 3 μm | 3 μm | 0.59 |
| Example 30 | | | | | | | |
| Comparative | 12 | 0.20 | 590 | 1450 | 3 μm | 3 μm | 0.59 |
| Example 31 | | | | | | | |
| Comparative | 19 | 0.32 | 540 | 1350 | 3 μm | 2 μm | 0.60 |
| Example 4 | | | | | | | |
| Comparative | 24 | 0.40 | 230 | 530 | 2 μm | 2 μm | 0.57 |
| Example 32 | | | | | | | |
| Comparative | 30 | 0.50 | 140 | 500 | 2 μm | 1.5 μm | 0.72 |
| Example 33 | | | | | | | |
| Comparative | 36 | 0.61 | 100 | 420 | 1.5 μm | 1.5 μm | 0.76 |
| Example 34 | | | | | | | |
| Comparative | 282 | 4.71 | 90 | 340 | 1.5 μm | 1.5 μm | 0.74 |
| Example 2 | | | | | | | |

From the results shown in Table 21, it has been confirmed that in a case where a mixed resin of the polymeric compound p20-3 and the polymeric compound p20-4 is used in the resist composition, there is no residue margin and the effect of reducing the residue is not obtained.

What is claimed is:

1. A resist pattern formation method comprising:
forming a resist film on a support using a resist composition that generates acid upon exposure and exhibits increased solubility in an alkali developing solution under action of acid;
exposing the resist film; and
subjecting the exposed resist film to alkali development to form a positive-tone resist pattern,
wherein the resist composition contains a first resin component (P1) and a second resin component (P2),
the first resin component (P1) contains a polymeric compound (p10) having a constitutional unit (a0) derived from acrylic acid in which a hydrogen atom bonded to a carbon atom at an α-position may be substituted with a substituent, and
the second resin component (P2) contains a polymeric compound (p20) having both a constitutional unit (u0) containing a phenolic hydroxyl group and a constitutional unit (u1) containing an acid decomposable group having a polarity that is increased under action of acid.

2. The resist pattern formation method according to claim 1,
wherein the first resin component (P1) and the second resin component (P2) are used in combination, when a dissolution rate of the first resin component (P1) in an alkali developing solution is denoted by DR_{P1}, a dissolution rate of the second resin component (P2) in an alkali developing solution is denoted by DR_{P2}, and when a dissolution rate of a mixed resin of the first resin component (P1) and the second resin component (P2), in an alkali developing solution, is denoted by DR_{MIX}, a mixing ratio satisfying the following expressions are present,
DR_{MIX}<DR_{P1} and DR_{MIX}<DR_{P2}.

3. The resist pattern formation method according to claim 1,
wherein the constitutional unit (a0) is a constitutional unit represented by General Formula (a0-0), 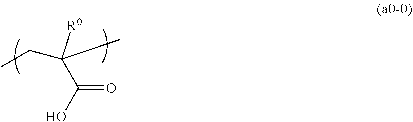
wherein R⁰ represents a hydrogen atom, an alkyl group having 1 to 5 carbon atoms, or a halogenated alkyl group having 1 to 5 carbon atoms.

4. The resist pattern formation method according to claim 1,
wherein the constitutional unit (u0) is a constitutional unit represented by General Formula (u0-0), 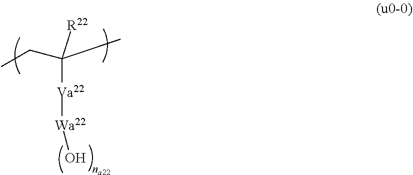
wherein R²² represents a hydrogen atom, an alkyl group having 1 to 5 carbon atoms, or a halogenated alkyl group having 1 to 5 carbon atoms, Va²² represents a divalent linking group or a single bond, Wa²² represents an (nₐ₂₂+1)-valent aromatic hydrocarbon group, and nₐ₂₂ represents an integer in a range of 1 to 3.

5. The resist pattern formation method according to claim 1,
wherein the constitutional unit (u1) is a constitutional unit derived from an acrylic acid ester in which a hydrogen atom bonded to a carbon atom at an α-position may be substituted with a substituent and is a constitutional unit containing an acid decomposable group having a polarity that is increased under action of acid.

6. The resist pattern formation method according to claim 1,
wherein a proportion of the constitutional unit (u1) in the polymeric compound (p20) is 5% to 50% by mole with respect to 100% by mole of all constitutional units constituting the polymeric compound (p20).

7. The resist pattern formation method according to claim 1,
wherein a proportion of the constitutional unit (a0) in the polymeric compound (p10) is 5% to 40% by mole with respect to 100% by mole of all constitutional units constituting the polymeric compound (p10).

8. The resist pattern formation method according to claim 1,
wherein a content proportion of the first resin component (P1) contained in the resist composition is 10 parts by mass or more and 50 parts by mass or less with respect to 100 parts by mass of a total of the first resin component (P1) and the second resin component (P2).
